(19) United States
(12) Patent Application Publication
(10) Pub. No.: US 2024/0389376 A1
(43) Pub. Date: Nov. 21, 2024

(54) LIGHT-EMITTING DEVICE, LIGHT-EMITTING APPARATUS, AND ELECTRONIC APPLIANCE

(71) Applicant: SEMICONDUCTOR ENERGY LABORATORY CO., LTD., Atsugi-shi (JP)

(72) Inventors: Toshiki SASAKI, Kawasaki (JP); Nobuharu OHSAWA, Zama (JP); Hiromi SEO, Sagamihara (JP); Shinya FUKUZAKI, Atsugi (JP)

(21) Appl. No.: 18/662,265

(22) Filed: May 13, 2024

(30) Foreign Application Priority Data
May 19, 2023 (JP) 2023-083173
Sep. 5, 2023 (JP) 2023-143442

(51) Int. Cl. H10K 50/13; H10K 50/19; H10K 85/30; H10K 85/60

(52) U.S. Cl. CPC H10K 50/13; H10K 50/19; H10K 85/342; H10K 85/346; H10K 85/371; H10K 85/381; H10K 85/615; H10K 85/633; H10K 85/636; H10K 85/654; H10K 85/6572; H10K 85/6574; H10K 85/6576

(57) ABSTRACT

To provide a light-emitting device with favorable characteristics. A plurality of light-emitting devices are over one insulating surface. Each of the plurality of light-emitting devices includes a first electrode, a second electrode, and an organic compound layer between the first electrode and the second electrode. The first electrodes of the plurality of light-emitting devices are separate from each other. The second electrode is shared by the plurality of light-emitting devices. The organic compound layer includes a first light-emitting layer, a second light-emitting layer, and an intermediate layer between the first light-emitting layer and the second light-emitting layer. Contours of the first light-emitting layer, the intermediate layer, and the second light-emitting layer are aligned or substantially aligned with each other in each of the plurality of light-emitting devices. The intermediate layer includes a first layer. The first layer is a mixed layer including a metal, a first organic compound, and a second organic compound. The first organic compound includes a phenanthroline ring having an electron-donating group. The second organic compound includes a π-electron deficient heteroaromatic ring.

### BACKGROUND OF THE INVENTION

### 1. Field of the Invention

One embodiment of the present invention relates to a light-emitting device, a light-emitting apparatus, a light-emitting and light-receiving apparatus, a display apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display apparatus, a liquid crystal display apparatus, a light-emitting apparatus, a lighting device, a power storage device, a memory device, an image capturing device, a driving method thereof, and a manufacturing method thereof.

### 2. Description of the Related Art

Recently, display apparatuses have been expected to be applied to a variety of uses. Usage examples of large-sized display apparatuses include a television device for home use (also referred to as TV or television receiver), digital signage, and a public information display (PID). In addition, a smartphone and a tablet terminal each including a touch panel, for example, are being developed as portable information terminals.

Higher-resolution display apparatuses have been required. For example, devices for virtual reality (VR), augmented reality (AR), substitutional reality (SR), or mixed reality (MR) are given as devices requiring high-resolution display apparatuses and have been actively developed.

Light-emitting apparatuses that include light-emitting devices (also referred to as light-emitting elements) have been developed as display apparatuses, for example. Light-emitting devices utilizing electroluminescence (hereinafter referred to as EL; such devices are also referred to as EL devices or EL elements) have features such as ease of reduction in thickness and weight, high-speed response to input signals, and driving with a constant DC voltage power source, and have been used in display apparatuses.

Patent Document 1 discloses a display apparatus for VR that includes an organic EL device (also referred to as organic EL element). Patent Document 2 discloses a light-emitting device that has a low driving voltage and high reliability and includes an electron-injection layer formed using a mixed film of a transition metal and an organic compound having an unshared electron pair.

### REFERENCES

### Patent Documents

[Patent Document 1] International Publication No. WO2018/087625
[Patent Document 2] Japanese Published Patent Application No. 2018-201012

### SUMMARY OF THE INVENTION

As a method for forming an organic semiconductor film in a predetermined shape, a vacuum evaporation method with a metal mask (mask vapor deposition) is widely used. However, in these days of higher density and higher resolution, mask vapor deposition has come close to the limit of increasing the resolution for various reasons such as the alignment accuracy and the distance between the mask and the substrate. By contrast, a finer pattern can be formed by shape processing of an organic semiconductor film by a lithography method. Moreover, because of the ease of large-area processing in this method, the processing of an organic semiconductor film by a lithography method is being researched.

At the time of processing an organic semiconductor film by a lithography method, the influence of oxygen or water in the air and a chemical solution or water used during the process has sometimes caused a light-emitting device to have a significantly increased driving voltage or greatly reduced current efficiency.

An object of one embodiment of the present invention is to provide a light-emitting device with favorable characteristics. Another object of one embodiment of the present invention is to provide a light-emitting device with high reliability. Another object of one embodiment of the present invention is to provide a novel light-emitting device.

Note that the description of these objects does not preclude the existence of other objects. One embodiment of the present invention does not need to achieve all of these objects. Other objects will be apparent from and can be derived from the description of the specification, the drawings, the claims, and the like.

One embodiment of the present invention is a light-emitting device which includes a first electrode, a second electrode, and an organic compound layer and in which the organic compound layer is located between the first electrode and the second electrode; the organic compound layer includes a first light-emitting layer, a second light-emitting layer, and an intermediate layer; the intermediate layer is located between the first light-emitting layer and the second light-emitting layer; the intermediate layer includes a metal, a first organic compound, and a second organic compound; the first organic compound includes a phenanthroline ring having an electron-donating group; the second organic compound includes a π-electron deficient heteroaromatic ring; and the first organic compound and the metal form a donor level by interacting with each other and function as an electron donor with respect to the second organic compound.

Another embodiment of the present invention is a light-emitting device which includes a first electrode, a second electrode, and an organic compound layer and in which the organic compound layer is located between the first electrode and the second electrode; the organic compound layer includes a first light-emitting layer, a second light-emitting layer, and an intermediate layer; the intermediate layer is located between the first light-emitting layer and the second light-emitting layer; the intermediate layer includes a metal, a first organic compound, and a second organic compound; the first organic compound includes a phenanthroline ring having an electron-donating group; the second organic compound includes a π-electron deficient heteroaromatic ring; and a LUMO level of the second organic compound is lower than a LUMO level of the first organic compound.

Another embodiment of the present invention is a light-emitting device, a plurality of the light-emitting devices being over one insulating surface, the light-emitting device including a first electrode, a second electrode, and an organic compound layer. The first electrodes of the plurality of light-emitting devices are separate from each other. The second electrode is shared by the plurality of light-emitting devices. The organic compound layer is located between the first electrode and the second electrode. The organic compound layer includes a first light-emitting layer, a second light-emitting layer, and an intermediate layer. The intermediate layer is located between the first light-emitting layer and the second light-emitting layer. The first light-emitting layers of the plurality of light-emitting devices are separate from each other. The intermediate layers of the plurality of light-emitting devices are separate from each other. The second light-emitting layers of the plurality of light-emitting devices are separate from each other. Contours of the first light-emitting layer, the intermediate layer, and the second light-emitting layer are aligned or substantially aligned with each other in each of the plurality of light-emitting devices. The intermediate layer includes a first layer. The first layer is a mixed layer including a metal, a first organic compound, and a second organic compound. The first organic compound includes a phenanthroline ring having an electron-donating group. The second organic compound includes a π-electron deficient heteroaromatic ring.

Another embodiment of the present invention is a light-emitting device with any of the above structures in which the electron-donating group is at least one of an alkyl group, an alkoxy group, an aryloxy group, an alkylamino group, an arylamino group, and a heterocyclic amino group.

Another embodiment of the present invention is a light-emitting device with any of the above structures in which the phenanthroline ring is a 1,10-phenanthroline ring and the electron-donating group is at at least one of a 4-position and a 7-position of the 1,10-phenanthroline ring.

Another embodiment of the present invention is a light-emitting device with any of the above structures in which an acid dissociation constant pKₐ of the first organic compound is higher than or equal to 8.

Another embodiment of the present invention is a light-emitting device, a plurality of the light-emitting devices being over one insulating surface, the light-emitting device including a first electrode, a second electrode, and an organic compound layer. The first electrodes of the plurality of light-emitting devices are separate from each other. The second electrode is shared by the plurality of light-emitting devices. The organic compound layer is located between the first electrode and the second electrode. The organic compound layer includes a first light-emitting layer, a second light-emitting layer, and an intermediate layer. The intermediate layer is located between the first light-emitting layer and the second light-emitting layer. The first light-emitting layers of the plurality of light-emitting devices are separate from each other. The intermediate layers of the plurality of light-emitting devices are separate from each other. The second light-emitting layers of the plurality of light-emitting devices are separate from each other. Contours of the first light-emitting layer, the intermediate layer, and the second light-emitting layer are aligned or substantially aligned with each other in each of the plurality of light-emitting devices. The intermediate layer includes a first layer. The first layer is a mixed layer including a metal, a first organic compound, and a second organic compound. The first organic compound includes a phenanthroline ring. A minimum value of an electrostatic potential of the first organic compound is smaller than or equal to −0.085 Eₕ when a threshold value of electron density distribution is 0.0004 e/a₀³. The second organic compound includes a π-electron deficient heteroaromatic ring.

Another embodiment of the present invention is a light-emitting device with any of the above structures in which spin density of the first layer measured by an electron spin resonance method is higher than or equal to 5×10¹⁶ spins/cm³.

Another embodiment of the present invention is a light-emitting device with the above structure in which spin density of a mixed film including the metal and the first organic compound is lower than or equal to 2×10¹⁶ spins/cm³ when measured by an electron spin resonance method. Another embodiment of the present invention is a light-emitting device with the above structure in which spin density of a mixed film including the metal and the second organic compound is lower than or equal to 2×10¹⁶ spins/cm³ when measured by an electron spin resonance method. Another embodiment of the present invention is a light-emitting device with the above structure in which spin density of a mixed film including the first organic compound and the second organic compound is lower than or equal to 2×10¹⁶ spins/cm³ when measured by an electron spin resonance method.

Another embodiment of the present invention is a light-emitting device with any of the above structures in which the second organic compound includes a phenanthroline ring.

Another embodiment of the present invention is a light-emitting device with any of the above structures in which a glass transition temperature (T_{g}) of the second organic compound is higher than or equal to 100° C.

Another embodiment of the present invention is a light-emitting device with any of the above structures in which a LUMO level of the second organic compound is lower than a LUMO level of the first organic compound.

Another embodiment of the present invention is a light-emitting device with the above structure in which the second organic compound has an electron-transport property.

Another embodiment of the present invention is a light-emitting device with the above structure in which an acid dissociation constant pKₐ of the second organic compound is higher than or equal to 4 and lower than 8.

Another embodiment of the present invention is a light-emitting device with the above structure in which a LUMO level of the second organic compound is higher than or equal to −3.0 eV and lower than or equal to −2.0 eV.

Another embodiment of the present invention is a light-emitting device with any of the above structures in which the metal belongs to Group 1, 3, 11, or 13 in a periodic table.

Another embodiment of the present invention is a light-emitting device with the above structure in which the metal is a main-group metal.

Another embodiment of the present invention is a light-emitting device with the above structure in which the metal is a transition metal.

Another embodiment of the present invention is a light-emitting device with any of the above structures in which the intermediate layer includes a second layer in addition to the first layer; the second layer includes a third organic compound and a fourth organic compound; the third organic compound includes a π-electron rich heteroaromatic ring or an aromatic amine; the fourth organic compound has one or more halogen groups, one or more cyano groups, or both one or more halogen groups and one or more cyano groups; and a total number of the one or more halogen groups, the one or more cyano groups, or both the one or more halogen groups and the one or more cyano groups is four or more.

Another embodiment of the present invention is a light-emitting device with the above structure in which spin density of the second layer measured by an electron spin resonance method is higher than or equal to 1×10¹⁷ spins/cm³.

Another embodiment of the present invention is a light-emitting device with the above structure in which the third organic compound has a hole-transport property and the fourth organic compound has an acceptor property with respect to the third organic compound.

Another embodiment of the present invention is a light-emitting apparatus that includes a light-emitting device with any of the above structures and a transistor or a substrate.

Another embodiment of the present invention is an electronic appliance that includes a light-emitting apparatus with the above structure and a sensor portion, an input portion, or a communication portion.

Note that the light-emitting apparatus in this specification includes, in its category, an image display device that uses a light-emitting device. The light-emitting apparatus may also include a module in which a light-emitting device over a substrate is provided with a connector such as an anisotropic conductive film or a tape carrier package (TCP), a module in which a printed wiring board is further provided at the end of the TCP, and a module in which an integrated circuit (IC) is directly mounted on a light-emitting device by a chip on glass (COG) method. Furthermore, a lighting device or the like may include the light-emitting apparatus.

One embodiment can provide a light-emitting device with favorable characteristics. Another embodiment can provide a light-emitting device with high reliability. Another embodiment can provide a novel light-emitting device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIG. 1 shows light-emitting devices;

FIGS. 2A to 2D each show a light-emitting device;

FIGS. 3A and 3B are, respectively, a top view and a cross-sectional view of a light-emitting apparatus;

FIGS. 4A to 4D each show a light-emitting device;

FIGS. 5A to 5E are cross-sectional views showing an example of a method for manufacturing a display apparatus;

FIGS. 6A to 6D are cross-sectional views showing an example of a method for manufacturing a display apparatus;

FIGS. 7A to 7D are cross-sectional views showing an example of a method for manufacturing a display apparatus;

FIGS. 8A to 8C are cross-sectional views showing an example of a method for manufacturing a display apparatus;

FIGS. 9A to 9C are cross-sectional views showing an example of a method for manufacturing a display apparatus;

FIGS. 10A to 10C are cross-sectional views showing an example of a method for manufacturing a display apparatus;

FIGS. 11A and 11B are perspective views showing a structure example of a display module;

FIGS. 12A and 12B are cross-sectional views showing structure examples of a display apparatus;

FIGS. 13A to 13D show examples of electronic appliances;

FIGS. 14A to 14F show examples of electronic appliances;

FIG. 15 shows luminance-current density characteristics of a light-emitting device 1 and a reference light-emitting device 4;

FIG. 16 shows luminance-voltage characteristics of the light-emitting device 1 and the reference light-emitting device 4;

FIG. 17 shows current efficiency-luminance characteristics of the light-emitting device 1 and the reference light-emitting device 4;

FIG. 18 shows current density-voltage characteristics of the light-emitting device 1 and the reference light-emitting device 4;

FIG. 19 shows electroluminescence spectra of the light-emitting device 1 and the reference light-emitting device 4;

FIG. 20 shows luminance-current density characteristics of a light-emitting device 2 and a reference light-emitting device 5;

FIG. 21 shows luminance-voltage characteristics of the light-emitting device 2 and the reference light-emitting device 5;

FIG. 22 shows current efficiency-luminance characteristics of the light-emitting device 2 and the reference light-emitting device 5;

FIG. 23 shows current density-voltage characteristics of the light-emitting device 2 and the reference light-emitting device 5;

FIG. 24 shows electroluminescence spectra of the light-emitting device 2 and the reference light-emitting device 5;

FIG. 25 shows luminance-current density characteristics of a light-emitting device 3 and a reference light-emitting device 6;

FIG. 26 shows luminance-voltage characteristics of the light-emitting device 3 and the reference light-emitting device 6;

FIG. 27 shows current efficiency-luminance characteristics of the light-emitting device 3 and the reference light-emitting device 6;

FIG. 28 shows current density-voltage characteristics of the light-emitting device 3 and the reference light-emitting device 6;

FIG. 29 shows electroluminescence spectra of the light-emitting device 3 and the reference light-emitting device 6;

FIGS. 30A to 30H are optical micrographs of light-emitting devices;

FIG. 31 shows an ESR spectrum of a sample 1;

FIG. 32 shows an ESR spectrum of a sample 2;

FIG. 33 shows an ESR spectrum of a comparative sample 3;

FIG. 34 shows an ESR spectrum of a comparative sample 4;

FIG. 35 shows an ESR spectrum of a comparative sample 5;

FIG. 36 shows an ESR spectrum of a comparative sample 6;

FIG. 37 shows an ESR spectrum of a comparative sample 7;

FIG. 38 shows an ESR spectrum of a comparative sample 8;

FIG. 39 shows an ESR spectrum of a comparative sample 9;

FIGS. 40A to 40C show results of analyzing spin density distribution in composite materials in a ground state;

FIGS. 41A and 41B show results of analyzing electrostatic potential maps of organic compounds in a ground state;

FIGS. 42A to 42C show results of analyzing electrostatic potential maps of composite materials in a ground state;

FIG. 43 shows an ESR spectrum of a thin film obtained by co-evaporation of PCBBiF and OCHD-003;

FIG. 44 shows luminance-current density characteristics of a light-emitting device 9G and a comparative light-emitting device 10G;

FIG. 45 shows luminance-voltage characteristics of the light-emitting device 9G and the comparative light-emitting device 10G;

FIG. 46 shows current efficiency-current density characteristics of the light-emitting device 9G and the comparative light-emitting device 10G;

FIG. 47 shows current density-voltage characteristics of the light-emitting device 9G and the comparative light-emitting device 10G;

FIG. 48 shows electroluminescence spectra of the light-emitting device 9G and the comparative light-emitting device 10G;

FIG. 49 shows driving time-dependent changes in luminance of the light-emitting device 9G and the comparative light-emitting device 10G;

FIG. 50 shows luminance-current density characteristics of a light-emitting device 9R and a comparative light-emitting device 10R;

FIG. 51 shows luminance-voltage characteristics of the light-emitting device 9R and the comparative light-emitting device 10R;

FIG. 52 shows current efficiency-current density characteristics of the light-emitting device 9R and the comparative light-emitting device 10R;

FIG. 53 shows current density-voltage characteristics of the light-emitting device 9R and the comparative light-emitting device 10R;

FIG. 54 shows electroluminescence spectra of the light-emitting device 9R and the comparative light-emitting device 10R;

FIG. 55 shows driving time-dependent changes in luminance of the light-emitting device 9R and the comparative light-emitting device 10R;

FIG. 56 shows luminance-current density characteristics of a light-emitting device 9B and a comparative light-emitting device 10B;

FIG. 57 shows luminance-voltage characteristics of the light-emitting device 9B and the comparative light-emitting device 10B;

FIG. 58 shows current efficiency-current density characteristics of the light-emitting device 9B and the comparative light-emitting device 10B;

FIG. 59 shows current density-voltage characteristics of the light-emitting device 9B and the comparative light-emitting device 10B;

FIG. 60 shows electroluminescence spectra of the light-emitting device 9B and the comparative light-emitting device 10B;

FIG. 61 shows blue index-current density characteristics of the light-emitting device 9B and the comparative light-emitting device 10B;

FIG. 62 shows driving time-dependent changes in luminance of the light-emitting device 9B and the comparative light-emitting device 10B;

FIG. 63 shows luminance-current density characteristics of a comparative light-emitting device 11G;

FIG. 64 shows luminance-voltage characteristics of the comparative light-emitting device 11G;

FIG. 65 shows current efficiency-current density characteristics of the comparative light-emitting device 11G;

FIG. 66 shows current density-voltage characteristics of the comparative light-emitting device 11G;

FIG. 67 shows external quantum efficiency-current density characteristics of the comparative light-emitting device 11G;

FIG. 68 shows an electroluminescence spectrum of the comparative light-emitting device 11G;

FIG. 69 shows a driving time-dependent change in luminance of the comparative light-emitting device 11G;

FIG. 70 shows luminance-current density characteristics of a comparative light-emitting device 11R;

FIG. 71 shows luminance-voltage characteristics of the comparative light-emitting device 11R;

FIG. 72 shows current efficiency-current density characteristics of the comparative light-emitting device 11R;

FIG. 73 shows current density-voltage characteristics of the comparative light-emitting device 11R;

FIG. 74 shows external quantum efficiency-current density characteristics of the comparative light-emitting device 11R;

FIG. 75 shows an electroluminescence spectrum of the comparative light-emitting device 11R;

FIG. 76 shows a driving time-dependent change in luminance of the comparative light-emitting device 11R;

FIG. 77 shows luminance-current density characteristics of a comparative light-emitting device 11B;

FIG. 78 shows luminance-voltage characteristics of the comparative light-emitting device 11B;

FIG. 79 shows current efficiency-current density characteristics of the comparative light-emitting device 11B;

FIG. 80 shows current density-voltage characteristics of the comparative light-emitting device 11B;

FIG. 81 shows external quantum efficiency-current density characteristics of the comparative light-emitting device 11B;

FIG. 82 shows blue index-current density characteristics of the comparative light-emitting device 11B;

FIG. 83 shows an electroluminescence spectrum of the comparative light-emitting device 11B;

FIG. 84 shows a driving time-dependent change in luminance of the comparative light-emitting device 11B;

FIG. 85 shows luminance-current density characteristics of a light-emitting device 12, a comparative light-emitting device 13, and a comparative light-emitting device 14;

FIG. 86 shows luminance-voltage characteristics of the light-emitting device 12, the comparative light-emitting device 13, and the comparative light-emitting device 14;

FIG. 87 shows current efficiency-current density characteristics of the light-emitting device 12, the comparative light-emitting device 13, and the comparative light-emitting device 14;

FIG. 88 shows current density-voltage characteristics of the light-emitting device 12, the comparative light-emitting device 13, and the comparative light-emitting device 14; and

FIG. 89 shows electroluminescence spectra of the light-emitting device 12, the comparative light-emitting device 13, and the comparative light-emitting device 14.

### DETAILED DESCRIPTION OF THE INVENTION

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the terms “film” and “layer” can be used interchangeably depending on the case or the circumstances. For example, the term “conductive layer” can be replaced with the term “conductive film”. For another example, the term “insulating film” can be replaced with the term “insulating layer”.

In this specification and the like, a device formed using a metal mask or a fine metal mask (FMM) is sometimes referred to as a device having a metal mask (MM) structure. In this specification and the like, a device formed without using a metal mask or an FMM is sometimes referred to as a device having a metal maskless (MML) structure.

In this specification and the like, a light-emitting device (also referred to as a light-emitting element) includes an EL layer (also referred to as an organic compound layer) between a pair of electrodes. The EL layer includes at least a light-emitting layer.

In this specification and the like, a tapered shape indicates a shape in which at least part of a side surface of a component is inclined to a substrate surface. For example, a tapered shape preferably includes a region where the angle formed by the inclined side surface and the substrate surface (such an angle is also referred to as a taper angle) is less than 90°. Note that the side surface of the component and the substrate surface are not necessarily completely flat, and may have a substantially planar shape with a small curvature or slight unevenness.

Note that the light-emitting apparatus in this specification includes, in its category, an image display device that uses an organic EL device. The light-emitting apparatus may also include a module in which an organic EL device is provided with a connector such as an anisotropic conductive film or a tape carrier package (TCP), a module in which a printed wiring board is further provided at the end of the TCP, and a module in which an integrated circuit (IC) is directly mounted on an organic EL device by a chip on glass (COG) method. Furthermore, a lighting device or the like may include the light-emitting apparatus.

### Embodiment 1

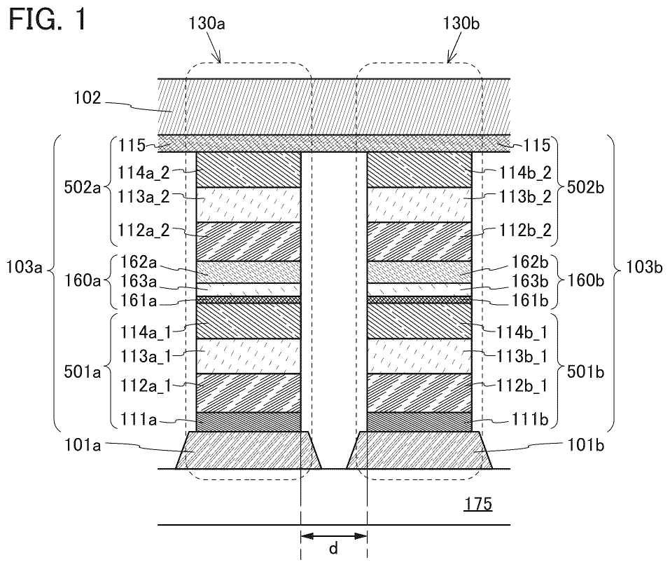

In this embodiment, a light-emitting device of one embodiment of the present invention will be described with reference to FIG. 1.

For description of a light-emitting device of one embodiment of the present invention, the schematic view of FIG. 1 illustrates light-emitting devices 130a and 130b, which are formed over one insulating surface to be adjacent to each other and are included in a light-emitting apparatus. In each of the light-emitting devices 130a and 130b, part of an organic compound layer is formed through processing by a lithography method.

The light-emitting device 130a is located over an insulating layer 175 and includes a first electrode 101a that includes an anode, a second electrode 102 that includes a cathode, and an organic compound layer 103a. The organic compound layer 103a is located between the first electrode 101a and the second electrode 102. In the organic compound layer 103a, a first light-emitting unit 501a and a second light-emitting unit 502a are stacked with an intermediate layer 160a sandwiched therebetween. The first light-emitting unit 501a includes a first light-emitting layer 113a_1. The intermediate layer 160a includes a first layer 161a and a second layer 162a. The second light-emitting unit 502a includes a second light-emitting layer 113a_2 and an electron-injection layer 115. It can be said that the intermediate layer 160a is located between the first light-emitting layer 113a_1 and the second light-emitting layer 113a_2.

In the organic compound layer 103a of the light-emitting device 130a, layers other than the electron-injection layer 115 are formed through processing by a lithography method. Thus, the layers other than the electron-injection layer 115 in the organic compound layer 103a are separate from those in the organic compound layer of the adjacent light-emitting device 130b. End portions (contours) of the layers other than the electron-injection layer 115 in the organic compound layer 103a are aligned or substantially aligned with each other in a direction perpendicular to a substrate. In other words, the first light-emitting layer 113a_1, the intermediate layer 160a (the first layer 161a and the second layer 162a), and the second light-emitting layer 113a_2 are separate from a first light-emitting layer 113b_1, an intermediate layer 160b (a first layer 161b and a second layer 162b), and a second light-emitting layer 113b_2. End portions (contours) of the first light-emitting layer 113a_1, the intermediate layer 160a (the first layer 161a and the second layer 162a), and the second light-emitting layer 113a_2 are aligned or substantially aligned with each other in a direction perpendicular to the substrate.

The light-emitting device 130b is located over the insulating layer 175 and includes a first electrode 101b that includes an anode, the second electrode 102 that includes the cathode, and an organic compound layer 103b. The organic compound layer 103b is located between the first electrode 101b and the second electrode 102. In the organic compound layer 103b, a first light-emitting unit 501b and a second light-emitting unit 502b are stacked with the intermediate layer 160b sandwiched therebetween. The first light-emitting unit 501b includes the first light-emitting layer 113b_1. The intermediate layer 160b includes the first layer 161b and the second layer 162b. The second light-emitting unit 502b includes the second light-emitting layer 113b_2 and the electron-injection layer 115. It can be said that the intermediate layer 160b is located between the first light-emitting layer 113b_1 and the second light-emitting layer 113b_2.

In the organic compound layer 103b of the light-emitting device 130b, layers other than the electron-injection layer 115 are formed through processing by a lithography method. Thus, the layers other than the electron-injection layer 115 in the organic compound layer 103b are separate from those in the organic compound layer of the adjacent light-emitting device 130a. End portions (contours) of the layers other than the electron-injection layer 115 in the organic compound layer 103b are aligned or substantially aligned with each other in a direction perpendicular to the substrate. In other words, the first light-emitting layer 113b_1, the intermediate layer 160b (the first layer 161b and the second layer 162b), and the second light-emitting layer 113b_2 are separate from the first light-emitting layer 113a_1, the intermediate layer 160a (the first layer 161a and the second layer 162a), and the second light-emitting layer 113a_2. End portions (contours) of the first light-emitting layer 113b_1, the intermediate layer 160b (the first layer 161b and the second layer 162b), and the second light-emitting layer 113b_2 are aligned or substantially aligned with each other in a direction perpendicular to the substrate.

The electron-injection layer 115 and the second electrode 102 are preferably formed after the layers of the organic compound layer 103a other than the electron-injection layer 115 and the layers of the organic compound layer 103b other than the electron-injection layer 115 are formed through processing by a lithography method. In other words, the electron-injection layer 115 and the second electrode 102 are each preferably a continuous layer shared by the light-emitting devices 130a and 130b.

The electron-injection layer 115 is preferably formed using a donor substance (also referred to as an electron donor), in which case the driving voltages of the light-emitting devices can be reduced. Typical examples of the donor substance include alkali metals such as lithium (Li), which have a low work function, and compounds of the alkali metals.

In the case where processing by a lithography method is performed in a state where an electron-injection layer including such a donor substance serves as an interface of an organic compound layer, the influence of oxygen or water in the air and a chemical solution or water used during the process sometimes causes a light-emitting device to have a significantly increased driving voltage or greatly reduced current efficiency. However, in one embodiment of the present invention, since the electron-injection layer 115 is formed after the layers other than the electron-injection layer 115 are formed through processing by a lithography method, using a donor substance for the electron-injection layer 115 does not cause deterioration of the characteristics of the light-emitting devices.

In the case where the organic compound layers are formed through processing by a lithography method, a distance d between the layers of the organic compound layer 103a other than the electron-injection layer 115 and the layers of the organic compound layer 103b other than the electron-injection layer 115 can be shorter than the distance d in the case of employing mask vapor deposition. Specifically, the distance d can be reduced to less than 10 μm, less than or equal to 8 μm, less than or equal to 5 μm, less than or equal to 3 μm, less than or equal to 2 μm, less than or equal to 1.5 μm, less than or equal to 1 μm, or less than or equal to 0.5 μm. Using a light exposure apparatus for LSI can further shorten the distance d to less than or equal to 500 nm, less than or equal to 200 nm, less than or equal to 100 nm, or even less than or equal to 50 nm, for example, in a process over a Si wafer.

It is preferable that an insulating layer be provided in the gap between the layers of the organic compound layer 103a other than the electron-injection layer 115 and the layers of the organic compound layer 103b other than the electron-injection layer 115 to separate the layers of the organic compound layer 103a other than the electron-injection layer 115 from the layers of the organic compound layer 103b other than the electron-injection layer 115. In that case, there is a region where the insulating layer is in contact with the electron-injection layer 115 or the second electrode 102.

In the light-emitting device 130a, the first light-emitting unit 501a preferably includes a hole-injection layer 111a, a first hole-transport layer 112a_1, and a first electron-transport layer 114a_1 in addition to the first light-emitting layer 113a_1. The second light-emitting unit 502a preferably includes a second hole-transport layer 112a_2 and a second electron-transport layer 114a_2 in addition to the second light-emitting layer 113a_2 and the electron-injection layer 115. The intermediate layer 160a can include a third layer 163a between the first layer 161a and the second layer 162a. In the case where the surface of the light-emitting unit on the anode side is in contact with the intermediate layer 160a as in the second light-emitting unit 502a, the second layer 162a of the intermediate layer 160a, which is located on the cathode side, can also function as a hole-injection layer of the second light-emitting unit 502a, and thus, providing a hole-injection layer in such a light-emitting unit is optional.

In the light-emitting device 130b, the first light-emitting unit 501b preferably includes a hole-injection layer 111b, a first hole-transport layer 112b_1, and a first electron-transport layer 114b_1 in addition to the first light-emitting layer 113b_1. The second light-emitting unit 502b preferably includes a second hole-transport layer 112b_2 and a second electron-transport layer 114b_2 in addition to the second light-emitting layer 113b_2 and the electron-injection layer 115. The intermediate layer 160b can include a third layer 163b between the first layer 161b and the second layer 162b. In the case where the surface of the light-emitting unit on the anode side is in contact with the intermediate layer 160b as in the second light-emitting unit 502b, the second layer 162b of the intermediate layer 160b, which is located on the cathode side, can also function as a hole-injection layer of the second light-emitting unit 502b, and thus, providing a hole-injection layer in such a light-emitting unit is optional.

As illustrated in FIG. 1, the uppermost one of the layers of the organic compound layer 103a other than the electron-injection layer 115 is preferably the second electron-transport layer 114a_2. Similarly, the uppermost one of the layers of the organic compound layer 103b other than the electron-injection layer 115 is preferably the second electron-transport layer 114b_2. The influence of oxygen or water in the air and a chemical solution or water used during the process can be smaller in the case where processing by a lithography method is performed at the interface on the second electron-transport layer 114a_2 and the second electron-transport layer 114b_2 than in the case where processing is performed at the interface on the second light-emitting layer 113a_2 and the second light-emitting layer 113b_2. Therefore, when the uppermost one of the layers of each organic compound layer other than the electron-injection layer 115 is the electron-transport layer, deterioration of the characteristics of the light-emitting devices due to the fabrication by a lithography method can be more easily avoided; processing by a lithography method is preferably performed at least above the second light-emitting layer 113a_2 and the second light-emitting layer 113b_2.

Although FIG. 1 illustrates an example in which each of the organic compound layers includes two light-emitting units, one embodiment of the present invention is not limited to this example. Each of the organic compound layers may include three or more light-emitting units. When a plurality of light-emitting units are stacked between a pair of electrodes with an intermediate layer sandwiched between the plurality of light-emitting units, the light-emitting device can perform high-luminance light emission with the current density kept low and can have high reliability. In addition, the light-emitting device can have low power consumption. Although not illustrated in FIG. 1, each of the light-emitting units may include a hole-injection layer, a hole-transport layer, an electron-blocking layer, a hole-blocking layer, an electron-transport layer, an electron-injection layer, or the like in addition to the above-described components. Each layer may be a stack of two or more layers.

Note that in this specification, description referring to the structure of one of the light-emitting devices 130a and 130b can apply to the structure of the other of the light-emitting devices 130a and 130b.

The intermediate layer 160a sandwiched between the first light-emitting unit 501a and the second light-emitting unit 502a injects electrons into one of the first light-emitting unit 501a and the second light-emitting unit 502a and injects holes into the other of the first light-emitting unit 501a and the second light-emitting unit 502a when voltage is applied between the first electrode 101a and the second electrode 102, for example. When voltage is applied such that the potential of the second electrode 102 is higher than that of the first electrode 101a in FIG. 1, for example, the intermediate layer 160a injects electrons into the first light-emitting unit 501a and injects holes into the second light-emitting unit 502a.

In the light-emitting device 130a illustrated as an example in FIG. 1, when voltage is applied between a pair of electrodes (the first electrode 101a and the second electrode 102), electrons are injected from the cathode into the electron-injection layer 115 and holes are injected from the anode into the hole-injection layer 111a, so that current flows. Furthermore, electrons are injected from the first layer 161a of the intermediate layer 160a located on the anode side into the first electron-transport layer 114a_1 of the first light-emitting unit 501a, and holes are injected from the second layer 162a of the intermediate layer 160a located on the cathode side into the second hole-transport layer 112a_2 of the second light-emitting unit 502a. By recombination of the injected carriers (electrons and holes), excitons are formed. When carriers (electrons and holes) recombine and excitons are formed in the first light-emitting layer 113a_1 and the second light-emitting layer 113a_2 including light-emitting materials, the light-emitting materials included in the first light-emitting layer 113a_1 and the second light-emitting layer 113a_2 are brought into an excited state, causing light emission from the light-emitting materials.

It is preferable that the first layer 161a of the intermediate layer 160a located on the anode side be adjacent to the first electron-transport layer 114a_1 and be provided between the first electron-transport layer 114a_1 and the second light-emitting unit 502a as illustrated in FIG. 1. With such a structure, electrons can be efficiently injected into the first light-emitting unit 501a.

For a lower driving voltage and more efficient light emission of the light-emitting device, a structure is preferably employed in which a barrier against electron injection from the intermediate layer 160a into the first electron-transport layer 114a_1 is lowered and electrons generated in the intermediate layer 160a are smoothly injected and transported into the first electron-transport layer 114a_1. In view of this, an alkali metal or an alkaline earth metal, which has a low work function, or a compound of an alkali metal or an alkaline earth metal is generally used for the intermediate layer 160a. However, the metal and the compound easily deteriorate by oxygen or water in the air and water or a chemical solution used during the process by a lithography method, causing a light-emitting device to have a significantly increased driving voltage or greatly reduced current efficiency.

In view of the above, it is preferable that the intermediate layer be formed using a material resistant to oxygen and water in the air and water and a chemical solution used during the process by a lithography method, and it is accordingly preferable that the intermediate layer 160a be formed using a metal that is stable with respect to oxygen and water in the air and resistant to water and a chemical solution. However, such a metal, which is stable and has a low electron-injection property, may form an electron injection barrier between the intermediate layer 160a and the first electron-transport layer 114a_1, causing the light-emitting device to have an increased driving voltage and reduced emission efficiency, for example.

Thus, in one embodiment of the present invention, the first layer 161a of the intermediate layer 160a located on the anode side is formed using a composite material formed by a combination of a metal, a first organic compound having an electron-donating property and unshared electron pairs, and a second organic compound having an electron-transport property. Interaction between the metal and the first organic compound forms a donor level (a singly occupied molecular orbital (SOMO) level or a highest occupied molecular orbital (HOMO) level), and the combination of the metal and the first organic compound functions as an electron donor with respect to the second organic compound. With such a structure, the intermediate layer can be formed to have a favorable electron-injection property and resistance to oxygen and water in the air and water and a chemical solution used during the process by a lithography method; thus, the light-emitting device can have a reduced driving voltage and high emission efficiency.

Since a metal with a low work function typified by an alkali metal and an alkaline earth metal and a compound of the metal with a low work function have high reactivity with oxygen and water, using the metal or the compound for a light-emitting device fabricated through processing by a lithography method may cause a reduction in emission efficiency, an increase in driving voltage, a reduction in driving lifetime, generation of shrinkage (a non-emission region at an end portion of a light-emitting portion), or the like, leading to deterioration in the characteristics or a reduction in the reliability of the light-emitting device. However, in one embodiment of the present invention, even when an alkali metal, an alkaline earth metal, or a compound of an alkali metal or an alkaline earth metal is used, interaction between the alkali metal, the alkaline earth metal, or the compound, the first organic compound having an electron-donating property and unshared electron pairs, and the second organic compound having an electron-transport property stabilizes the composite material, so that an intermediate layer having resistance to oxygen and water in the air and water and a chemical solution used during the process by a lithography method can be formed. When an alkali metal, an alkaline earth metal, or a compound of an alkali metal or an alkaline earth metal is used as the metal in one embodiment of the present invention, the donor level (SOMO level or HOMO level) that is formed by interaction between the alkali metal, the alkaline earth metal, or the compound and the first organic compound having an electron-donating property and unshared electron pairs can be a high energy level, facilitating electron donation to the second organic compound. This structure is preferable because it lowers a barrier against electron injection from the intermediate layer 160a into the first electron-transport layer 114a_1 and enables the electrons generated in the intermediate layer 160a to be injected and transported smoothly into the first electron-transport layer 114a_1.

As the metal in the light-emitting device of one embodiment of the present invention, it is possible to use any one of transition metals (metal elements belonging to Group 3 to Group 11) and main-group metal elements belonging to Group 12 to Group 14. These metals have low reactivity with oxygen and water in the air and water and a chemical solution used in a lithography process. Thus, using any of these metals in the light-emitting device is advantageous in that the metals hardly cause deterioration due to water and oxygen, which would be a matter of concern in the case of using a metal with a low work function. On the other hand, transition metals (metal elements belonging to Group 3 to Group 11) and main-group metal elements belonging to Group 12 to Group 14, which are stable and have a low electron-injection property, cause the light-emitting device to have reduced emission efficiency, an increased driving voltage, and a reduced driving lifetime, for example. However, in one embodiment of the present invention, even when any one of transition metals (metal elements belonging to Group 3 to Group 11) and main-group metal elements belonging to Group 12 to Group 14 is used, a donor level (SOMO level or HOMO level) is formed by interaction between the metal and the first organic compound having an electron-donating property and unshared electron pairs, and electrons are easily donated to the second organic compound having an electron-transport property. This structure lowers a barrier against electron injection from the intermediate layer 160a into the first electron-transport layer 114a_1 and enables the electrons generated in the intermediate layer 160a to be injected and transported smoothly into the first electron-transport layer 114a_1. The above structure is preferably employed, in which case an intermediate layer that has resistance to oxygen and water in the air and water and a chemical solution used during the process by a lithography method can be formed. Thus, one embodiment of the present invention can provide a light-emitting device having high moisture resistance, high water resistance, high oxygen resistance, high chemical resistance, a low driving voltage, and high emission efficiency.

In the interaction between the metal and the first organic compound having an electron-donating property and unshared electron pairs, the sum of the number of electrons of the compound and the number of electrons of the metal is preferably an odd number, in which case the stabilization energy is lower and a donor level (SOMO level or HOMO level) can be formed as a high energy level. Accordingly, in the case where the number of electrons of the compound is an even number, the metal preferably belongs to an odd-numbered group in the periodic table.

### <Estimation of Spin Density and Electrostatic Potential in Interaction Between Metal and Organic Compound by Quantum Chemical Calculation>

The spin density and the electrostatic potential (ESP) at the time of interaction between a metal, the first organic compound having an electron-donating property and unshared electron pairs, and the second organic compound having an electron-transport property were analyzed by quantum chemical calculation. Note that 4,7-di-1-pyrrolidinyl-1,10-phenanthroline (abbreviation: Pyrrd-Phen), 2,9-di(naphthalen-2-yl)-4,7-diphenyl-1,10-phenanthroline (abbreviation: NBPhen), and silver (Ag) were used as the first organic compound, the second organic compound, and the metal, respectively, in the calculation.

As the quantum chemistry computational program, Gaussian 09 was used. The calculation was performed using SGI 8600 manufactured by Hewlett Packard Enterprise. The most stable structures of the first organic compound alone in a ground state, the second organic compound alone in a ground state, a composite material of the first organic compound and the metal in a ground state, a composite material of the second organic compound and the metal in a ground state, and a composite material of the first organic compound, the second organic compound, and the metal in a ground state were calculated by the density functional theory (DFT). As basis functions, 6-311G(d,p) and LanL2DZ were used, and as a functional, B3LYP was used. In the DFT, the total energy is represented as the sum of potential energy, electrostatic energy between electrons, electronic kinetic energy, and exchange-correlation energy including all the complicated interactions between electrons. Also in the DFT, exchange-correlation interaction is approximated by a functional (a function of another function) of one electron potential represented in terms of electron density to enable highly accurate calculations.

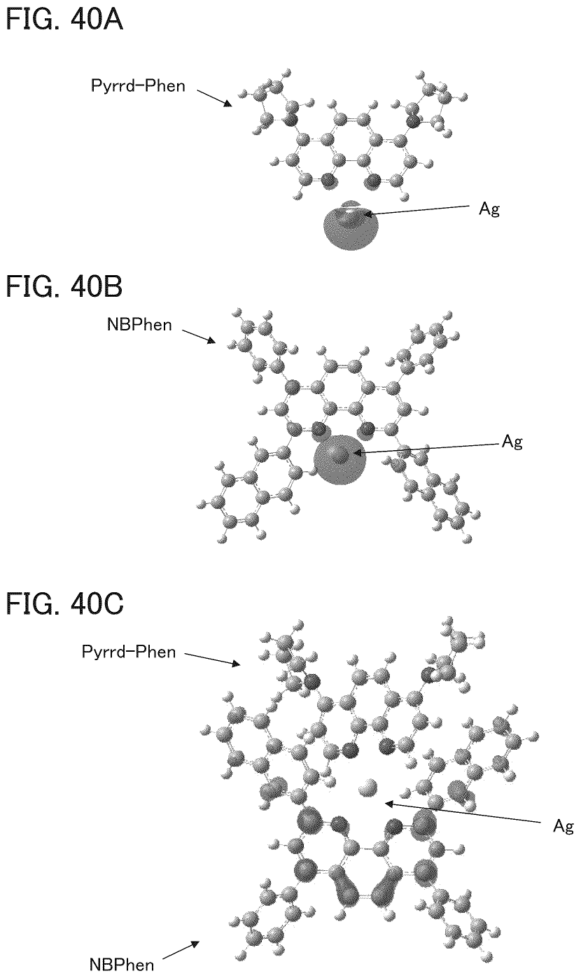

FIGS. 40A to 40C respectively show the analysis results of spin density distribution in the composite material of the first organic compound (Pyrrd-Phen) and the metal (Ag) in a ground state, the composite material of the second organic compound (NBPhen) and the metal (Ag) in a ground state, and the composite material of the first organic compound (Pyrrd-Phen), the second organic compound (NBPhen), and the metal (Ag) in a ground state. In the diagrams, spheres represent atoms included in the compounds, and clouds around some of the atoms represent spin density distribution at the time when the threshold value of electron density distribution in atomic units is 0.003 e/a₀³ (where e represents elementary charge (1 e=1.60218×10⁻¹⁹ C) and a₀ represents a Bohr radius (1 a₀=5.29177×10⁻¹¹ m)). The clouds represent localization of the doublet ground state of the compounds. Note that no spin density distribution is observed in the first organic compound (Pyrrd-Phen) in a ground state and the second organic compound (NBPhen) in a ground state because the ground states of the first organic compound and the second organic compound are singlet ground states.

In the composite material of the first organic compound (Pyrrd-Phen) and the metal (Ag) in the doublet ground state, the first organic compound (Pyrrd-Phen) interacts with the metal (Ag), and the metal (Ag) is coordinated to the two nitrogen atoms having unshared electron pairs (the nitrogen atoms (N) at the 1- and 10-positions) in the 1,10-phenanthroline ring of the first organic compound (Pyrrd-Phen), which leads to stabilization and the formation of the composite material. As illustrated in FIG. 40A, some spins attributed to an unpaired electron of the metal (Ag) are accordingly distributed over part of the 1,10-phenanthroline ring of the first organic compound (Pyrrd-Phen), particularly the two nitrogen atoms having unshared electron pairs (the nitrogen atoms (N) at the 1- and 10-positions). However, the interaction is weak, and thus, most spins are distributed over the metal (Ag).

In the composite material of the second organic compound (NBPhen) and the metal (Ag) in the doublet ground state, the second organic compound (NBPhen) interacts with the metal (Ag), and the metal (Ag) is coordinated to the two nitrogen atoms having unshared electron pairs (the nitrogen atoms (N) at the 1- and 10-positions) in the 1,10-phenanthroline ring of the second organic compound (NBPhen), which leads to stabilization and the formation of the composite material. As illustrated in FIG. 40B, some spins attributed to an unpaired electron of the metal (Ag) are accordingly distributed over part of the 1,10-phenanthroline ring of the second organic compound (NBPhen), particularly the two nitrogen atoms having unshared electron pairs (the nitrogen atoms (N) at the 1- and 10-positions). However, the interaction is weak, and thus, most spins are distributed over the metal (Ag).

Meanwhile, in the composite material of the first organic compound (Pyrrd-Phen), the second organic compound (NBPhen), and the metal (Ag), which is one embodiment of the present invention, in the doublet ground state, the first organic compound (Pyrrd-Phen), the second organic compound (NBPhen), and the metal (Ag) interact with one another, and the metal (Ag) is coordinated to the two nitrogen atoms having unshared electron pairs (the nitrogen atoms (N) at the 1- and 10-positions) in the 1,10-phenanthroline ring of the first organic compound (Pyrrd-Phen) and the two nitrogen atoms having unshared electron pairs (the nitrogen atoms (N) at the 1- and 10-positions) in the 1,10-phenanthroline ring of the second organic compound (NBPhen), which leads to stabilization and the formation of the composite material. As illustrated in FIG. 40C, spins attributed to an unpaired electron of the metal (Ag) are accordingly localized in the second organic compound (NBPhen). Furthermore, no spin density distribution is observed in the metal (Ag). It is thus found that the second organic compound (NBPhen) is in a radical anion state owing to the interaction between the first organic compound (Pyrrd-Phen), the second organic compound (NBPhen), and the metal (Ag).

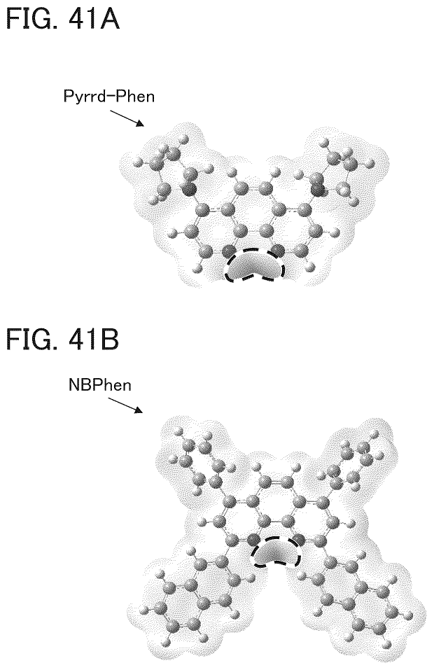

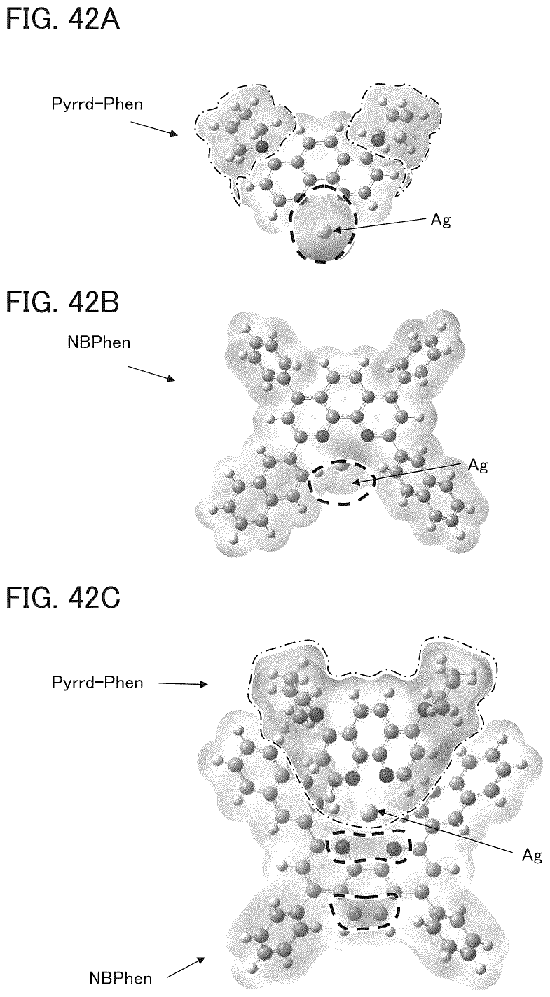

Next, FIG. 41A, FIG. 41B, FIG. 42A, FIG. 42B, and FIG. 42C respectively show the analysis results of the electrostatic potential maps of the first organic compound (Pyrrd-Phen) in a ground state, the second organic compound (NBPhen) in a ground state, the composite material of the first organic compound (Pyrrd-Phen) and the metal (Ag) in a ground state, the composite material of the second organic compound (NBPhen) and the metal (Ag) in a ground state, and the composite material of the first organic compound (Pyrrd-Phen), the second organic compound (NBPhen), and the metal (Ag) in a ground state. In the diagrams, spheres represent atoms included in the compounds, and clouds around some of the atoms represent electrostatic potentials in electron density distribution at the time when the threshold value of electron density distribution in atomic units is 0.003 e/a₀³. An electrostatic potential is the energy of interaction between positive point charge with unit quantity of electricity and electron distribution of a molecule. An electrostatic potential map denotes an electrostatic potential on an electron density isosurface in colors. In an electrostatic potential map, a region with a negative electrostatic potential is denoted in red, a region with a positive electrostatic potential is denoted in blue, an atom in the region with a negative electrostatic potential has negative charge, and an atom in the region with a positive electrostatic potential has positive charge. To show a region with a negative electrostatic potential and a region with a positive electrostatic potential in FIGS. 41A and 41B and FIGS. 42A to 42C, which were obtained by gray-scale conversion of electrostatic potential maps produced through analysis, the region with a negative electrostatic potential is surrounded by a thick dotted line, and the region with a positive electrostatic potential is surrounded by a thin dashed-dotted line. Note that portions that are denoted in deep red in the electrostatic potential maps before the gray-scale conversion are surrounded by the thick dotted lines in FIGS. 41A and 41B and FIGS. 42A to 42C, and portions that are denoted in deep blue in the electrostatic potential maps before the gray-scale conversion are surrounded by the thin dashed-dotted lines in FIGS. 41A and 41B and FIGS. 42A to 42C.

As shown in FIG. 41A, the electrostatic potential around the two nitrogen atoms having unshared electron pairs (the nitrogen atoms (N) at the 1- and 10-positions) in the 1,10-phenanthroline ring of the first organic compound (Pyrrd-Phen) in the singlet ground state is negative. The two N atoms each had a negative Mulliken partial charge of −0.29 e in atomic units. Accordingly, it is found that the two N atoms have negative partial charge.

As shown in FIG. 41B, the electrostatic potential around the two nitrogen atoms having unshared electron pairs (the nitrogen atoms (N) at the 1- and 10-positions) in the 1,10-phenanthroline ring of the second organic compound (NBPhen) in the singlet ground state is negative. The two N atoms each had a negative Mulliken partial charge of −0.34 e in atomic units. Accordingly, it is found that the two N atoms have negative partial charge.

In the composite material of the first organic compound (Pyrrd-Phen) and the metal (Ag) in the doublet ground state, the first organic compound (Pyrrd-Phen) interacts with the metal (Ag), and the metal (Ag) is coordinated to the two nitrogen atoms having unshared electron pairs (the nitrogen atoms (N) at the 1- and 10-positions) in the 1,10-phenanthroline ring of the first organic compound (Pyrrd-Phen), which leads to stabilization and the formation of the composite material. As shown in FIG. 42A, the electrostatic potential around the two nitrogen atoms having unshared electron pairs (the nitrogen atoms (N) at the 1- and 10-positions) in the 1,10-phenanthroline ring of the first organic compound (Pyrrd-Phen) and the metal (Ag) is accordingly negative. The two N atoms each had a negative Mulliken partial charge of −0.37 e in atomic units and the metal (Ag) had a negative Mulliken partial charge of −0.18 e in atomic units. Accordingly, it is found that the two N atoms and the Ag atom have negative partial charge.

In the composite material of the second organic compound (NBPhen) and the metal (Ag) in the doublet ground state, the second organic compound (NBPhen) interacts with the metal (Ag), and the metal (Ag) is coordinated to the two nitrogen atoms having unshared electron pairs (the nitrogen atoms (N) at the 1- and 10-positions) in the 1,10-phenanthroline ring of the second organic compound (NBPhen), which leads to stabilization and the formation of the composite material. As shown in FIG. 42B, the electrostatic potential around the two nitrogen atoms having unshared electron pairs (the nitrogen atoms (N) at the 1- and 10-positions) in the 1,10-phenanthroline ring of the second organic compound (NBPhen) and the metal (Ag) is accordingly negative. The two N atoms respectively had negative Mulliken partial charges of −0.45 e and −0.39 e in atomic units and the metal (Ag) had a negative Mulliken partial charge of −0.06 e in atomic units. Accordingly, it is found that the two N atoms and the Ag atom have negative partial charge.

Meanwhile, in the composite material of the first organic compound (Pyrrd-Phen), the second organic compound (NBPhen), and the metal (Ag), which is one embodiment of the present invention, in the doublet ground state, the first organic compound (Pyrrd-Phen), the second organic compound (NBPhen), and the metal (Ag) interact with one another, and the metal (Ag) is coordinated to the two nitrogen atoms having unshared electron pairs (the nitrogen atoms (N) at the 1- and 10-positions) in the 1,10-phenanthroline ring of the first organic compound (Pyrrd-Phen) and the two nitrogen atoms having unshared electron pairs (the nitrogen atoms (N) at the 1- and 10-positions) in the 1,10-phenanthroline ring of the second organic compound (NBPhen), which leads to stabilization and the formation of the composite material. Accordingly, as shown in FIG. 42C, a positive electrostatic potential is mainly distributed over the metal (Ag) and the first organic compound (Pyrrd-Phen), and a negative electrostatic potential is mainly distributed over the second organic compound (NBPhen). It is also found that the electrostatic potential around the two nitrogen atoms having unshared electron pairs (the nitrogen atoms (N) at the 1- and 10-positions) in the 1,10-phenanthroline ring of the second organic compound (NBPhen) is negative, whereas the electrostatic potential around the metal (Ag) is positive. The two N atoms each had a negative Mulliken partial charge of −0.52 e in atomic units, whereas the metal (Ag) had a positive Mulliken partial charge of 0.39 e in atomic units. These results show that charge of the Ag atom is distributed over the two N atoms.

From the above, it is found that the combination of the metal, the first organic compound having an electron-donating property and unshared electron pairs, and the second organic compound having an electron-transport property is such that interaction between the first organic compound and the metal forms a donor level and the metal and the first organic compound function as an electron donor with respect to the second organic compound. In one embodiment of the present invention, the intermediate layer formed using the composite material that includes this combination can have a favorable electron-injection property and resistance to oxygen and water in the air and water and a chemical solution used during the process by a lithography method; thus, the light-emitting device can have a reduced driving voltage and high emission efficiency.

### <Estimation of SOMO or HOMO Level in Interaction Between Metal and Organic Compound by Quantum Chemical Calculation>

Next, stabilization energy at the time of interaction between a metal, the first organic compound having an electron-donating property and unshared electron pairs, and the second organic compound having an electron-transport property and the SOMO or HOMO level formed at the time of the interaction were estimated by quantum chemical calculation.

As the quantum chemistry computational program, Gaussian 09 was used. The calculation was performed using SGI 8600 manufactured by Hewlett Packard Enterprise. First, the most stable structures of the first organic compound in a ground state, the second organic compound in a ground state, the metal in a ground state, the composite material of the first organic compound and the metal in a ground state, the composite material of the second organic compound and the metal in a ground state, and the composite material of the first organic compound, the second organic compound, and the metal in a ground state were calculated by the density functional theory (DFT). As basis functions, 6-311G(d,p) and LanL2DZ were used, and as a functional, B3LYP was used. Next, the stabilization energy was calculated by subtracting the sum of the total energy of the organic compound(s) alone and the total energy of the metal alone from the total energy of the composite material of the organic compound(s) and the metal. That is, (stabilization energy)=(the total energy of the composite material of the organic compound(s) and the metal)−(the total energy of the organic compound(s) alone)−(the total energy of the metal alone).

The stabilization energy of the composite material of the first organic compound and the metal, the composite material of the second organic compound and the metal, and the composite material of the first organic compound, the second organic compound, and the metal and the HOMO and SOMO levels of the first organic compound, the second organic compound, the composite material of the first organic compound and the metal, the composite material of the second organic compound and the metal, and the composite material of the first organic compound, the second organic compound, and the metal were calculated. The following tables show the calculation results. Note that the HOMO and SOMO levels in the tables are calculated values and may be different from measured values.

First, the results of the calculation conducted using 4,7-di-1-pyrrolidinyl-1,10-phenanthroline (abbreviation: Pyrrd-Phen) as the first organic compound, 2,2′-(1,3-phenylene)bis(9-phenyl-1,10-phenanthroline) (abbreviation: mPPhen2P) as the second organic compound, and zinc (Zn) as the metal are shown in the table below.

TABLE 1

| | Stabilization | HOMO |
|---|---|---|
| | energy (eV) | level (eV) |
| Pyrrd-Phen | — | −5.65 |
| mPPhen2P | — | −5.88 |
| Pyrrd-Phen + Zn | −0.0030 | −4.48 |
| mPPhen2P + Zn | −0.0012 | −5.85 |
| Pyrrd-Phen + | −0.92 | −2.43 |
| mPPhen2P + Zn | | |

The above table shows that the stabilization energy of the composite material of the metal (Zn) and the first organic compound (Pyrrd-Phen) and that of the composite material of the metal (Zn) and the second organic compound (mPPhen2P) each have a negative value, and that the difference between the stabilization energies is small although the energetic stability in the case of mixing the first or second organic compound and the metal is higher than the energetic stability of the first or second organic compound alone owing to the interaction between the organic compound and the metal. There is a small difference between the HOMO level formed at the time of the interaction and the HOMO level of the first organic compound (Pyrrd-Phen) or the second organic compound (mPPhen2P), indicating weak interaction between the metal and each of the first organic compound and the second organic compound.

Meanwhile, it is found that the stabilization energy of the composite material of the metal (Zn), the first organic compound (Pyrrd-Phen), and the second organic compound (mPPhen2P), which is one embodiment of the present invention, is lower than the stabilization energy of the composite material of the metal (Zn) and the first organic compound (Pyrrd-Phen) and the stabilization energy of the composite material of the metal (Zn) and the second organic compound (mPPhen2P), and that the composite material of one embodiment of the present invention is energetically stable. As described above, the stabilization energy of the composite material of the first organic compound, the second organic compound, and the metal is preferably lower than or equal to −0.50 eV, further preferably lower than or equal to −1.0 eV, still further preferably lower than or equal to −2.0 eV, yet still further preferably lower than or equal to −3.0 eV, yet still further preferably lower than or equal to −4.0 eV. The HOMO level formed here is higher than that of the first organic compound (Pyrrd-Phen) and that of the second organic compound (mPPhen2P). The HOMO level is preferably high to achieve a high electron-injection property.

Next, the table below shows the results of calculation using Pyrrd-Phen as the first organic compound, mPPhen2P as the second organic compound, and calcium (Ca) or magnesium (Mg) as the metal.

TABLE 2

| | Stabilization | HOMO |
|---|---|---|
| | energy (eV) | level (eV) |
| Pyrrd-Phen + | −3.3 | −2.40 |
| mPPhen2P + Ca | | |
| Pyrrd-Phen + | −2.4 | −2.43 |
| mPPhen2P + Mg | | |

The metal is preferably an alkaline earth metal (Ca or Mg), in which case the stabilization energy of the composite material of the metal, the first organic compound, and the second organic compound is lower than or equal to −2.0 eV as shown in the above table and the energetic stability is higher. The HOMO level formed here is higher than that of the first organic compound and that of the second organic compound. The HOMO level is preferably high to achieve a high electron-injection property.

Next, the table below shows the results of calculation using Pyrrd-Phen as the first organic compound, mPPhen2P as the second organic compound, and a metal belonging to an odd-numbered group (Group 1, 3, 5, 7, 9, 11, or 13) as the metal; specifically, the metal is lithium (Li), aluminum (Al), silver (Ag), copper (Cu), or indium (In).

TABLE 3

| | Stabilization | HOMO |
|---|---|---|
| | energy (eV) | level (eV) |
| Pyrrd-Phen + | −3.7 | −2.32 |
| mPPhen2P + Li | | |
| Pyrrd-Phen + | −4.1 | −2.82 |
| mPPhen2P + Al | | |
| Pyrrd-Phen + | −1.2 | −2.35 |
| mPPhen2P + Ag | | |
| Pyrrd-Phen + | −4.0 | −2.39 |
| mPPhen2P + Cu | | |
| Pyrrd-Phen + | −1.1 | −2.83 |
| mPPhen2P + In | | |

The metal is preferably a metal belonging to an odd-numbered group, in which case the stabilization energy of the composite material of the metal, the first organic compound, and the second organic compound is lower than or equal to −1.0 eV, lower than or equal to −2.0 eV, lower than or equal to −3.0 eV, or lower than or equal to −4.0 eV as shown in the above table and the energetic stability is higher. The SOMO level formed here is higher than the HOMO level of the first organic compound and the HOMO level of the second organic compound. The SOMO level is preferably high to achieve a high electron-injection property.

In a general fabrication process of a light-emitting device, an organic compound layer, particularly an intermediate layer, of the light-emitting device is formed by a vacuum evaporation method in many cases. In those cases, it is preferable to use a material that can be easily deposited by vacuum evaporation, i.e., a material with a low melting point. The metals belonging to Group 11 and Group 13 have low melting points and thus, they can be suitably used for vacuum evaporation. The metals belonging to Group 11 and Group 13 are preferable because they are stable with respect to oxygen and water in the air. A vacuum evaporation method is preferably used, in which case a metal atom and an organic compound can be easily mixed.

Furthermore, each of Ag and In can be used also as a cathode material. The intermediate layer and the cathode are preferably formed using the same material to facilitate the fabrication of the light-emitting device and to reduce the manufacturing cost thereof.

### <<Structure of Intermediate Layer>>

Next, details of the structure of the intermediate layer that can be used for the light-emitting devices 130a and 130b are described.

### <<First Layer>>

As each of the first layers (the first layer 161a and the first layer 161b) of the intermediate layers, which are located on the anode side, it is preferable to use a mixed layer including a metal, the first organic compound, and the second organic compound (which will be described later in detail). The metal and the first organic compound interact with each other and form a donor level (SOMO level or HOMO level), and the combination of the metal and the first organic compound functions as an electron donor with respect to the second organic compound with an electron-transport property. When a layer that includes these materials is used as each of the first layers of the intermediate layers, electrons generated in the first layers can be easily injected into the first light-emitting units. Alternatively, electrons generated in the second layers (the second layer 162a and the second layer 162b) of the intermediate layers, which are located on the cathode side, can be easily injected into the first light-emitting units. This facilitation of electron injection into the first light-emitting units enables the light-emitting devices to have a reduced driving voltage and increased emission efficiency.

The mixed layer including the metal, the first organic compound, and the second organic compound is preferably used as each of the first layers of the intermediate layers, which are located on the anode side. The formation of the mixed layer of the metal, the first organic compound, and the second organic compound facilitates interaction between these substances, so that the combination of the first organic compound and the metal functions as an electron donor with respect to the second organic compound; thus, a barrier against electron injection from the second light-emitting unit side to the first light-emitting unit side can be further lowered. This facilitates electron injection into the first light-emitting unit and accordingly enables the light-emitting device to have a further reduced driving voltage and further increased emission efficiency. When the first layer of the intermediate layer is the mixed layer of the metal, the first organic compound, and the second organic compound, the first layer of the intermediate layer is less likely to be crystallized than when having a stacked-layer structure of the metal, the first organic compound, and the second organic compound. Accordingly, the first layer of the intermediate layer is not easily crystallized even when affected by oxygen or water in the air and a chemical solution or water during processing by a lithography method for forming part of the organic compound layer. An increase in driving voltage or a reduction in current efficiency of the light-emitting device due to crystallization of the intermediate layer can be prevented. Thus, when the mixed layer is employed, the composite material of the metal, the first organic compound, and the second organic compound can be more suitably used for the intermediate layer of the light-emitting device in which part of the organic compound layer is formed through processing by a lithography method, than when the stacked-layer structure is employed.

### <Metal>

As the metal, a main-group metal or a transition metal can be used.

As the main-group metal, an alkali metal (Group 1 element) such as Li, Na, K, or Cs, an alkaline earth metal (Group 2 element) such as Mg, Ca, or Ba, a Group 12 element such as Zn, an earth metal (Group 13 element) such as Al or In, a Group 14 element such as Sn, or a compound of a Group 1, 2, 13, or 14 element can be used.

An alkali metal, an alkaline earth metal, or a compound of an alkali metal or an alkaline earth metal is preferably used as the metal, in which case the donor level formed by interaction between the alkali metal, the alkaline earth metal, or the compound and the first organic compound can be a high energy level, facilitating electron donation to the second organic compound; accordingly, electrons generated in the intermediate layer can be smoothly injected and transported into the electron-transport layer, enabling the light-emitting device to have a low driving voltage and emit light with high efficiency.

As the transition metal, any of Group 3 elements, including Y and lanthanoids such as Eu and Yb, Group 7 elements such as Mn, Group 8 elements such as Fe, Group 9 elements such as Co, Group 10 elements such as Ni and Pt, Group 11 elements such as Cu, Ag, and Au, and a compound of a Group 3, 7, 8, 9, 10, or 11 element can be used. The transition metal is preferable because it has low reactivity with components of the air such as water and oxygen.

It is further preferable to use a metal belonging to an odd-numbered group (Group 1, 3, 5, 7, 9, 11, or 13) among the above metals. Among transition metals belonging to the odd-numbered groups, a metal having one electron (unpaired electron) in an orbital of the outermost shell is particularly preferable because a combination of this metal and the first organic compound easily forms a SOMO level.

A metal that has a low melting point and that can be deposited by a vacuum evaporation method is preferably used because a mixed layer of this metal and an organic compound is easy to form. Specifically, for example, the metals belonging to Group 11 and Group 13 have low melting points and thus, they can be suitably used for vacuum evaporation. The metals belonging to Group 11 and Group 13 are preferable because they are stable with respect to oxygen and water in the air.

### <First Organic Compound>

As the first organic compound, an organic compound having a phenanthroline ring can be used.

Among organic compounds having a phenanthroline ring, an organic compound having a 1,10-phenanthroline ring, the two nitrogen atoms of which can be coordinated to a metal, is particularly preferably used to facilitate interaction with the metal.

As the first organic compound, an organic compound having a phenanthroline ring with an electron-donating group is further preferably used. Specifically, introducing an electron-donating group to a 1,10-phenanthroline ring can increase the electron density of the phenanthroline ring and the efficiency of the interaction with the metal. Furthermore, an electron-donating group is preferably bonded to at least one of the 4- and 7-positions of the 1,10-phenanthroline ring. Introducing an electron-donating group to the 4- and 7-positions can increase the electron density of the nitrogen atoms at the 1- and 10-positions, which are the para-positions with respect to the 4- and 7-positions. In addition, steric congestion around the nitrogen atoms at the 1- and 10-positions can be inhibited, and the electron density around the nitrogen atoms can be increased. This structure facilitates the interaction with the metal and is thus preferable.

The minimum value of the electrostatic potential (ESP) of the first organic compound is preferably small (i.e., the minimum value is preferably a negative value the absolute value of which is large), in which case the efficiency of the interaction with the metal is high. In an organic compound having a phenanthroline ring, the electrostatic potential around the nitrogen atoms of the phenanthroline ring, which is likely to be negative, can be further lowered (i.e., the absolute value of the negative value can be increased) by introduction of an electron-donating group to the phenanthroline ring. Note that an electrostatic potential is the energy of interaction between positive point charge with unit quantity of electricity and electron distribution of a molecule. An electrostatic potential value also depends on the threshold value of electron density distribution. To increase the efficiency of the interaction with the metal, the minimum value of the electrostatic potential of the first organic compound is preferably smaller (negatively larger) than the minimum value of the electrostatic potential of a phenanthroline ring having no substituent. Specifically, when the threshold value of electron density distribution in atomic units is 0.0004 e/a₀³, the minimum value of the electrostatic potential is preferably smaller than or equal to −0.085 Eₕ (Eₕ is the Hartree energy (1 Eₕ=27.211 eV)), further preferably smaller than or equal to −0.090 Eₕ. When the threshold value of electron density distribution is 0.003 e/a₀³, the minimum value of the electrostatic potential is preferably smaller than or equal to −0.12 Eₕ, further preferably smaller than or equal to −0.13 Eₕ.

The first organic compound is preferably strongly basic, in which case the first organic compound interacts with holes to significantly reduce the hole-transport property in the first layer 161a of the intermediate layer 160a and prevent hole transport from the first layer 161a to the second layer 162a, enabling high efficiency of the light-emitting device. Specifically, the acid dissociation constant pKₐ of the first organic compound is preferably higher than or equal to 8, further preferably higher than or equal to 10, still further preferably higher than or equal to 12.

Specific examples of the electron-donating group include an alkyl group, an alkoxy group, an aryloxy group, an alkylamino group, an arylamino group, and a heterocyclic amino group. Note that examples of the electron-donating group that is preferably introduced to the phenanthroline ring are not limited to the above examples. The electron-donating group may be any group that can increase the electron density of the phenanthroline ring by being introduced to the phenanthroline ring. The electron-donating group may be introduced to the phenanthroline ring via an arylene group such as a phenylene group, and the arylene group is preferably a p-phenylene group.

An alkyl group refers to a monovalent group obtained by eliminating one hydrogen atom from an alkane (CₙH₂ₙ₊₂). Specific examples of an alkyl group include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, and a 2,3-dimethylbutyl group.

An alkoxy group refers to a monovalent group with a structure in which an alkyl group is bonded to an oxygen atom. Specific examples of an alkoxyl group include a methoxy group, an ethoxy group, an n-propoxy group, an isopropoxy group, an n-butoxy group, a sec-butoxy group, an isobutoxy group, a tert-butoxy group, an n-pentyloxy group, an isopentyloxy group, a sec-pentyloxy group, a tert-pentyloxy group, a neopentyloxy group, an n-hexyloxy group, an isohexyloxy group, a sec-hexyloxy group, a tert-hexyloxy group, and a neohexyloxy group.

An aryloxy group refers to a monovalent group with a structure in which an aryl group is bonded to an oxygen atom. An aryl group refers to a monovalent group obtained by eliminating one hydrogen atom from one of carbon atoms forming the ring(s) of a monocyclic or polycyclic aromatic compound. Specific examples of an aryloxy group include a phenoxy group, an o-tolyloxy group, a m-tolyloxy group, a p-tolyloxy group, a mesityloxy group, an o-biphenyloxy group, a m-biphenyloxy group, a p-biphenyoxyl group, a 1-naphthyloxy group, a 2-naphthyloxy group, and a 2-fluorenyloxy group. Note that the aryloxy group may further have a substituent, and specific examples of the substituent include an alkyl group, an alkoxy group, and a phenyl group.

An alkylamino group refers to a monovalent group obtained by eliminating one hydrogen atom from the nitrogen atom of a primary amine in which one alkyl group is bonded to the nitrogen atom, or from the nitrogen atom of a secondary amine in which two alkyl groups are bonded to the nitrogen atom. Specific examples of an alkylamino group include a dimethylamino group and a diethylamino group.

An arylamino group refers to a monovalent group obtained by eliminating one hydrogen atom from the nitrogen atom of a primary amine in which one aryl group is bonded to the nitrogen atom, or from the nitrogen atom of a secondary amine in which two aryl groups are bonded to the nitrogen atom. Specific examples of an arylamino group include a diphenylamino group, a bis(α-naphthyl)amino group, and a bis(m-tolyl)amino group. Note that the arylamino group may further have a substituent, and specific examples of the substituent include an alkyl group, an alkoxy group, and a phenyl group.

Note that an amino group having a structure in which both an alkyl group and an aryl group are bonded to the nitrogen atom can be regarded as either an alkylamino group or an arylamino group. Specific examples of such an amino group include an N-methyl-N-phenylamino group.

A heterocyclic amino group refers to a monovalent group obtained by eliminating one hydrogen atom from one nitrogen atom among the atoms forming a ring(s) of a heterocyclic amine. Here, the heterocyclic amine refers to a monocyclic or polycyclic heterocyclic compound in which at least one of the atoms forming the ring(s) is a nitrogen atom bonded to a hydrogen atom. Specific examples of a heterocyclic amino group include groups represented by Structural Formulae (R-1) to (R-26) below. Note that the heterocyclic amino group may further have a substituent, and specific examples of the substituent include an alkyl group, an alkoxy group, and a phenyl group.

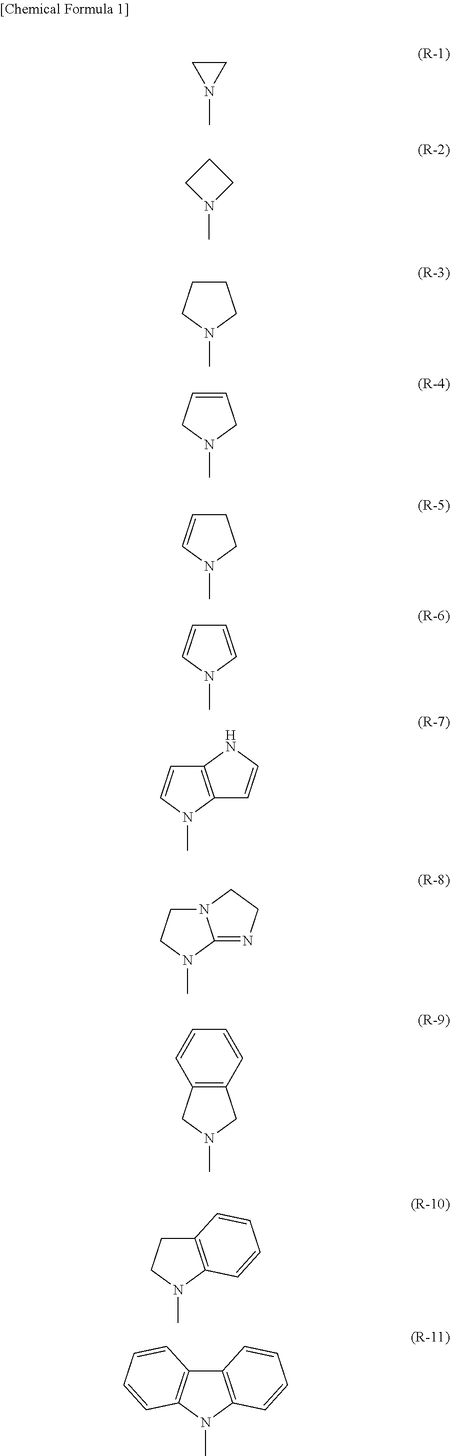

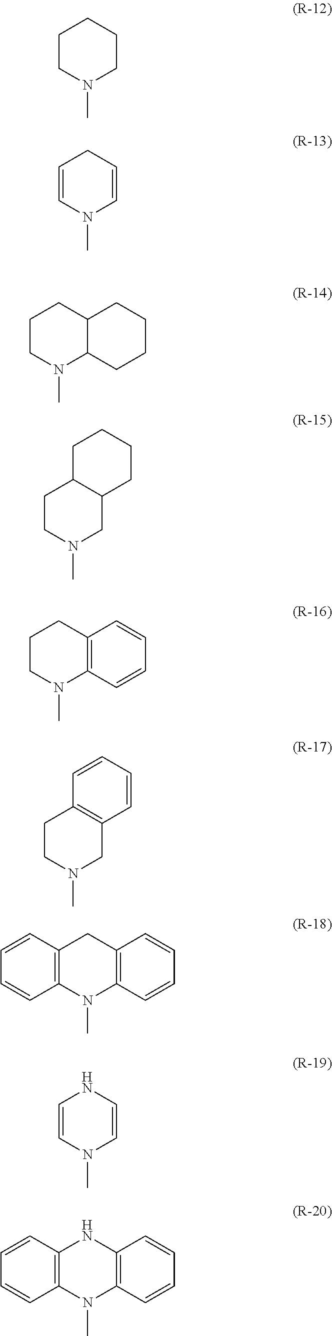

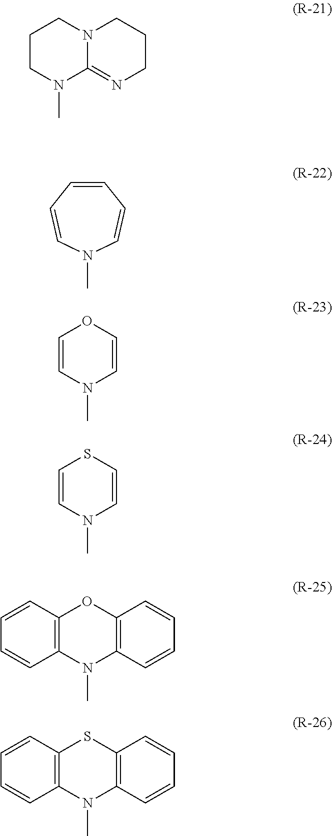

In some cases, the property of donating electrons to the phenanthroline ring is lower in a heterocyclic amino group which has aromaticity and in which an unshared electron pair of the nitrogen atom contributes to the aromaticity than in a heterocyclic amino group which has aromaticity and in which an unshared electron pair of the nitrogen atom does not contribute to the aromaticity. Therefore, among the above heterocyclic amino groups, a heterocyclic amino group which has aromaticity and in which an unshared electron pair of the nitrogen atom does not contribute to the aromaticity is further preferable. Specifically, the group represented by Structural Formula (R-1), (R-2), (R-3), (R-4), (R-5), (R-8), (R-9), (R-10), (R-12), (R-14), (R-15), (R-16), (R-17), or (R-21) is further preferably used as the electron-donating group. Among these groups, the group represented by Structural Formula (R-3), (R-4), (R-8), or (R-21) is preferably used because the group has a high electron-donating property and can further increase the electron density of the phenanthroline ring.

Specific examples of the electron-donating group include groups represented by Structural Formulae (R-27) and (R-28) below.

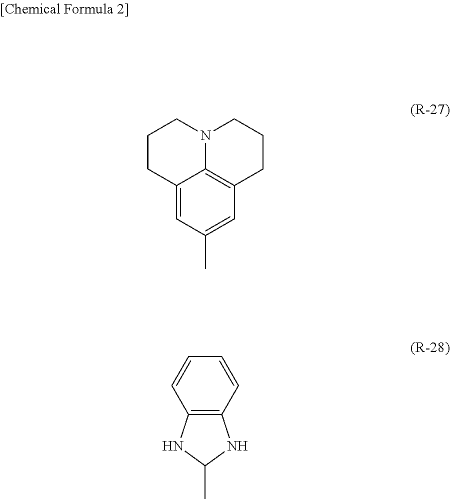

Note that an organic compound with a phenanthroline ring that can be used as the first organic compound may have both the above-described electron-donating group and another substituent. Note that introduction of an electron-withdrawing group (e.g., a cyano group or a fluoro group) to the phenanthroline ring is not preferable because the introduction reduces the electron density of the phenanthroline ring and inhibits the interaction with the metal in some cases. Specific examples of the substituent that can be introduced to the phenanthroline ring together with the above electron-donating group include an aryl group. Specific examples of the aryl group include a phenyl group, an o-tolyl group, a m-tolyl group, a p-tolyl group, a mesityl group, an o-biphenyl group, a m-biphenyl group, a p-biphenyl group, a 1-naphthyl group, a 2-naphthyl group, and a 2-fluorenyl group. Note that the aryl group may further have a substituent, and specific examples of the substituent include an alkyl group, an alkoxy group, and a phenyl group.

The first organic compound may have a structure in which a plurality of phenanthroline rings are bonded to each other via a single bond or a divalent group. Specific examples of the divalent group include an alkylene group and an arylene group.

An alkylene group refers to a divalent group obtained by eliminating two hydrogen atoms from an alkane. Specific examples of an alkylene group include a divalent group having a structure obtained by eliminating one hydrogen atom from any of the above specific examples of an alkyl group.

An arylene group refers to a divalent group obtained by eliminating two hydrogen atoms from an aromatic hydrocarbon. Specific examples of an arylene group include a divalent group having a structure obtained by eliminating one hydrogen atom from any of the above specific examples of an aryl group. Note that the arylene group may further have a substituent, and specific examples of the substituent include an alkyl group, an alkoxy group, and a phenyl group.

Specific examples of an organic compound with a phenanthroline ring that can be used as the first organic compound are represented by Structural Formulae (100) to (108). Note that the organic compound that can be used as the first organic compound is not limited to those examples. Structural Formula (100) represents 4,7-di-1-pyrrolidinyl-1,10-phenanthroline (abbreviation: Pyrrd-Phen), Structural Formula (102) represents 4,7-dimethoxy-1,10-phenanthroline (abbreviation: p-MeO-Phen), Structural Formula (103) represents 4,7-bis(1,3,4,6,7,8-hexahydro-2H-pyrimido[1,2-a]pyrimidin-1-yl)-1,10-phenanthroline (abbreviation: 4,7hpp2Phen), Structural Formula (105) represents 2,2′-(1,3-phenylene)bis[9-(1,3,4,6,7,8-hexahydro-2H-pyrimido[1,2-a]pyrimidin-1-yl)-1,10-phenanthroline] (abbreviation: mhppPhen2P), Structural Formula (106) represents 2-(1,3,4,6,7,8-hexahydro-2H-pyrimido[1,2-a]pyrimidin-1-yl)-9-phenyl-1,10-phenanthroline (abbreviation: 9Ph-2hppPhen), Structural Formula (107) represents 2,9-bis(1,3,4,6,7,8-hexahydro-2H-pyrimido[1,2-a]pyrimidin-1-yl)-1,10-phenanthroline (abbreviation: 2,9hpp2Phen), and Structural Formula (108) represents 4,7-di(2,3,3a,4,5,6,7,7a-octahydro-1H-isoindol-2-yl)-1,10-phenanthroline (abbreviation: Hid2Phen).

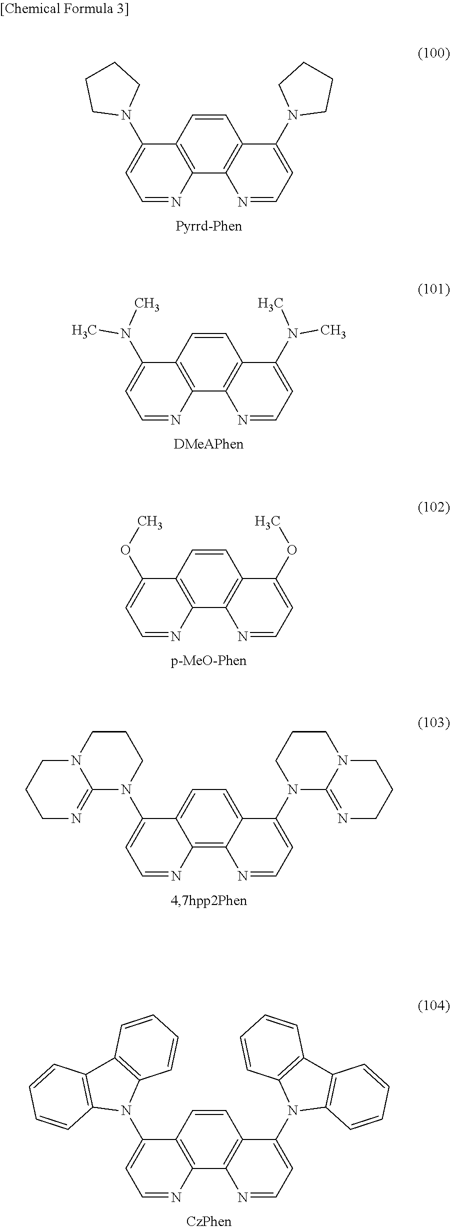

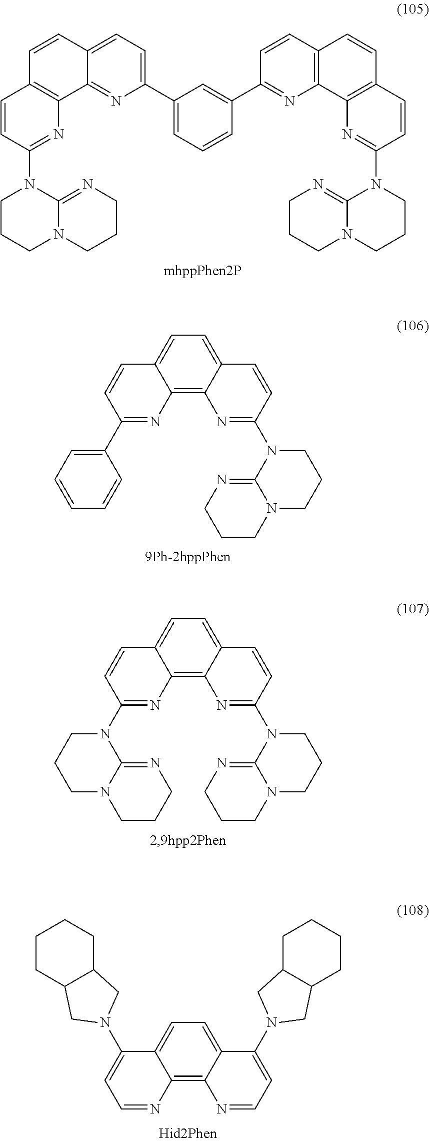 [SMILES: c1cc(-c2ccc3ccc4ccc(N5CCCN6CCCN=C65)nc4c3n2)cc(-c2ccc3ccc4ccc(N5CCCN6CCCN=C65)nc4c3n2)c1 ; c1ccc(-c2ccc3ccc4ccc(N5CCCN6CCCN=C65)nc4c3n2)cc1 ; c1cc2ccc3ccc(N4CCCN5CCCN=C54)nc3c2nc1N1CCCN2CCCN=C21 ; c1cc(N2CC3CCCCC3C2)c2ccc3c(N4CC5CCCCC5C4)ccnc3c2n1]

### <<Estimation of Characteristics by Quantum Chemical Calculation>>

The minimum values of the electrostatic potentials (ESP) of the above organic compounds that can be used as the first organic compound were estimated by quantum chemical calculation. For comparison, the minimum values of ESP of 4,7-diphenyl-1,10-phenanthroline (abbreviation: BPhen), 2,2′-(1,3-phenylene)bis(9-phenyl-1,10-phenanthroline) (abbreviation: mPPhen2P), 2,9-di(naphthalen-2-yl)-4,7-diphenyl-1,10-phenanthroline (abbreviation: NBPhen), and 1,10-phenanthroline (abbreviation: Phen) were also estimated in a similar manner. The structural formulae of BPhen, mPPhen2P, NBPhen, and Phen are shown below.

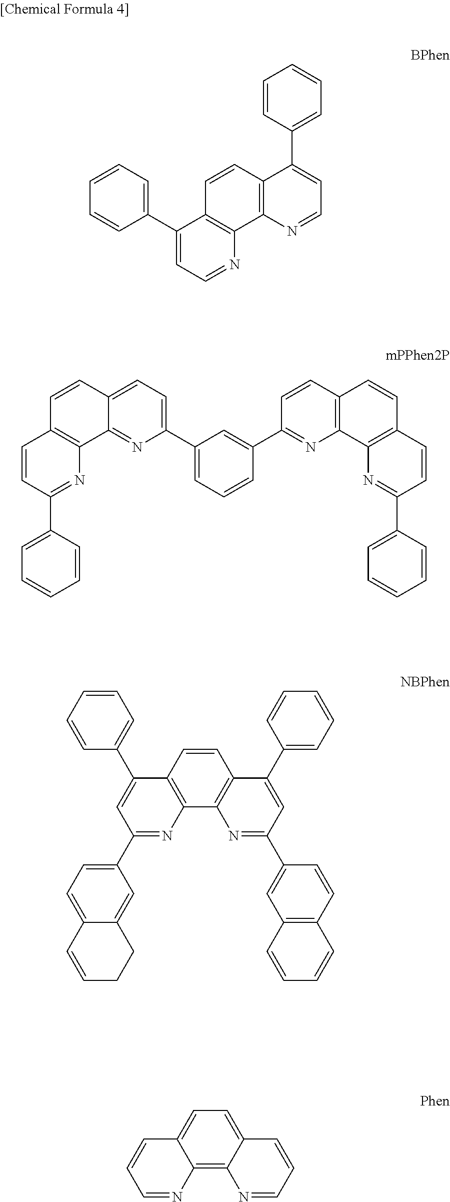 [SMILES: c1ccc(-c2ccnc3c2ccc2c(-c4ccccc4)ccnc23)cc1 ; c1ccc(-c2ccc3ccc4ccc(-c5cccc(-c6ccc7ccc8ccc(-c9ccccc9)nc8c7n6)c5)nc4c3n2)cc1 ; C1=Cc2ccc(-c3cc(-c4ccccc4)c4ccc5c(-c6ccccc6)cc(-c6ccc7ccccc7c6)nc5c4n3)cc2CC1 ; c1cnc2c(c1)ccc1cccnc12]

As the quantum chemistry computational program, Gaussian 09 was used. The calculation was performed using SGI 8600 manufactured by Hewlett Packard Enterprise. The most stable structures of the organic compounds in a ground state were calculated by the density functional theory (DFT). As basis functions, 6-311G(d,p) was used, and as a functional, B3LYP was used.

The table below lists the estimation results of the minimum values of ESP of the organic compounds, which were obtained through analysis of the electrostatic potentials of the organic compounds in a ground state. Note that an electrostatic potential is the energy of interaction between positive point charge with unit quantity of electricity and electron distribution of a molecule. An electrostatic potential value also depends on the threshold value of electron density distribution. The table below shows electrostatic potentials in electron density distribution at the time when the threshold value of electron density distribution in atomic units is 0.0004 e/a₀ or 0.003 e/a₀³. Note that the threshold value of electron density distribution is referred to as “threshold value of density” in the table below.

TABLE 4

| | | Minimum value | Minimum value |
|---|---|---|---|
| | | of ESP (Eₕ) | of ESP (Eₕ) |
| | | (Threshold value | (Threshold value |
| | | of density = | of density = |
| | | 0.0004 e/a₀³) | 0.003 e/a₀³) |
| Pyrrd-Phen | (100) | −0.091 | −0.12 |
| DMeAPhen | (101) | −0.089 | −0.12 |
| p-MeO-Phen | (102) | −0.089 | −0.12 |
| 4,7hpp2Phen | (103) | −0.096 | −0.13 |
| CzPhen | (104) | −0.072 | −0.10 |
| mhppPhen2P | (105) | −0.057 | −0.096 |
| 9Ph2hppPhen | (106) | −0.057 | −0.096 |
| 2,9hpp2Phen | (107) | −0.061 | −0.097 |
| Hid2Phen | (108) | −0.094 | −0.13 |
| BPhen | | −0.083 | −0.11 |
| mPPhen2P | | −0.057 | −0.094 |
| NBPhen | | −0.053 | −0.093 |
| Phen | | −0.081 | −0.11 |

From the above table, it is found that the minimum values of ESP of the organic compounds represented by Structural Formulae (100) to (103) and (108) are each smaller than or equal to −0.085 Eₕ when the threshold value of electron density distribution is 0.0004 e/a₀³ and that using any of these organic compounds as the first organic compound is the most preferable. Meanwhile, it is found that the minimum values of ESP of the organic compounds represented by Structural Formulae (104) to (107) are each larger than −0.085 Eₕ.

It is found that the organic compounds represented by Structural Formulae (100) to (103) and (108) have the most favorable values because of having an electron-donating group at each of the 4- and 7-positions of the 1,10-phenanthroline ring.

The organic compound represented by Structural Formula (104) has N-carbazolyl groups as electron-donating groups at the 4- and 7-positions of the 1,10-phenanthroline ring. In the N-carbazolyl group, in which an unshared electron pair of the nitrogen atom contributes to aromaticity, the property of donating electrons to the phenanthroline ring is lower than that in a group in which an unshared electron pair of a nitrogen atom does not contribute to aromaticity, inhibiting a reduction in the minimum value of ESP of the organic compound represented by Structural Formula (104).

The organic compounds represented by Structural Formulae (105) to (107) each have electron-donating groups at the 2- and 9-positions of the 1,10-phenanthroline ring. The electron-donating groups introduced to the 2- and 9-positions have a low property of donating electrons to the nitrogen atoms at the 1- and 10-positions of the phenanthroline ring. It is thus preferable that electron-donating groups be at the 4- and 7-positions of a 1,10-phenanthroline ring.

Note that the LUMO level of the second organic compound is further preferably lower than that of the first organic compound. In that case, electrons can be easily donated from the donor level formed by the first organic compound and the metal to the second organic compound. The LUMO level of the second organic compound is preferably lower than that of the first organic compound also because the second organic compound preferably has an electron-transport property.

For example, the LUMO level of the first organic compound is preferably higher than or equal to −3.0 eV and lower than or equal to −2.0 eV, further preferably higher than or equal to −2.7 eV and lower than or equal to −2.0 eV. The LUMO level of the second organic compound is preferably higher than or equal to −3.0 eV and lower than or equal to −2.0 eV, further preferably higher than or equal to −3.0 eV and lower than or equal to −2.5 eV. In that case, electrons can be easily donated from the donor level formed by the first organic compound and the metal to the second organic compound. This can increase the electron-transport property of the second organic compound.

Note that the HOMO level and the LUMO level of an organic compound are generally estimated by cyclic voltammetry (CV), photoelectron spectroscopy, optical absorption spectroscopy, inverse photoemission spectroscopy, or the like. When values of different compounds are compared with each other, it is preferable that values estimated by the same measurement be used.

In the case where the acid dissociation constant pKₐ of an organic compound is unknown, the acid dissociation constants pKₐ of skeletons in the organic compound are calculated and the largest acid dissociation constant pKₐ can be regarded as the acid dissociation constant pKₐ of the organic compound.

The acid dissociation constant may be obtained by calculation. For example, the acid dissociation constant pKₐ can be obtained by the following calculation method.

The initial structure of a molecule serving as a calculation model is the most stable structure (the singlet ground state) obtained from first-principles calculation.

For the first-principles calculation, Jaguar, which is the quantum chemical computational software manufactured by Schrödinger, Inc., is used, and the most stable structure in the singlet ground state is calculated by the density functional theory (DFT). As a basis function, 6-31G** is used, and as a functional, B3LYP-D3 is used. The structure subjected to quantum chemical calculation is sampled by conformational analysis in mixed torsional/low-mode sampling with Maestro GUI produced by Schrödinger, Inc.

In the calculation of pKₐ, one or more atoms in each molecule are designated as basic sites, MacroModel is used to search for the stable structure of the protonated molecule in water, conformational search is performed with OPLS2005 force field, and a conformational isomer having the lowest energy is used. Jaguar's pKₐ calculation module is used. After structure optimization is performed by B3LYP/6-31G*, single point calculation is performed by cc-pVTZ(+) and the pKₐ value is calculated using empirical correction for functional group(s). In the case where one or more atoms are designated as basic sites in a molecule, the largest of obtained values is used as a pKₐ value. The obtained pKₐ values are shown below.

The acid dissociation constant pKₐ of 2,9hpp2Phen is 13.35, that of 4,7hpp2Phen is 13.42, that of Pyrrd-Phen is 11.23, that of mPPhen2P is 5.16, that of NBPhen is 5.59, and that of BPhen is 5.62.

### <Second Organic Compound>

As the second organic compound, an organic compound with an electron-transport property can be used. The organic compound with an electron-transport property is preferably a substance having an electron mobility higher than or equal to 1′10⁻⁷ cm²/Vs, further preferably higher than or equal to 1′10⁻⁶ cm²/Vs, when the square root of electric field strength [V/cm] is 600. Note that any other substance can be used as long as the substance has an electron-transport property higher than a hole-transport property.

An organic compound having a π-electron deficient heteroaromatic ring is preferable as the organic compound with an electron-transport property. The organic compound having a π-electron deficient heteroaromatic ring is preferably one or more of an organic compound having a heteroaromatic ring with an azole skeleton, an organic compound having a heteroaromatic ring with a pyridine skeleton, an organic compound having a heteroaromatic ring with a diazine skeleton, and an organic compound having a heteroaromatic ring with a triazine skeleton.

Specific examples of the organic compound with an electron-transport property include the following compounds: organic compounds having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: COl1), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl)stilbene (abbreviation: BzOs); organic compounds having a heteroaromatic ring with a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), and 2,2′-(1,3-phenylene)bis(9-phenyl-1,10-phenanthroline) (abbreviation: mPPhen2P); organic compounds having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-{3-[3-(N-phenyl-9H-carbazol-3-yl)-9H-carbazol-9-yl]phenyl}dibenzo[f,h]quinoxaline (abbreviation: 2mPCCzPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 8-(1,1′: 4′,1″-terphenyl-3-yl)-4-[3-(dibenzothiophen-4-yl)phenyl]-[1]benzofuro[3,2-d]pyrimidine (abbreviation: 8mpTP-4mDBtPBfpm), 8-(1,1′: 4′,1″-terphenyl-3-yl-2,4,5,6,2′,3′,5′,6′,2″,3″,4″,5″,6″-d₁₃)-4-[3-(dibenzothiophen-4-yl-1,2,3,6,7,8,9-d₇)phenyl-2,4,6-d₃]-[1]benzofuro[3,2-d]pyrimidine (abbreviation: 8mpTP-4mDBtPBfpm-d₂₃), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(2,2′-bipyridine-6,6′-diyl)bis(4-phenylbenzo[h]quinazoline) (abbreviation: 6,6′(P-Bqn)2BPy), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), and 7-[4-(9-phenyl-9H-carbazol-2-yl)quinazolin-2-yl]-7H-dibenzo[c,g]carbazole (abbreviation: PC-cgDBCzQz); and organic compounds having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), and 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn).

Among the above organic compounds, the organic compound having a phenanthroline ring, particularly a 1,10-phenanthroline ring, such as BPhen, BCP, NBPhen, or mPPhen2P, is further preferable because two nitrogen atoms contained therein can be coordinated to the metal to facilitate the interaction with the metal. An organic compound having a phenanthroline ring dimer structure, such as mPPhen2P, is further preferable because of its high stability.

The second organic compound preferably has 25 to 100 carbon atoms. When having 25 to 100 carbon atoms, the second organic compound can have excellent sublimability, and thus, thermal decomposition of the organic compound during vacuum evaporation can be inhibited and the efficiency of use of the material can be high. An organic compound having a glass transition temperature T_{g} higher than or equal to 100° C. can be used as the second organic compound. In that case, the intermediate layer is not easily crystallized. Accordingly, the intermediate layer is not easily crystallized even when affected by oxygen or water in the air and a chemical solution or water during processing by a lithography method for forming part of the organic compound layer. An increase in driving voltage or a reduction in current efficiency of the light-emitting device due to crystallization of the intermediate layer can be accordingly prevented. Thus, when the second organic compound has T_{g} higher than or equal to 100° C., the composite material of the metal, the first organic compound, and the second organic compound can be suitably used for the intermediate layer of the light-emitting device in which part of the organic compound layer is formed through processing by a lithography method.

Examples of an organic compound having a phenanthroline ring and a glass transition temperature (T_{g}) higher than or equal to 100° C. include NBPhen (T_{g}: 165° C.), mPPhen2P (T_{g}: 135° C.), 2,2′-(biphenyl-4,4′-diyl)bis(9-phenyl-1,10-phenanthroline) (abbreviation: PPhen2BP) (T_{g}: 166° C.), 2,2′-biphenyl-3,3′-diylbis(9-phenyl-1,10-phenanthroline) (abbreviation: mPPhen2BP) (T_{g}: 144° C.), 2,8-bis(phenanthrolin-5-yl)dibenzofuran (abbreviation: 2,8Phen2DBf) (T_{g}: 210° C.), and 5,5′,5″-(benzene-1,3,5-triyl)tri-1,10-phenanthroline (abbreviation: Phen3P) (T_{g}: 257° C.). A glass transition temperature (T_{g}) can be measured with a differential scanning calorimeter (DSC8500 manufactured by PerkinElmer Japan Co., Ltd.) in a state where a powder is put on an aluminum cell and the temperature is increased at a rate of 40° C./min.

As the second organic compound, an organic compound with an acid dissociation constant pKₐ higher than or equal to 4 and lower than 8 can be used. The second organic compound preferably has such an acid dissociation constant to have a poor hole-transport property, in which case the hole-transport property in the first layer 161a of the intermediate layer 160a can be reduced and hole transport from the first layer 161a to the second layer 162a can be prevented, enabling the light-emitting device to have high efficiency. An excessively high acid dissociation constant pKₐ leads to high solubility in water and thus causes low resistance to water and a chemical solution used in the process by a lithography method. Thus, the acid dissociation constant pKₐ of the second organic compound is preferably higher than or equal to 4 and lower than 8.

In the layer that includes the combination of the metal, the first organic compound, and the second organic compound, interaction between the materials occurs more efficiently than in a layer that includes only two of the materials (e.g., a layer that includes the metal and the first organic compound or a layer that includes the metal and the second organic compound). This can be confirmed when films that include some or all of the materials are formed using an odd-numbered metal as the metal and the spin densities of the films are measured by an electron spin resonance (ESR) method.

For example, in the case where ESR measurement shows that the spin density of a film that includes the metal, the first organic compound, and the second organic compound is higher than the spin density of a film that includes the metal and the first organic compound or a film that includes the metal and the second organic compound, it can be confirmed that the interaction between the materials has occurred more efficiently in the film that includes the combination of the metal, the first organic compound, and the second organic compound than in the film that includes only two of the materials. Note that spin density measurement by an electron spin resonance method is preferably performed at room temperature.

Specifically, in the case where the density of spins attributed to a signal observed at a g-factor of approximately 2.00 is measured by an electron spin resonance method to be, for example, lower than or equal to 2×10¹⁶ spins/cm³ in a mixed film that includes the metal and the first organic compound; the density of spins attributed to a signal observed at a g-factor of approximately 2.00 is measured by an electron spin resonance method to be, for example, lower than or equal to 2×10¹⁶ spins/cm³ in a mixed film that includes the metal and the second organic compound; the density of spins attributed to a signal observed at a g-factor of approximately 2.00 is measured by an electron spin resonance method to be, for example, lower than or equal to 2×10¹⁶ spins/cm³ in a mixed film that includes the first organic compound and the second organic compound; and the density of spins attributed to a signal observed at a g-factor of approximately 2.00 is measured by an electron spin resonance method to be, for example, higher than or equal to 5×10¹⁶ spins/cm³, preferably higher than or equal to 1×10¹⁷ spins/cm³, in a mixed film that includes the metal, the first organic compound, and the second organic compound, it can be confirmed that the interaction between the materials has occurred more efficiently in the mixed film that includes the combination of the metal, the first organic compound, and the second organic compound than in the mixed film that includes only two of the materials.

The molar ratio of the metal to the sum of the first organic compound and the second organic compound is preferably greater than or equal to 0.1 and less than or equal to 10, further preferably greater than or equal to 0.2 and less than or equal to 5, still further preferably greater than or equal to 0.5 and less than or equal to 2. Alternatively, the volume ratio of the metal to the sum of the first organic compound and the second organic compound is preferably greater than or equal to 0.01 and less than or equal to 0.3, further preferably greater than or equal to 0.02 and less than or equal to 0.2, still further preferably greater than or equal to 0.05 and less than or equal to 0.1. Mixing the metal, the first organic compound, and the second organic compound in such a ratio enables providing the intermediate layer having a favorable electron-injection property. The volume ratio of the first organic compound to the second organic compound is preferably greater than or equal to 0.1 and less than or equal to 10, further preferably greater than or equal to 0.2 and less than or equal to 5, still further preferably greater than or equal to 0.5 and less than or equal to 2. Mixing the first organic compound and the second organic compound in such a ratio enables providing the intermediate layer having a favorable electron-transport property.

The thickness of the first layer 161a of the intermediate layer 160a, which is located on the anode side, is preferably greater than or equal to 3 nm and less than or equal to 20 nm, further preferably greater than or equal to 5 nm and less than or equal to 10 nm. In that case, the composite material in which the metal, the first organic compound, and the second organic compound are mixed can favorably function, enabling high emission efficiency of the light-emitting device.

### <<Second Layer>>

In the case where a mixed layer or a stacked-layer structure that includes the metal, the first organic compound, and the second organic compound is used for the first layer of the intermediate layer, a layer that includes a third organic compound and a fourth organic compound (which will be described later in detail) is preferably used for the second layer to enable favorable injection of holes into the light-emitting layer on the upper side.

### <Third Organic Compound>

As the third organic compound, an organic compound with a hole-transport property is preferably used. As the organic compound with a hole-transport property, any of a variety of organic compounds such as aromatic amine compounds, heteroaromatic compounds, aromatic hydrocarbons, and high molecular compounds (e.g., oligomers, dendrimers, and polymers) can be used. Note that the organic compound with a hole-transport property preferably has a hole mobility higher than or equal to 1′10⁻⁶ cm²/Vs. The organic compound with a hole-transport property is preferably a compound having a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton is preferable; specifically, a carbazole ring, a dibenzothiophene ring, or a ring in which an aromatic ring or a heteroaromatic ring is further fused to the carbazole ring or the dibenzothiophene ring is preferable. Note that in this specification and the like, an organic compound with a hole-transport property is sometimes referred to as a material with a hole-transport property.

Such an organic compound with a hole-transport property further preferably has any of a carbazole skeleton, a dibenzofuran skeleton, a dibenzothiophene skeleton, and an anthracene skeleton. In particular, an aromatic amine having a substituent with a dibenzofuran ring or a dibenzothiophene ring, an aromatic monoamine having a naphthalene ring, or an aromatic monoamine in which a 9-fluorenyl group is bonded to the nitrogen of the amine through an arylene group may be used. Note that the organic compound with a hole-transport property preferably has an N,N-bis(4-biphenyl)amino group to enable fabrication of a light-emitting device having a long lifetime.

Specific examples of the organic compound with a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAaNβNB), 4,4′-diphenyl-4″-(7;1′-binaphthyl-2-yl)triphenylamine (abbreviation: BBAaNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNaNB), 4,4′-diphenyl-4″-(5;2′-binaphthyl-1-yl)triphenylamine (abbreviation: BBAβNaNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiPNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

As the organic compound with a hole-transport property, any of the following aromatic amine compounds can also be used: N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

### <Fourth Organic Compound>

As the fourth organic compound, a substance having an acceptor property with respect to the third organic compound is preferably used. As the substance with an acceptor property, an organic compound having an electron-withdrawing group (e.g., a halogen group or a cyano group) is preferably used, and an organic compound which has one or more halogen groups, one or more cyano groups, or both one or more halogen groups and one or more cyano groups and in which the total number of the one or more halogen groups, the one or more cyano groups, or both the one or more halogen groups and the one or more cyano groups is four or more is further preferably used. Specific examples include 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F₆-TCNNQ), and 2-(7-dicyanomethylene-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a very high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance with an acceptor property, a transition metal oxide such as molybdenum oxide, vanadium oxide, ruthenium oxide, tungsten oxide, or manganese oxide can be used, other than the above-described organic compounds.

A signal is preferably observed by electron spin resonance in the second layer. For example, the density of spins attributed to a signal observed at a g-factor of approximately 2.00 is preferably higher than or equal to 1′10¹⁷ spins/cm³, further preferably higher than or equal to 1′10¹⁸ spins/cm³, still further preferably higher than or equal to 1′10¹⁹ spins/cm³. In that case, the second layer can function as a charge-generation layer. Furthermore, the light-emitting device can have a low driving voltage and high efficiency.

### <<Third Layer>>

Between the first layer and the second layer of the intermediate layer, the third layer for enabling smooth electron transfer between the two layers may be provided.

The third layer includes a substance with an electron-transport property and has a function of preventing interaction between the first layer and the second layer and transferring electrons smoothly. The LUMO level of the substance with an electron-transport property included in the third layer is preferably between the LUMO level of the acceptor substance in the second layer and the LUMO level of the organic compound included in a layer (the first electron-transport layer 114a_1 in the first light-emitting unit 501a in FIG. 1) which is included in the light-emitting unit on the first electrode side and is in contact with the intermediate layer. As a specific value of the energy level, the LUMO level of the substance with an electron-transport property in the third layer is preferably higher than or equal to −5.0 eV, further preferably higher than or equal to −5.0 eV and lower than or equal to −3.0 eV, still further preferably higher than or equal to −4.30 eV and lower than or equal to −3.00 eV, yet still further preferably higher than or equal to −4.30 eV and lower than or equal to −3.30 eV, in which case electrons generated in the second layer can be easily injected into the first layer and accordingly an increase in the driving voltage of the light-emitting device can be inhibited. Note that as the substance with an electron-transport property in the third layer, a phthalocyanine-based material or a metal complex having a metal-oxygen bond and an aromatic ligand is preferably used.

Specifically, it is possible to use a perylenetetracarboxylic acid derivative such as diquinoxalino[2,3-a:2′,3′-c]phenazine (abbreviation: HATNA), 2,3,8,9,14,15-hexafluorodiquinoxalino[2,3-a:2′,3′-c]phenazine (abbreviation: HATNA-F6), 3,4,9,10-perylenetetracarboxylic diimide (abbreviation: PTCDI), or 3,4,9,10-perylenetetracarboxyl-bis-benzimidazole (abbreviation: PTCBI), (C₆₀-Iₕ)[5,6]fullerene (abbreviation: C₆₀), (C₇₀-D₅ₕ)[5,6]fullerene (abbreviation: C₇₀), or phthalocyanine (abbreviation: H₂Pc). Alternatively, it is possible to use a metal phthalocyanine containing copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). It is particularly preferable to use a phthalocyanine-based metal complex such as copper phthalocyanine or zinc phthalocyanine or 2,3,8,9,14,15-hexafluorodiquinoxalino[2,3-a:2′,3′-c]phenazine.

The thickness of the third layer is preferably greater than or equal to 1 nm and less than or equal to 10 nm, further preferably greater than or equal to 2 nm and less than or equal to 5 nm.

The structures described in this embodiment can be used in combination with any of the structures described in the other embodiments as appropriate.

### Embodiment 2

In this embodiment, other structures of a light-emitting device of one embodiment of the present invention are described.

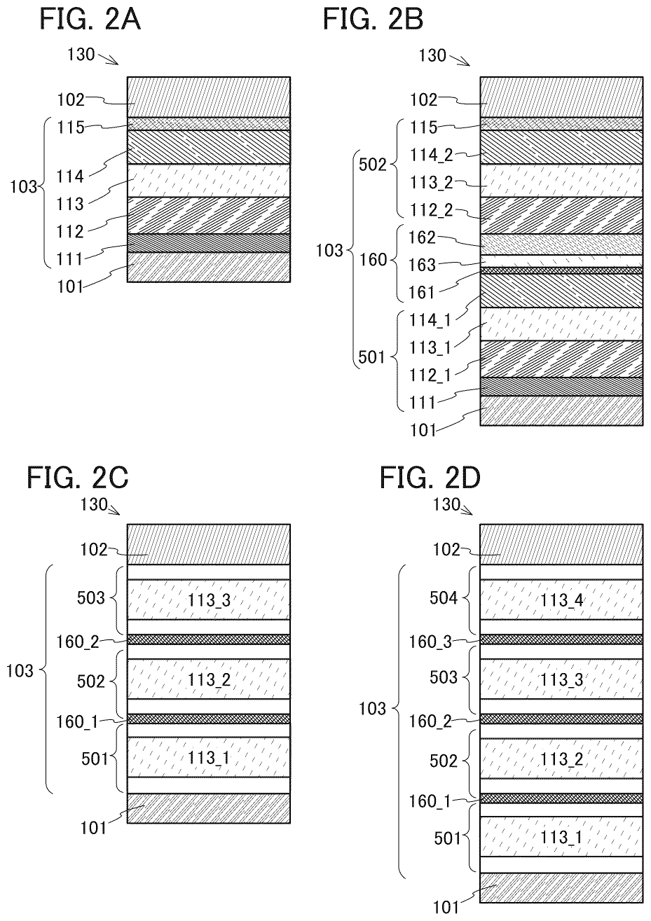

FIG. 2A illustrates a light-emitting device 130, which is an example of the light-emitting device of one embodiment of the present invention. The light-emitting device 130 includes an organic compound layer 103 that includes a light-emitting layer 113, between a first electrode 101 that includes an anode and the second electrode 102 that includes a cathode.

FIG. 2B illustrates the light-emitting device 130 that is another example of the light-emitting device of one embodiment of the present invention. The light-emitting device 130 is a tandem light-emitting device. The light-emitting device 130 includes a first light-emitting unit 501 including a first light-emitting layer 1131, a second light-emitting unit 502 including a second light-emitting layer 113_2, and an intermediate layer 160, as the organic compound layer 103. The intermediate layer 160 includes a first layer 161, a second layer 162, and a third layer 163 between the first layer 161 and the second layer 162.

Although a light-emitting device that includes one intermediate layer 160 and two light-emitting units is described as an example in this embodiment, a light-emitting device that includes n intermediate layer(s) (n is an integer greater than or equal to 1) and n+1 light-emitting units may be employed.

For example, the light-emitting device 130 illustrated in FIG. 2C is an example of the tandem light-emitting device in which n is 2 and which includes the first light-emitting unit 501, a first intermediate layer 160_1, the second light-emitting unit 502, a second intermediate layer 1602, and a third light-emitting unit 503, as the organic compound layer 103. The color gamut of light emitted by a light-emitting layer in one light-emitting unit may be the same as or different from that of light emitted by a light-emitting layer in another light-emitting unit. In addition, the light-emitting layer may have a single-layer structure or a stacked-layer structure. For example, the light-emitting layers in the first and third light-emitting units emit light in the blue range while the stacked light-emitting layers in the second light-emitting unit emit light in the red range and light in the green range, whereby white light emission can be obtained.

The light-emitting device 130 illustrated in FIG. 2D is an example of the tandem light-emitting device in which n is 3 and which includes the first light-emitting unit 501, the first intermediate layer 160_1, the second light-emitting unit 502, the second intermediate layer 160_2, the third light-emitting unit 503, a third intermediate layer 160_3, and a fourth light-emitting unit 504, as the organic compound layer 103. The color gamut of light emitted by a light-emitting layer in one light-emitting unit may be the same as or different from that of light emitted by a light-emitting layer in another light-emitting unit. In addition, the light-emitting layer may have a single-layer structure or a stacked-layer structure. For example, any three of the four light-emitting units can be blue (B), and the other one can be green (G); any two of the four light-emitting units can be blue (B), and the other two can be yellow (Y); alternatively, any one of the four light-emitting units can be red (R), another one can be green (G), the other two can be blue (B).

The light-emitting device 130 may be fabricated using a lithography method, for example. In the case of the light-emitting device fabricated using a lithography method, at least the light-emitting layer 113 (or the second light-emitting layer 113_2) and the layer(s) in the organic compound layer that is/are closer to the first electrode 101 than the light-emitting layer or the second light-emitting layer are formed by processing at the same time; consequently, their end portions are substantially aligned in the perpendicular direction.

The organic compound layer 103 may include another functional layer in addition to the light-emitting layer. FIG. 2A illustrates a structure where, in addition to the light-emitting layer 113, a hole-injection layer 111, a hole-transport layer 112, an electron-transport layer 114, and the electron-injection layer 115 are provided in the organic compound layer 103. Furthermore, the first light-emitting unit 501 and the second light-emitting unit 502 may each include another functional layer in addition to the light-emitting layer. FIG. 2B illustrates a structure where the hole-injection layer 111, a first hole-transport layer 1121, and a first electron-transport layer 114_1, in addition to the first light-emitting layer 113_1, are provided in the first light-emitting unit 501 and a second hole-transport layer 112_2, a second electron-transport layer 114_2, and the electron-injection layer 115, in addition to the second light-emitting layer 1132, are provided in the second light-emitting unit 502. The structure of the organic compound layer 103 in the present invention is not limited to these structures; any of the layers may be absent or another layer may be added. A carrier-blocking layer (a hole-blocking layer or an electron-blocking layer), an exciton-blocking layer, or the like may be typically added.

Then, components of the above light-emitting device 130, other than the intermediate layer 160, are described.

### <<Structure of First Electrode>>

The first electrode 101 includes an anode. The first electrode 101 may have a stacked-layer structure where the layer in contact with the organic compound layer 103 functions as the anode. The anode is preferably formed using any of metals, alloys, and conductive compounds with a high work function (specifically, higher than or equal to 4.0 eV), mixtures thereof, and the like. Specific examples include indium oxide-tin oxide (ITO: indium tin oxide), indium oxide-tin oxide containing silicon or silicon oxide, indium oxide-zinc oxide, and indium oxide containing tungsten oxide and zinc oxide (IWZO). Such conductive metal oxide films are usually formed by a sputtering method, but may be formed by application of a sol-gel method or the like. In an example of the formation method, a film of indium oxide-zinc oxide is formed by a sputtering method using a target obtained by adding 1 wt % to 20 wt % zinc oxide to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), a nitride of a metal material (e.g., titanium nitride), or the like can be used for the anode. Graphene can also be used for the anode. Note that an electrode material can be selected regardless of the work function when the second layer 162 in the above intermediate layer 160 is used for the layer (typically the hole-injection layer) in contact with the anode.

### <<Structure of Hole-Injection Layer>>

The hole-injection layer 111 is provided in contact with the anode and has a function of facilitating injection of holes into the organic compound layer 103 (the first light-emitting unit 501). The hole-injection layer 111 can be formed using phthalocyanine (abbreviation: H₂Pc), a phthalocyanine-based compound such as copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS).

The hole-injection layer 111 may be formed using a substance with an acceptor property. As the substance with an acceptor property, any of the substances described as the substance with an acceptor property used for the second layer 162 of the above intermediate layer 160 can be used similarly.

The hole-injection layer 111 may be formed using the organic compound with a hole-transport property that is used for the second layer 162 of the above intermediate layer 160. The hole-injection layer 111 may employ the structure of the second layer 162 of the above intermediate layer 160.

In the case where the hole-injection layer 111 is formed using a mixed material of the substance with an acceptor property and the organic compound with a hole-transport property, it is further preferable that the organic compound with a hole-transport property used in the mixed material have a relatively deep HOMO level higher than or equal to −5.7 eV and lower than or equal to −5.4 eV. When the organic compound with a hole-transport property used in the mixed material has a relatively deep HOMO level, hole injection into the hole-transport layer is facilitated and the light-emitting device can easily have a long lifetime. In addition, when the organic compound with a hole-transport property used in the mixed material has a relatively deep HOMO level, induction of holes can be inhibited properly, so that the light-emitting device can have a longer lifetime.

The formation of the hole-injection layer 111 can improve the hole-injection property, which allows the light-emitting device to be driven at a low voltage.

Among substances with an acceptor property, an organic compound with an acceptor property is easy to use because the organic compound is easily deposited by evaporation and its film is easily formed.

The second light-emitting unit 502 includes no hole-injection layer because the second layer 162 of the intermediate layer 160 functions as a hole-injection layer; however, the second light-emitting unit 502 may include a hole-injection layer.

The hole-transport layer (the first hole-transport layer 112_1 or the second hole-transport layer 112_2) includes an organic compound with a hole-transport property. The organic compound with a hole-transport property preferably has a hole mobility higher than or equal to 1′10⁻⁶ cm²/Vs.

Examples of the aforementioned organic compound with a hole-transport property include the following compounds: compounds having an aromatic amine skeleton, such as 4,4′-bis[N-(1-naphthyl)-N-phenylamino]biphenyl (abbreviation: NPB), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BispNCz), 9-(2-naphthyl)-9′-[1,1′: 4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, and 9-(triphenylen-2-yl)-9′-[1,1′: 3′,1″-terphenyl]-4-yl-3,3′-9H,9′H-bicarbazole; compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. Note that any of the substances given as examples of the organic compound with a hole-transport property that is used for the second layer of the intermediate layer and the hole-injection layer 111 can also be suitably used as the material included in the hole-transport layer.

### <<Structure of Light-Emitting Layer>>

The light-emitting layer (the light-emitting layer 113, the first light-emitting layer 113_1, or the second light-emitting layer 1132) preferably includes alight-emitting substance and a host material. The light-emitting layer may additionally include other materials. Alternatively, the light-emitting layer may be a stack of two layers with different compositions.

As the light-emitting substance, fluorescent substances, phosphorescent substances, substances exhibiting thermally activated delayed fluorescence (TADF), or other light-emitting substances may be used.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(N,N′,N-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), 9,10-bis(2-biphenyl)-2-(N,N′,N′-triphenyl-1,4-phenylenediamin-N-yl)anthracene (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N-tetrakis(4-methylphenyl)tetracene-5,11-diamine (abbreviation: p-mPhTD), 7,14-diphenyl-N,N,N,N-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine] (abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties and high emission efficiency or high reliability.

Examples of the material that can be used when a phosphorescent substance is used as the light-emitting substance in the light-emitting layer are as follows.

The examples include an organometallic iridium complex having a 4H-triazole skeleton, such as tris{2-[5-(2-methylphenyl)-4-(2,6-dimethylphenyl)-4H-1,2,4-triazol-3-yl-κN²]phenyl-KC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), and tris[4-(3-biphenyl)-5-isopropyl-3-phenyl-4H-1,2,4-triazolato]iridium(III) (abbreviation: [Ir(iPrptz-3b)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); an organometallic iridium complex having an imidazole skeleton, such as fac-tris[Ir(2,6-diisopropylphenyl)-2-phenyl-1H-imidazole]iridium(III) (abbreviation: [Ir(iPrpim)₃]) and tris[3-(2,6-dimethylphenyl)-7-methylimidazo[1,2-f]phenanthridinato]iridium(III) (abbreviation: [Ir(dmpimpt-Me)₃]); and an organometallic iridium complex in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIracac). These compounds emit blue phosphorescent light and have an emission peak in the wavelength range from 450 nm to 520 nm.

Other examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²)iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridine-KC]bis[2-(5-d₃-methyl-2-pyridinyl-κN²)phenyl-KC]iridium(III) (abbreviation: Ir(5mppy-d₃)₂(mbfpypy-d₃)), tris{2-[5-(methyl-d₃)-4-phenyl-2-pyridinyl-κN]phenyl-KC}iridium(III) (abbreviation: Ir(5m4dppy-d₃)₃), {[2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-N]phenyl-KC}iridium(III) (abbreviation: Ir(5mtpy-d₆)₂(mbfpypy-iPr-d₄)), [2-d₃-methyl-(2-pyridinyl-κN)benzofuro[2,3-b]pyridine-κC]bis[2-(2-pyridinyl-κN)phenyl-κC]iridium(III) (abbreviation: Ir(ppy)₂(mbfpypy-d₃)), and [2-(4-methyl-5-phenyl-2-pyridinyl-κN)phenyl-κC]bis[2-(2-pyridinyl-κN)phenyl-κC]iridium(III) (abbreviation: Ir(ppy)₂(mdppy)); and a rare earth metal complex such as tris(acetylacetonato)(monophenanthroline)terbium(III) (abbreviation: [Tb(acac)₃(Phen)]). These are mainly compounds that emit green phosphorescent light and have an emission peak in the wavelength range from 500 nm to 600 nm. Note that organometallic iridium complexes having a pyrimidine skeleton have distinctively high reliability or emission efficiency and thus are particularly preferable.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes having a pyridine skeleton, such as tris(1-phenylisoquinolinato-N,C^{2′})iridium(III) (abbreviation: [Ir(piq)₃]) and bis(1-phenylisoquinolinato-N,C^{2′})iridium(III) acetylacetonate (abbreviation: [Ir(piq)₂(acac)]); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These compounds emit red phosphorescent light and have an emission peak in the wavelength range from 600 nm to 700 nm. Furthermore, the organometallic iridium complexes having a pyrazine skeleton can provide red light emission with favorable chromaticity.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structure formulae.

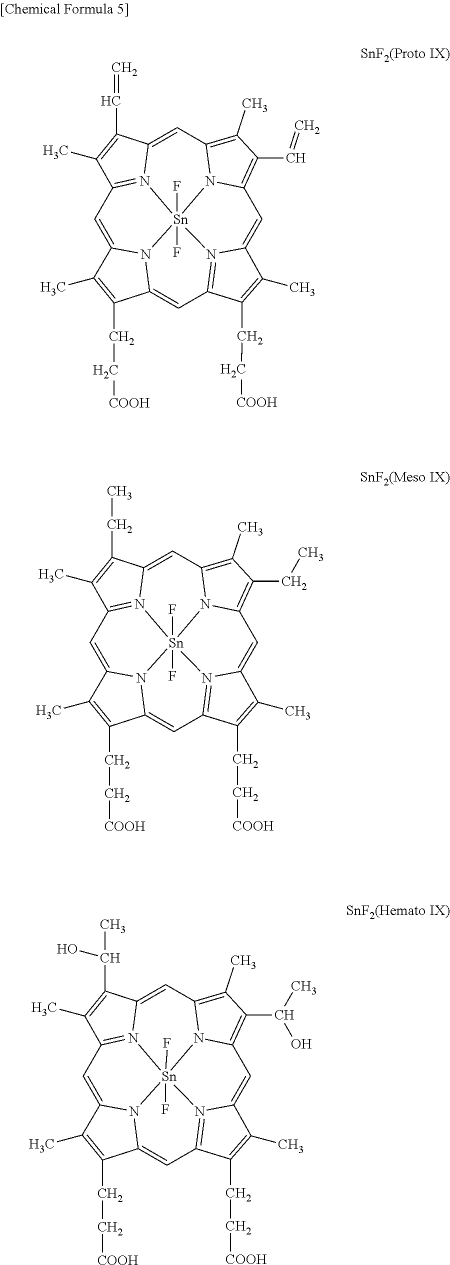

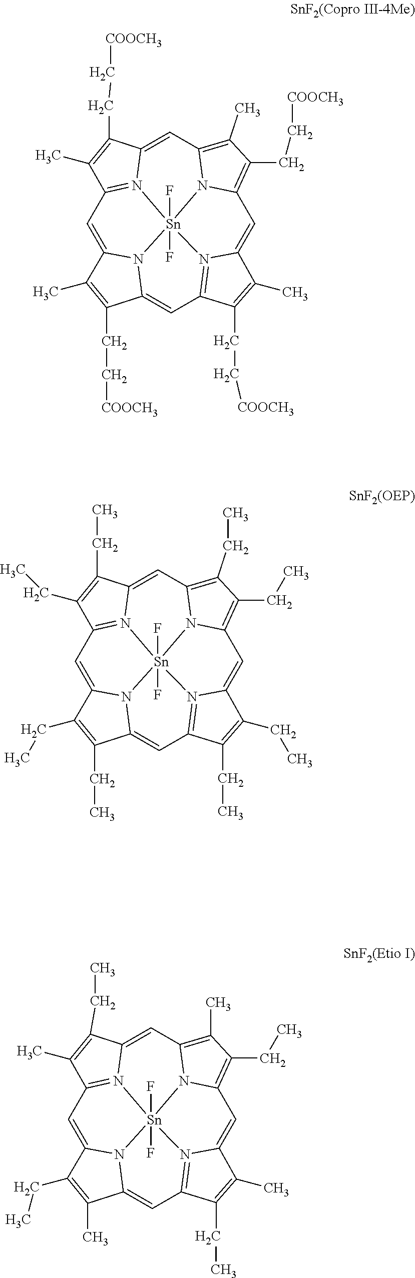

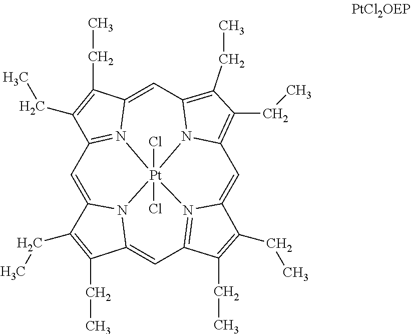

Alternatively, a heterocyclic compound having one or both of a π-electron rich heteroaromatic ring and a π-electron deficient heteroaromatic ring and represented by any of the following structure formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. Such a heterocyclic compound is preferable because of having high electron-transport and hole-transport properties owing to a π-electron rich heteroaromatic ring and a π-electron deficient heteroaromatic ring. Among skeletons having a π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having a π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which a π-electron rich heteroaromatic ring is directly bonded to a π-electron deficient heteroaromatic ring is particularly preferable because the electron-donating property of the π-electron rich heteroaromatic ring and the electron-accepting property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

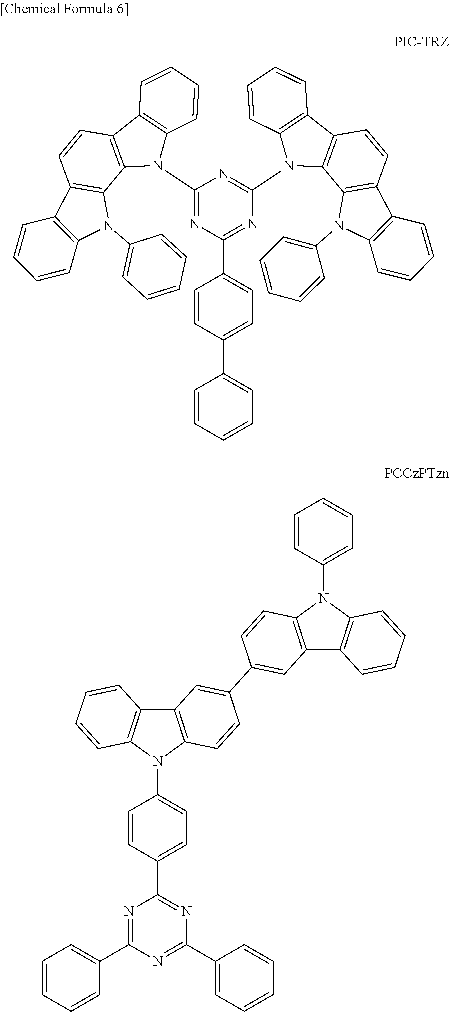 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

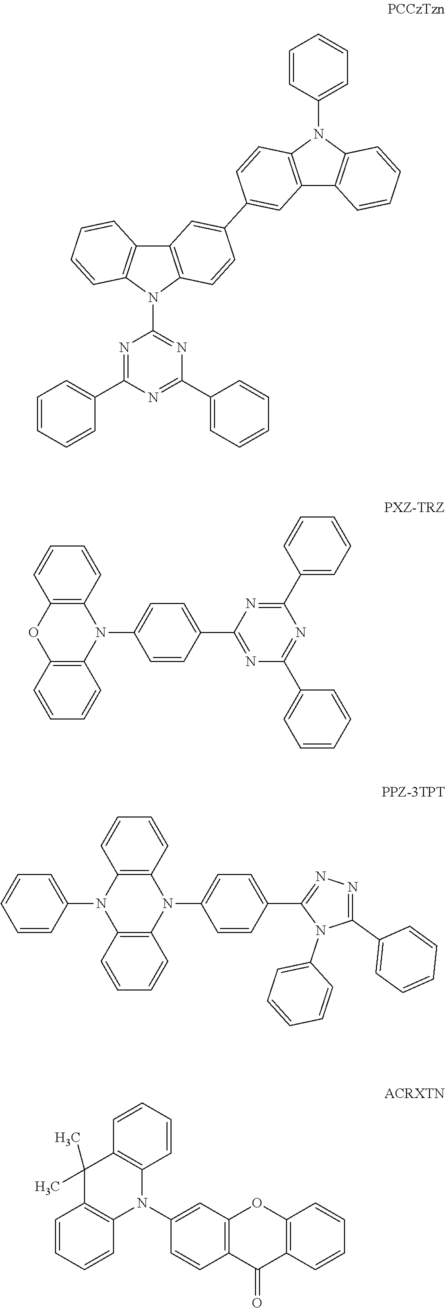 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21]

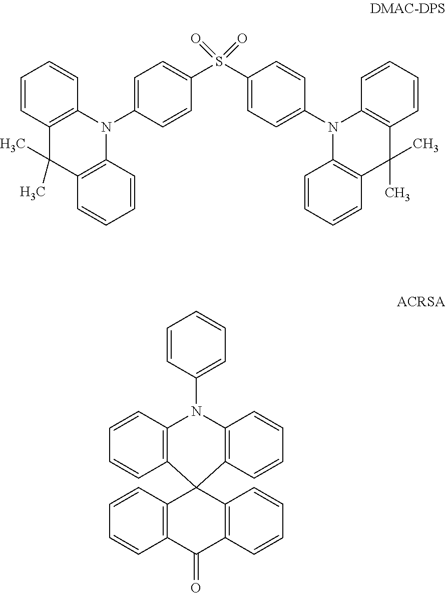 [SMILES: CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Alternatively, a TADF material whose singlet excited state and triplet excited state are in a thermal equilibrium state may be used. Such a TADF material has a short emission lifetime (excitation lifetime), inhibiting a decrease in the efficiency of a light-emitting device in a high-luminance region. Specifically, a material having the following molecular structure can be used.

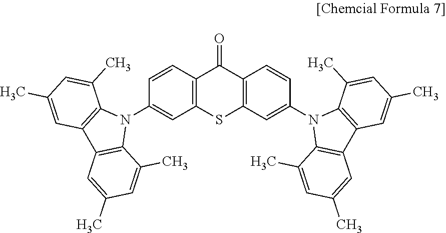

Note that a TADF material is a material having a small difference between the S₁ level and the T₁ level and a function of converting triplet excitation energy into singlet excitation energy by reverse intersystem crossing. Thus, a TADF material enables upconversion of triplet excitation energy into singlet excitation energy (i.e., reverse intersystem crossing) using a small amount of thermal energy and can efficiently generate a singlet excited state. In addition, the triplet excitation energy can be converted into light emission.

An exciplex whose excited state is formed by two kinds of substances has an extremely small difference between the S₁ level and the T₁ level and functions as a TADF material capable of converting triplet excitation energy into singlet excitation energy.

A phosphorescent spectrum observed at a low temperature (e.g., 77 K to 10 K) is used for an index of the T₁ level. When the level of energy with a wavelength of the line obtained by extrapolating a tangent to the fluorescent spectrum at a tail on the short wavelength side is the S₁ level and the level of energy with a wavelength of the line obtained by extrapolating a tangent to the phosphorescent spectrum at a tail on the short wavelength side is the T₁ level, the difference between the S₁ level and the T₁ level of the TADF material is preferably smaller than or equal to 0.3 eV, further preferably smaller than or equal to 0.2 eV.

When a TADF material is used as the light-emitting substance, the S₁ level of the host material is preferably higher than that of the TADF material. In addition, the T₁ level of the host material is preferably higher than that of the TADF material.

As the host material in the light-emitting layer, any of various carrier-transport materials such as materials with an electron-transport property and/or materials with a hole-transport property, and the TADF materials can be used.

As the material with a hole-transport property, the aforementioned material given as the material with a hole-transport property can be used similarly.

As the material with an electron-transport property, the aforementioned material given as the material with an electron-transport property can be used similarly.

As the TADF material that can be used as the host material, the aforementioned materials given as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material emitting light whose wavelength overlaps with the wavelength on the lowest-energy-side absorption band of the fluorescent substance, in which case excitation energy is transferred smoothly from the TADF material to the fluorescent substance and light emission can be obtained efficiently.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton that causes light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transport or carrier recombination. Here, the luminophore refers to an atomic group (skeleton) that causes light emission in a fluorescent substance. The luminophore is preferably a skeleton having a π bond, further preferably includes an aromatic ring, and still further preferably includes a condensed aromatic ring or a condensed heteroaromatic ring. Examples of such a luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer with high emission efficiency and high durability. Among the substances having an anthracene skeleton, a substance having a diphenylanthracene skeleton, in particular, a substance having a 9,10-diphenylanthracene skeleton, is chemically stable and thus is preferably used as the host material. The host material preferably has a carbazole skeleton to have higher hole-injection and hole-transport properties; further preferably, the host material has a benzocarbazole skeleton in which a benzene ring is further condensed to a carbazole skeleton, because the HOMO level of the host material having a benzocarbazole skeleton is shallower than that of the host material having a carbazole skeleton by approximately 0.1 eV and the host material having a benzocarbazole skeleton is thus easier for holes to enter than the host material having a carbazole skeleton. In particular, the host material preferably has a dibenzocarbazole skeleton, because the HOMO level of the host material having a dibenzocarbazole skeleton is shallower than that of the host material having a carbazole skeleton by approximately 0.1 eV, the host material having a dibenzocarbazole skeleton is thus easier for holes to enter than the host material having a carbazole skeleton, and the host material having a dibenzocarbazole skeleton has a higher hole-transport property and higher heat resistance than the host material having a carbazole skeleton. Accordingly, a substance having both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4′-(9-phenyl-9H-fluoren-9-yl)biphenyl-4-yl]anthracene (abbreviation: FLPPA), 9-(1-naphthyl)-10-[4-(2-naphthyl)phenyl]anthracene (abbreviation: αN-βNPAnth), 9-(1-naphthyl)-10-(2-naphthyl)anthracene (abbreviation: α,β-ADN), 2-(10-phenylanthracen-9-yl)dibenzofuran, 2-(10-phenyl-9-anthracenyl)-benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA have excellent characteristics and thus are preferably selected.

Note that the host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, a phosphorescent substance can be used as an energy donor supplying excitation energy to the fluorescent substance.

An exciplex may be formed by these mixed materials. These mixed materials are preferably selected so as to form an exciplex that exhibits light emission whose wavelength overlaps with the wavelength on the lowest-energy-side absorption band of the light-emitting substance, in which case energy can be transferred smoothly and light emission can be obtained efficiently. Such a structure is preferably used to reduce the driving voltage.

Note that at least one of the materials forming an exciplex may be a phosphorescent substance. In this case, triplet excitation energy can be efficiently converted into singlet excitation energy by reverse intersystem crossing.

Combination of a material having an electron-transport property and a material having a hole-transport property whose HOMO level is higher than or equal to that of the material having an electron-transport property is preferable for forming an exciplex efficiently. In addition, the LUMO level of the material having a hole-transport property is preferably higher than or equal to that of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of the mixed film in which the material having a hole-transport property and the material having an electron-transport property are mixed is shifted to the longer wavelength than the emission spectrum of each of the materials (or has another peak on the longer wavelength side) observed by comparison of the emission spectra of the material having a hole-transport property, the material having an electron-transport property, and the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of transient PL of the material having a hole-transport property, the material having an electron-transport property, and the mixed film of these materials. The transient PL can be rephrased as transient electroluminescence (EL). That is, the formation of an exciplex can also be confirmed by a difference in transient response observed by comparison of the transient EL of the material having a hole-transport property, the material having an electron-transport property, and the mixed film of these materials.

### <<Structure of Electron-Transport Layer>>

The electron-transport layer (the electron-transport layer 114, the first electron-transport layer 114_1, or the second electron-transport layer 114_2) includes a substance with an electron-transport property. The substance with an electron-transport property is preferably a substance having an electron mobility higher than or equal to 1′10⁻⁷ cm²/Vs, further preferably higher than or equal to 1′10⁻⁶ cm²/Vs, when the square root of electric field strength [V/cm] is 600. Note that any other substance can be used as long as the substance has an electron-transport property higher than a hole-transport property. An organic compound having a π-electron deficient heteroaromatic ring is preferable as the above organic compound. The organic compound having a π-electron deficient heteroaromatic ring is preferably one or more of an organic compound having a heteroaromatic ring with an azole skeleton, an organic compound having a heteroaromatic ring with a pyridine skeleton, an organic compound having a heteroaromatic ring with a diazine skeleton, and an organic compound having a heteroaromatic ring with a triazine skeleton.

As the organic compound with an electron-transport property that can be used for the electron-transport layer, any of the above organic compounds that can be used as the organic compound having an electron-transport property in the first layer of the intermediate layer 160 can be used similarly. Among the above organic compounds, the organic compound having a heteroaromatic ring with a diazine skeleton, the organic compound having a heteroaromatic ring with a pyridine skeleton, and the organic compound having a heteroaromatic ring with a triazine skeleton have high reliability and thus are preferable. In particular, the organic compound having a heteroaromatic ring with a diazine (pyrimidine or pyrazine) skeleton and the organic compound having a heteroaromatic ring with a triazine skeleton have a high electron-transport property to contribute to a reduction in driving voltage.

The electron mobility of the electron-transport layer is preferably higher than or equal to 1′10⁻⁷ cm²/Vs and lower than or equal to 5′10⁻⁵ cm²/Vs, when the square root of the electric field strength [V/cm] is 600. The amount of electrons injected into the light-emitting layer can be controlled by the reduction in the electron-transport property of the electron-transport layer, whereby the light-emitting layer can be prevented from having excess electrons. It is particularly preferable to employ this structure when the material with a hole-transport property in the hole-injection layer has a relatively deep HOMO level higher than or equal to −5.7 eV or and lower than or equal to −5.4 eV, in which case a long lifetime can be achieved. In this case, the material with an electron-transport property preferably has a HOMO level higher than or equal to −6.0 eV.

### <<Structure of Electron-Injection Layer>>

As the electron-injection layer 115, a layer that includes an alkali metal, an alkaline earth metal, a rare earth metal, a compound of an alkali metal, an alkaline earth metal, or a rare earth metal, or a complex of an alkali metal, an alkaline earth metal, or a rare earth metal, such as lithium fluoride (LiF), cesium fluoride (CsF), calcium fluoride (CaF₂), 8-quinolinolato-lithium (abbreviation: Liq), or ytterbium (Yb) may be provided. An electride or a layer that is formed using a substance with an electron-transport property and that includes an alkali metal, an alkaline earth metal, or a compound of an alkali metal or an alkaline earth metal may be used as the electron-injection layer 115. Examples of the electride include a substance in which electrons are added at a high concentration to calcium oxide-aluminum oxide.

Note that as the electron-injection layer 115, it is possible to use a layer including a substance that has an electron-transport property (preferably an organic compound having a bipyridine skeleton) and includes a fluoride of the alkali metal or the alkaline earth metal at a concentration higher than or equal to that at which the electron-injection layer 115 becomes in a microcrystalline state (50 wt % or higher). Since the layer has a low refractive index, a light-emitting device including the layer can have high external quantum efficiency.

The first or second organic compound described in Embodiment 1 can be used for the electron-injection layer 115. The electron-injection layer 115 may include a substance with an electron-transport property in addition to the first or second organic compound described in Embodiment 1.

### <<Structure of Second Electrode>>

The second electrode 102 includes a cathode. The second electrode 102 may have a stacked-layer structure where the layer in contact with the organic compound layer 103 functions as the cathode. As a substance of the cathode, any of metals, alloys, and electrically conductive compounds with a low work function (specifically, lower than or equal to 3.8 eV), mixtures thereof, and the like can be used. Specific examples of such a cathode material include elements belonging to Group 1 and Group 2 of the periodic table, such as alkali metals (e.g., lithium (Li) or cesium (Cs)), magnesium (Mg), calcium (Ca), and strontium (Sr), alloys containing any of these elements (e.g., MgAg and AlLi), rare earth metals such as europium (Eu) and ytterbium (Yb), and alloys containing any of these rare earth metals. However, when the electron-injection layer is provided between the second electrode 102 and the electron-transport layer, any of a variety of conductive materials such as Al, Ag, ITO, or indium oxide-tin oxide containing silicon or silicon oxide can be used for the cathode regardless of the work function.

When the second electrode 102 is formed using a material transmitting visible light, the light-emitting device can emit light from the second electrode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

The organic compound layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different methods may be used to form the electrodes or the layers described above.

This embodiment can be combined as appropriate with any of the other embodiments and examples. In this specification, in the case where a plurality of structure examples are shown in one embodiment, the structure examples can be combined as appropriate.

### Embodiment 3

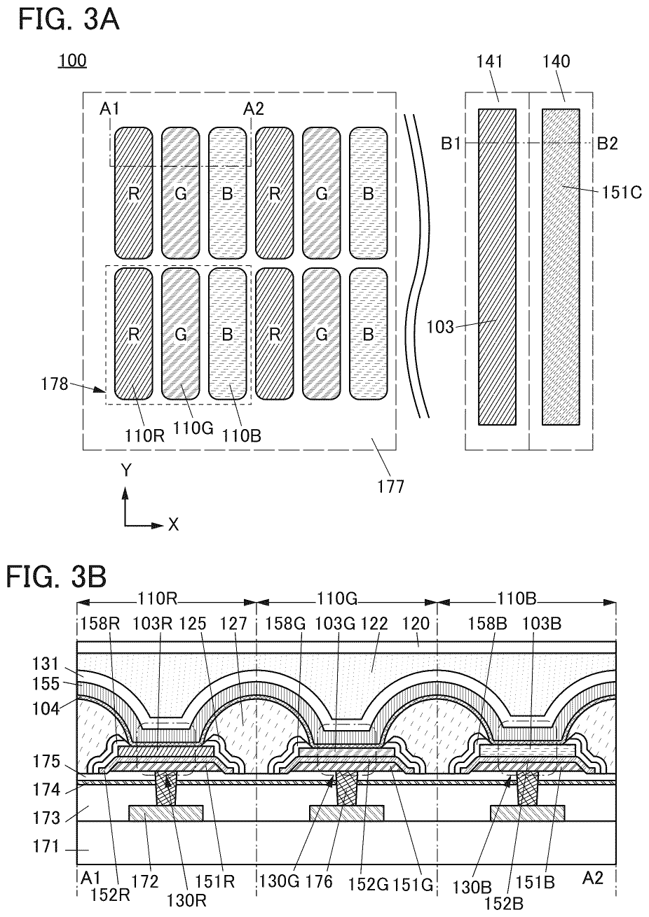

As illustrated in FIGS. 3A and 3B, a plurality of the light-emitting devices 130 are formed over the insulating layer 175 to constitute a display apparatus. In this embodiment, the display apparatus of one embodiment of the present invention will be described in detail.

A display apparatus 100 includes a pixel portion 177 in which a plurality of pixels 178 are arranged in matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared (IR) light.

In this specification and the like, the row direction and the column direction are sometimes referred to as the X direction and the Y direction, respectively. The X direction and the Y direction intersect with each other and are perpendicular to each other, for example.

FIG. 3A illustrates an example where subpixels of different colors are arranged in the X direction and subpixels of the same color are arranged in the Y direction. Note that subpixels of different colors may be arranged in the Y direction, and subpixels of the same color may be arranged in the X direction.

A connection portion 140 and a region 141 may be provided outside the pixel portion 177, and the region 141 is provided between the pixel portion 177 and the connection portion 140. The organic compound layer 103 is provided in the region 141. A conductive layer 151C is provided in the connection portion 140.

Although FIG. 3A illustrates an example where the region 141 and the connection portion 140 are located on the right side of the pixel portion 177, there is no particular limitation on the positions of the region 141 and the connection portion 140. The number of regions 141 and the number of connection portions 140 can each be one or more.

FIG. 3B is a cross-sectional view along the dashed-dotted line A1-A2 in FIG. 3A. As illustrated in FIG. 3B, the display apparatus 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is attached to the protective layer 131 with a resin layer 122. An inorganic insulating layer 125 and an insulating layer 127 over the inorganic insulating layer 125 are preferably provided between the adjacent light-emitting devices 130.

Although each of the inorganic insulating layer 125 and the insulating layer 127 looks like a plurality of layers in the cross-sectional view in FIG. 3B, each of the inorganic insulating layer 125 and the insulating layer 127 is preferably one continuous layer when the display apparatus 100 is seen from above. In other words, the inorganic insulating layer 125 and the inorganic insulating layer 127 preferably include opening portions over first electrodes.

In FIG. 3B, a light-emitting device 130R, a light-emitting device 130G, and a light-emitting device 130B are each illustrated as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, 130G, or 130B may emit visible light of another color or infrared light.

The display apparatus of one embodiment of the present invention can be, for example, a top-emission display apparatus where light is emitted in the direction opposite to a substrate over which light-emitting devices are formed. Note that the display apparatus of one embodiment of the present invention may be of a bottom-emission type.

Examples of a light-emitting substance included in the light-emitting device 130 include organic compounds or organometallic complexes such as a substance emitting fluorescent light (a fluorescent material), a substance emitting phosphorescent light (a phosphorescent material), and a substance exhibiting thermally activated delayed fluorescence (a thermally activated delayed fluorescent (TADF) material). Other examples include inorganic compounds (e.g., a quantum dot material).

The light-emitting device 130R has a structure as described in Embodiment 1. The light-emitting device 130R includes the first electrode (pixel electrode) including a conductive layer 151R and a conductive layer 152R, an organic compound layer 103R over the first electrode, a common layer 104 over the organic compound layer 103R, and a second electrode (common electrode) 155 over the common layer 104. Although the common layer 104 is not necessarily provided, it is preferable to provide the common layer 104 to reduce damage to the organic compound layer 103R during processing. In the case where the common layer 104 is provided, the common layer 104 is preferably an electron-injection layer. Furthermore, in the case where the common layer 104 is provided, a stack of the organic compound layer 103R and the common layer 104 corresponds to the organic compound layer 103 described in Embodiment 2.

The light-emitting device 130G has a structure as described in Embodiment 1. The light-emitting device 130G includes the first electrode (pixel electrode) including a conductive layer 151G and a conductive layer 152G, an organic compound layer 103G over the first electrode, the common layer 104 over the organic compound layer 103G, and the second electrode (common electrode) 155 over the common layer 104. Although the common layer 104 is not necessarily provided, it is preferable to provide the common layer 104 to reduce damage to the organic compound layer 103G during processing. In the case where the common layer 104 is provided, the common layer 104 is preferably an electron-injection layer. Furthermore, in the case where the common layer 104 is provided, a stack of the organic compound layer 103G and the common layer 104 corresponds to the organic compound layer 103 described in Embodiment 2.

The light-emitting device 130B has a structure as described in Embodiment 1. The light-emitting device 130B includes the first electrode (pixel electrode) including a conductive layer 151B and a conductive layer 152B, an organic compound layer 103B over the first electrode, the common layer 104 over the organic compound layer 103B, and the second electrode (common electrode) 155 over the common layer 104. Although the common layer 104 is not necessarily provided, it is preferable to provide the common layer 104 to reduce damage to the organic compound layer 103B during processing. In the case where the common layer 104 is provided, the common layer 104 is preferably an electron-injection layer. Furthermore, in the case where the common layer 104 is provided, a stack of the organic compound layer 103B and the common layer 104 corresponds to the organic compound layer 103 described in Embodiment 2.

In the light-emitting device, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layers 103R, the organic compound layers 103G, and the organic compound layers 103B are island-shaped layers that are separate from each other; alternatively, an organic compound layer of the light-emitting devices of one emission color may be separate from an organic compound layer of the light-emitting devices of another emission color. Providing the island-shaped organic compound layer 103 in each of the light-emitting devices 130 can inhibit leakage current between the adjacent light-emitting devices 130 even in a high-resolution display apparatus. This can prevent crosstalk, so that a display apparatus with extremely high contrast can be obtained. Specifically, a display apparatus having high current efficiency at low luminance can be obtained.

The island-shaped organic compound layer 103 is formed by forming an EL film and processing the EL film by a lithography method.

In the display apparatus of one embodiment of the present invention, the first electrode (pixel electrode) of the light-emitting device preferably has a stacked-layer structure. For example, in the example illustrated in FIG. 3B, the first electrode of the light-emitting device 130 is a stack of the conductive layer 151 and the conductive layer 152. In the case where the display apparatus 100 is of a top-emission type and the pixel electrode of the light-emitting device 130 functions as the anode, for example, the conductive layer 151 preferably has high visible light reflectance, and the conductive layer 152 preferably has a visible-light-transmitting property and a high work function. In the case where the display apparatus 100 is of a top-emission type, the higher the visible light reflectance of the pixel electrode is, the higher the efficiency of extraction of the light emitted by the organic compound layer 103 is. In the case where the pixel electrode functions as the anode, the higher the work function of the pixel electrode is, the easier hole injection into the organic compound layer 103 is. Accordingly, when the pixel electrode of the light-emitting device 130 is a stack of the conductive layer 151 with high visible light reflectance and the conductive layer 152 with a high work function, the light-emitting device 130 can have high light extraction efficiency and a low driving voltage.

In the case where the conductive layer 151 has high visible light reflectance, the visible light reflectance of the conductive layer 151 is preferably higher than or equal to 40% and lower than or equal to 100%, further preferably higher than or equal to 70% and lower than or equal to 100%, for example. When used as an electrode having a visible-light-transmitting property, the conductive layer 152 preferably has a visible light transmittance higher than or equal to 40%, for example.

Here, such a pixel electrode being a stack composed of a plurality of layers might change in quality as a result of, for example, a reaction between the plurality of layers. For example, when a film formed after the formation of the pixel electrode is removed by a wet etching method, contact of a chemical solution with the pixel electrode might cause galvanic corrosion.

In view of the above, the conductive layer 152 is formed to cover the top surface and the side surface of the conductive layer 151 in the display apparatus 100 of this embodiment. This can inhibit a chemical solution from coming into contact with the conductive layer 151 when a film that is formed after formation of the pixel electrode including the conductive layer 151 and the conductive layer 152 is removed by a wet etching method, for example. Accordingly, occurrence of galvanic corrosion in the pixel electrode can be inhibited, for example. This allows the display apparatus 100 to be manufactured by a high-yield method and to be accordingly inexpensive. In addition, generation of a defect in the display apparatus 100 can be inhibited, which makes the display apparatus 100 highly reliable.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layer 151 and the conductive layer 152 may each be a stack of a plurality of layers that include different materials. In this case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

The conductive layer 151 preferably has an end portion with a tapered shape. Specifically, the end portion of the conductive layer 151 preferably has a tapered shape with a taper angle less than 90°. In that case, the conductive layer 152 provided along the side surface of the conductive layer 151 also has a tapered shape. When the side surface of the conductive layer 152 has a tapered shape, coverage with the organic compound layer 103 provided along the side surface of the conductive layer 152 can be improved.

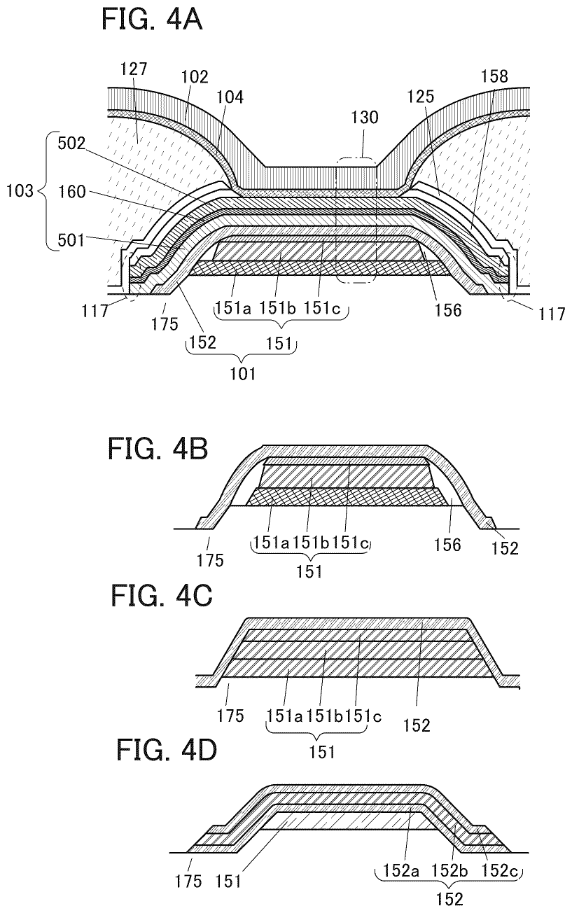

FIG. 4A illustrates the cases where the conductive layer 151 has a stacked-layer structure of a plurality of layers that include different materials. As illustrated in FIG. 4A, the conductive layer 151 includes a conductive layer 151a, a conductive layer 151b over the conductive layer 151a, and a conductive layer 151c over the conductive layer 151b. In other words, the conductive layer 151 illustrated in FIG. 4A has a three-layer structure. In the case where the conductive layer 151 has a stacked-layer structure of a plurality of layers as described above, the visible light reflectance of at least one of the layers included in the conductive layer 151 is made higher than that of the conductive layer 152.

In the example illustrated in FIG. 4A, the conductive layer 151b is sandwiched between the conductive layers 151a and 151c. A material that is less likely to change in quality than the material for the conductive layer 151b is preferably used for the conductive layers 151a and 151c. The conductive layer 151a can be formed using, for example, a material that is less likely to migrate owing to contact with the insulating layer 175 than the material for the conductive layer 151b. The conductive layer 151c can be formed using a material an oxide of which has lower electrical resistivity than an oxide of the material for the conductive layer 151b and which is less likely to be oxidized than the material for the conductive layer 151b.

In this manner, the structure where the conductive layer 151b is sandwiched between the conductive layers 151a and 151c can expand the range of choices for the material for the conductive layer 151b. The conductive layer 151b, for example, can thus have higher visible light reflectance than at least one of the conductive layers 151a and 151c. For example, aluminum can be used for the conductive layer 151b. The conductive layer 151b may be formed using an alloy containing aluminum. The conductive layer 151a can be formed using titanium; titanium has lower visible light reflectance than aluminum but is less likely to migrate owing to contact with the insulating layer 175 than aluminum. Furthermore, the conductive layer 151c can be formed using titanium; titanium is less likely to be oxidized than aluminum and an oxide of titanium has lower electrical resistivity than aluminum oxide, although titanium has lower visible light reflectance than aluminum.

The conductive layer 151c may be formed using silver or an alloy containing silver. Silver is characterized by its visible light reflectance higher than that of titanium. In addition, silver is characterized by being less likely to be oxidized than aluminum, and silver oxide is characterized by having electrical resistivity lower than that of aluminum oxide. Thus, the conductive layer 151c formed using silver or an alloy containing silver can favorably increase the visible light reflectance of the conductive layer 151 and inhibit an increase in the electrical resistance of the pixel electrode due to oxidation of the conductive layer 151b. Here, as the alloy containing silver, an alloy of silver, palladium, and copper (also referred to as Ag—Pd—Cu or APC) can be used, for example. When the conductive layer 151c is formed using silver or an alloy containing silver and the conductive layer 151b is formed using aluminum, the visible light reflectance of the conductive layer 151c can be higher than that of the conductive layer 151b. Here, the conductive layer 151b may be formed using silver or an alloy containing silver. The conductive layer 151a may be formed using silver or an alloy containing silver.

Meanwhile, a film formed using titanium has better processability in etching than a film formed using silver. Thus, use of titanium for the conductive layer 151c can facilitate formation of the conductive layer 151c. Note that a film formed using aluminum also has better processability in etching than a film formed using silver.

The conductive layer 151 having a stacked-layer structure of a plurality of layers as described above can improve the characteristics of the display apparatus. For example, the display apparatus 100 can have high light extraction efficiency and high reliability.

Here, in the case where the light-emitting device 130 has a microcavity structure, use of silver or an alloy containing silver, i.e., a material with high visible light reflectance, for the conductive layer 151c can favorably increase the light extraction efficiency of the display apparatus 100.

As already described above, the conductive layer 151 preferably has a side surface with a tapered shape. Specifically, the side surface of the conductive layer 151 preferably has a tapered shape with a taper angle less than 90°. For example, in the conductive layer 151 illustrated in FIG. 4A, the side surface of at least one of the conductive layer 151a, the conductive layer 151b, and the conductive layer 151c preferably has a tapered shape.

The conductive layer 151 illustrated in FIG. 4A can be formed by a lithography method. Specifically, first, a conductive film to be the conductive layer 151a, a conductive film to be the conductive layer 151b, and a conductive film to be the conductive layer 151c are sequentially formed. Next, a resist mask is formed over the conductive film to be the conductive layer 151c. Then, the conductive film in the region not overlapping with the resist mask is removed by etching. Here, when the conductive film is processed under conditions where the resist mask is easily recessed (reduced in size) as compared to the case where the conductive layer 151 is formed such that the side surface does not have a tapered shape (i.e., the conductive layer 151 is formed to have a perpendicular side surface), the side surface of the conductive layer 151 can have a tapered shape.

Here, when the conductive film is processed under conditions where the resist mask is easily recessed (reduced in size), the conductive film might be easily processed in the horizontal direction. That is, the etching sometimes might become isotropic as compared to the case where the conductive layer 151 is formed to have a perpendicular side surface.

In the case where the conductive layer 151 is a stack of a plurality of layers formed of different materials, the plurality of layers sometimes differ in processability in the horizontal direction. For example, the conductive layer 151a, the conductive layer 151b, and the conductive layer 151c sometimes differ in processability in the horizontal direction.

In that case, after the processing of the conductive film, as illustrated in FIG. 4A, the side surface of the conductive layer 151b may be positioned inward from the side surfaces of the conductive layers 151a and 151c and a protruding portion may be formed. This might impair coverage of the conductive layer 151 with the conductive layer 152 and cause step disconnection of the conductive layer 152.

In view of this, an insulating layer 156 is preferably provided as illustrated in FIG. 4A. FIG. 4A illustrates an example where the insulating layer 156 is provided over the conductive layer 151a to include a region overlapping with the side surface of the conductive layer 151b. In this structure, occurrence of step disconnection or thinning of the conductive layer 152 due to the protruding portion can be inhibited, so that poor connection or an increase in driving voltage can be inhibited.

Although FIG. 4A illustrates the structure where the side surface of the conductive layer 151b is entirely covered with the insulating layer 156, part of the side surface of the conductive layer 151b is not necessarily covered with the insulating layer 156. Also in a pixel electrode with a later-described structure, part of the side surface of the conductive layer 151b is not necessarily covered with the insulating layer 156.

In the case where the conductive layer 151 has the structure illustrated in FIG. 4A, the conductive layer 152 is provided to cover the conductive layers 151a, 151b, and 151c and the insulating layer 156 and to be electrically connected to the conductive layers 151a, 151b, and 151c. This can prevent a chemical solution from coming into contact with the conductive layers 151a, 151b, and 151c when a film formed after formation of the conductive layer 152 is removed by a wet etching method, for example. It is thus possible to inhibit occurrence of corrosion in the conductive layers 151a, 151b, and 151c. Hence, the display apparatus 100 can be fabricated by a high-yield method. Moreover, the display apparatus 100 can have high reliability since generation of defects is inhibited therein.

Here, the insulating layer 156 preferably has a curved surface as illustrated in FIG. 4A. In that case, step disconnection in the conductive layer 152 covering the insulating layer 156 is less likely to occur than in the case where the insulating layer 156 has a perpendicular side surface (a side surface parallel to the Z direction), for example. In addition, step disconnection in the conductive layer 152 covering the insulating layer 156 is less likely to occur also in the case where the side surface of the insulating layer 156 has a tapered shape, or specifically, a tapered shape with a taper angle less than 90°, than in the case where the insulating layer 156 has a perpendicular side surface, for example. As described above, the display apparatus 100 can be fabricated by a high-yield method. Moreover, the display apparatus 100 can have high reliability since generation of defects is inhibited therein.

FIG. 4A illustrates the structure where the side surface of the conductive layer 151b is located inward from that of the conductive layer 151a and that of the conductive layer 151c; however, one embodiment of the present invention is not limited to this structure. For example, the side surface of the conductive layer 151b may be located outward from that of the conductive layer 151a. The side surface of the conductive layer 151b may be located outward from that of the conductive layer 151c.

FIGS. 4B to 4D illustrate other structures of the first electrode 101. FIG. 4B illustrates a variation structure of the first electrode 101 in FIG. 4A, in which the insulating layer 156 covers the side surfaces of the conductive layers 151a, 151b, and 151c instead of covering only the side surface of the conductive layer 151b.

FIG. 4C illustrates a variation structure of the first electrode 101 in FIG. 4A, in which the insulating layer 156 is not provided.

FIG. 4D illustrates a variation structure of the first electrode 101 in FIG. 4A, in which the conductive layer 151 does not have a stacked-layer structure but the conductive layer 152 has a stacked-layer structure.

A conductive layer 152a has higher adhesion to a conductive layer 152b than the insulating layer 175 does, for example. For the conductive layer 152a, an oxide containing one or more selected from indium, tin, zinc, gallium, titanium, aluminum, and silicon, for example, can be used. For example, it is preferable to use a conductive oxide containing one or more of indium oxide, indium tin oxide, indium zinc oxide, zinc oxide, zinc oxide containing gallium, titanium oxide, indium titanium oxide, zinc titanate, aluminum zinc oxide, indium zinc oxide containing gallium, indium zinc oxide containing aluminum, indium tin oxide containing silicon, indium zinc oxide containing silicon, and the like. Accordingly, peeling of the conductive layer 152b can be inhibited. The conductive layer 152b is not in contact with the insulating layer 175.

The conductive layer 152b is a layer whose visible light reflectance (e.g., reflectance with respect to light with a predetermined wavelength longer than or equal to 400 nm and shorter than 750 nm) is higher than that of the conductive layers 151, 152a, and 152c. The visible light reflectance of the conductive layer 152b can be, for example, higher than or equal to 70% and lower than or equal to 100%, and is preferably higher than or equal to 80% and lower than or equal to 100%, further preferably higher than or equal to 90% and lower than or equal to 100%. For the conductive layer 152b, a material having higher visible light reflectance than aluminum can be used, for example. Specifically, for the conductive layer 152b, silver or an alloy containing silver can be used, for example. An example of the alloy containing silver is an alloy of silver, palladium, and copper (APC). In the above manner, the display apparatus 100 can have high light extraction efficiency. Note that a metal other than silver may be used for the conductive layer 152b.

When the conductive layers 151 and 152 serve as the anode, a layer having a high work function is preferably used as the conductive layer 152c. The conductive layer 152c has a higher work function than the conductive layer 152b, for example. For the conductive layer 152c, a material similar to the material usable for the conductive layer 152a can be used, for example. For example, the conductive layers 152a and 152c can be formed using the same kind of material. For example, in the case where indium tin oxide is used for the conductive layer 152a, indium tin oxide can also be used for the conductive layer 152c.

When the conductive layers 151 and 152 serve as the cathode, the conductive layer 152c is preferably a layer having a low work function. The conductive layer 152c has a lower work function than the conductive layer 152b, for example.

The conductive layer 152c is preferably a layer having high visible light transmittance (e.g., transmittance with respect to light with a predetermined wavelength longer than or equal to 400 nm and shorter than 750 nm). For example, the visible light transmittance of the conductive layer 152c is preferably higher than that of the conductive layers 151 and 152b. The visible light transmittance of the conductive layer 152c can be, for example, higher than or equal to 60% and lower than or equal to 100%, and is preferably higher than or equal to 70% and lower than or equal to 100%, further preferably higher than or equal to 80% and lower than or equal to 100%. In that case, the amount of light that is absorbed by the conductive layer 152c after being emitted from the organic compound layer 103 can be reduced. As described above, the conductive layer 152b under the conductive layer 152c can be a layer having high visible light reflectance. Thus, the display apparatus 100 can have high light extraction efficiency.

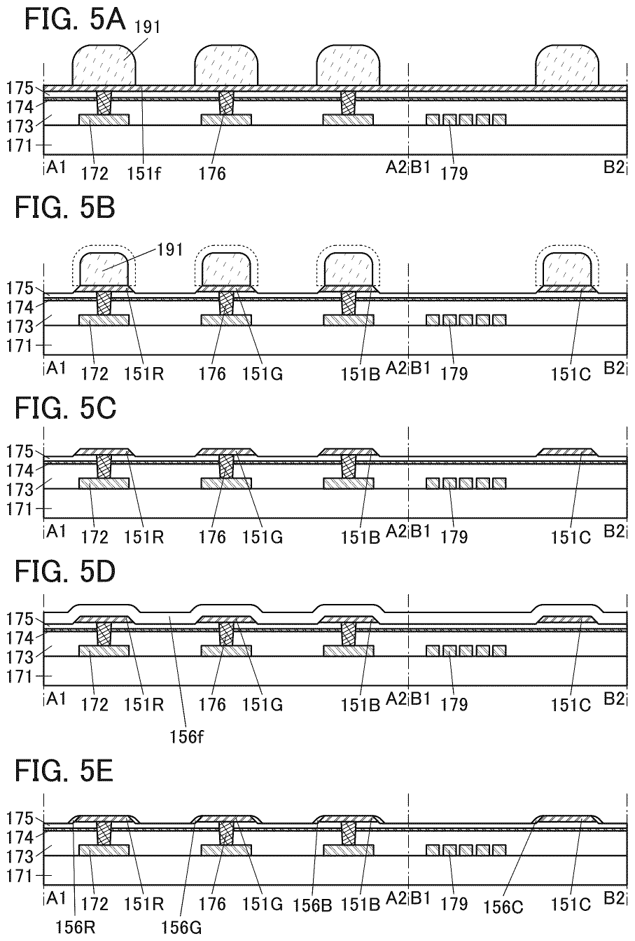

Next, a method for manufacturing the display apparatus 100 having the structure illustrated in FIG. 3A is described with reference to FIGS. 5A to 5E, FIGS. 6A to 6D, FIGS. 7A to 7D, FIGS. 8A to 8C, FIGS. 9A to 9C, and FIGS. 10A to 10C. The organic compound layer of the light-emitting device included in the display apparatus 100 is formed by manufacturing steps including treatment using water. The use of the composite material described in Embodiment 1 for the organic compound layer of the light-emitting device included in the display apparatus of one embodiment of the present invention prevents problems such as dissolution of the organic compound layer and permeation of a chemical solution into the organic compound layer even in the manufacture by a manufacturing method including treatment using water; consequently, the light-emitting device can have favorable characteristics.

### [Manufacturing Method Example]

Thin films included in the display apparatus (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a plasma-enhanced CVD (PECVD) method and a thermal CVD method. An example of a thermal CVD method is a metal organic CVD (MOCVD) method.

Thin films included in the display apparatus (e.g., insulating films, semiconductor films, and conductive films) can also be formed by a wet film-formation method such as spin coating, dipping, spray coating, ink-jetting, dispensing, screen printing, offset printing, doctor blade coating, slit coating, roll coating, curtain coating, or knife coating.

Specifically, for fabrication of the light-emitting device, a vacuum process such as an evaporation method and a solution process such as a spin coating method or an ink-jet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, the functional layers (e.g., the hole-injection layer, the hole-transport layer, the hole-blocking layer, the light-emitting layer, the electron-blocking layer, the electron-transport layer, and the electron-injection layer) included in the organic compound layer can be formed by an evaporation method (e.g., a vacuum evaporation method), a coating method (e.g., a dip coating method, a die coating method, a bar coating method, a spin coating method, or a spray coating method), a printing method (e.g., ink-jetting, screen printing (stencil), offset printing (planography), flexography (relief printing), gravure printing, or micro-contact printing), or the like.

Thin films included in the display apparatus can be processed by a lithography method, for example. Alternatively, a nanoimprinting method, a sandblasting method, a lift-off method, or the like may be used to process thin films. Alternatively, island-shaped thin films may be directly formed by a film formation method using a shielding mask such as a metal mask.

As a lithography method, for example, a photolithography method can be used. There are two typical examples of photolithography methods. In one of the methods, a resist mask is formed over a thin film that is to be processed, the thin film is processed by etching, for example, and then the resist mask is removed. In the other method, a photosensitive thin film is formed and then processed into a desired shape by light exposure and development.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used. It is preferable to use EUV light, X-rays, or an electron beam to perform extremely minute processing. Note that when exposure is performed by scanning of a beam such as an electron beam, a photomask is not needed.

For etching of thin films, a dry etching method, a wet etching method, a sandblasting method, or the like can be used.

First, as illustrated in FIG. 5A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate having heat resistance high enough to withstand at least heat treatment performed later can be used. When an insulating substrate is used, it is possible to use a glass substrate, a quartz substrate, a sapphire substrate, a ceramic substrate, an organic resin substrate, or the like. Alternatively, it is possible to use a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 5A, openings reaching the conductive layer 172 are formed in the insulating layers 175, 174, and 173. Then, the plugs 176 are formed to fill the openings.

Next, as illustrated in FIG. 5A, a conductive film 151f to be the conductive layers 151R, 151G, 151B, and 151C is formed over the plugs 176 and the insulating layer 175. The conductive film 151f can be formed by a sputtering method or a vacuum evaporation method, for example. A metal material can be used for the conductive film 151f, for example.

Subsequently, a resist mask 191 is formed over the conductive film 151f as illustrated in FIG. 5A. The resist mask 191 can be formed by application of a photosensitive material (photoresist), light exposure, and development.

Subsequently, as illustrated in FIG. 5B, the conductive film 151f in a region not overlapping with the resist mask 191, for example, is removed by an etching method, specifically, a dry etching method, for instance. Note that in the case where the conductive film 151f includes a layer formed using a conductive oxide such as indium tin oxide, for example, the layer may be removed by a wet etching method. In this manner, the conductive layer 151 is formed. In the case where part of the conductive film 151f is removed by a dry etching method, for example, a recessed portion may be formed in a region of the insulating layer 175 not overlapping with the conductive layer 151.

Next, the resist mask 191 is removed as illustrated in FIG. 5C. The resist mask 191 can be removed by ashing using oxygen plasma, for example. Alternatively, an oxygen gas and any of CF₄, C₄F₈, SF₆, CHF₃, Cl₂, H₂O, BCl₃, and a Group 18 element such as He may be used. Alternatively, the resist mask 191 may be removed by wet etching.

Then, as illustrated in FIG. 5D, an insulating film 156f to be an insulating layer 156R, an insulating layer 156G, an insulating layer 156B, and an insulating layer 156C is formed over the conductive layer 151R, the conductive layer 151G, the conductive layer 151B, the conductive layer 151C, and the insulating layer 175. The insulating film 156f can be formed by a CVD method, an ALD method, a sputtering method, or a vacuum evaporation method, for example.

For the insulating film 156f, an inorganic material can be used. As the insulating film 156f, an inorganic insulating film such as an oxide insulating film, a nitride insulating film, an oxynitride insulating film, or a nitride oxide insulating film can be used, for example. For example, an oxide insulating film including silicon, a nitride insulating film including silicon, an oxynitride insulating film including silicon, a nitride oxide insulating film including silicon, or the like can be used as the insulating film 156f. For the insulating film 156f, silicon oxynitride can be used, for example.

Subsequently, as illustrated in FIG. 5E, the insulating film 156f is processed to form the insulating layers 156R, 156G, 156B, and 156C. The insulating layer 156 can be formed by performing etching substantially uniformly on the top surface of the insulating film 156f, for example. Such uniform etching for planarization is also referred to as etch back treatment. Note that the insulating layer 156 may be formed by a lithography method.

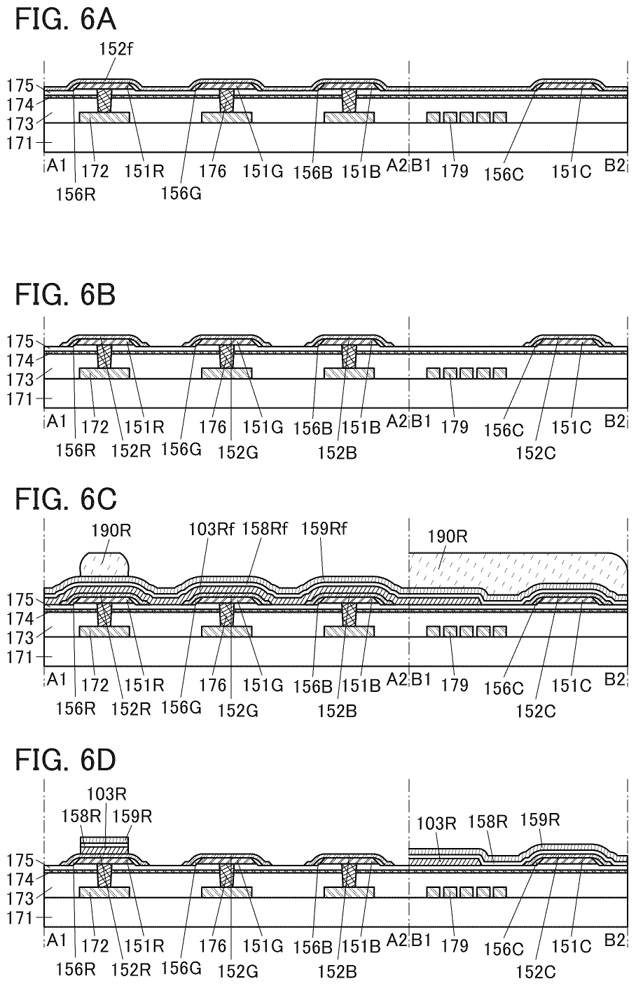

Then, as illustrated in FIG. 6A, a conductive film 152f to be the conductive layers 152R, 152G, and 152B and a conductive layer 152C is formed over the conductive layers 151R, 151G, 151B, and 151C and the insulating layers 156R, 156G, 156B, 156C, and 175. Specifically, the conductive film 152f is formed to cover the conductive layers 151R, 151G, 151B, and 151C and the insulating layers 156R, 156G, 156B, and 156C, for example.

The conductive film 152f can be formed by a sputtering method or a vacuum evaporation method, for example. A conductive oxide can be used for the conductive film 152f, for example. The conductive film 152f can be a stack of a film formed using a metal material and a film formed thereover using a conductive oxide. For example, the conductive film 152f can be a stack of a film formed using titanium, silver, or an alloy containing silver and a film formed thereover using a conductive oxide.

The conductive film 152f can be formed by an ALD method. In this case, for the conductive film 152f, an oxide containing one or more selected from indium, tin, zinc, gallium, titanium, aluminum, and silicon can be used. In this case, the conductive film 152f can be formed by repeating a cycle of introduction of a precursor (generally referred to as a metal precursor or the like in some cases), purge of the precursor, introduction of an oxidizer (generally referred to as a reactant, a non-metal precursor, or the like in some cases), and purge of the oxidizer. Here, in the case where an oxide film including a plurality of kinds of metals (e.g., an indium tin oxide film) is formed as the conductive film 152f, the composition of the metals can be controlled by varying the number of cycles for different kinds of precursors.

For example, in the case where an indium tin oxide film is formed as the conductive film 152f, after a precursor containing indium is introduced, the precursor is purged, and an oxidizer is introduced to form an In—O film, and then a precursor containing tin is introduced, the precursor is purged, and an oxidizer is introduced to form a Sn—O film. Here, when the number of cycles of forming an In—O film is larger than the number of cycles of forming a Sn—O film, the number of In atoms included in the conductive film 152f can be larger than the number of Sn atoms included therein.

For example, to form a zinc oxide film as the conductive film 152f, a Zn—O film is formed in the above procedure. For another example, to form an aluminum zinc oxide film as the conductive film 152f, a Zn—O film and an Al—O film are formed in the above procedure. For another example, to form a titanium oxide film as the conductive film 152f, a Ti—O film is formed in the above procedure. For another example, to form an indium tin oxide film including silicon as the conductive film 152f, an In—O film, a Sn—O film, and a Si—O film are formed in the above procedure. For another example, to form a zinc oxide film including gallium, a Ga—O film and a Zn—O film are formed in the above procedure.

As a precursor containing indium, it is possible to use, for example, triethylindium, trimethylindium, or [1,1,1-trimethyl-N-(trimethylsilyl)amide]-indium. As a precursor containing tin, it is possible to use, for example, tin chloride or tetrakis(dimethylamido)tin. As a precursor containing zinc, it is possible to use, for example, diethylzinc or dimethylzinc. As a precursor containing gallium, it is possible to use, for example, triethylgallium. As a precursor containing titanium, it is possible to use, for example, titanium chloride, tetrakis(dimethylamido)titanium, or tetraisopropyl titanate. As a precursor containing aluminum, it is possible to use, for example, aluminum chloride or trimethylaluminum. As a precursor containing silicon, it is possible to use, for example, trisilylamine, bis(diethylamino)silane, tris(dimethylamino)silane, bis(tert-butylamino)silane, or bis(ethylmethylamino)silane. As the oxidizer, water vapor, oxygen plasma, or an ozone gas can be used.

Then, as illustrated in FIG. 6B, the conductive film 152f is processed by a lithography method, for example, whereby the conductive layers 152R, 152G, 152B, and 152C are formed. Specifically, after a resist mask is formed, part of the conductive film 152f is removed by an etching method, for example. The conductive film 152f can be removed by a wet etching method, for example. The conductive film 152f may be removed by a dry etching method. Through the above steps, the pixel electrode including the conductive layer 151 and the conductive layer 152 is formed.

Next, hydrophobization treatment is preferably performed on the conductive layer 152. The hydrophobization treatment can change the hydrophilic properties of the subject surface to hydrophobic properties or increase the hydrophobic properties of the subject surface. The hydrophobization treatment for the conductive layer 152 can increase the adhesion between the conductive layer 152 and the organic compound layer 103 formed in a later step and inhibit film peeling. Note that the hydrophobization treatment is not necessarily performed.

Next, as illustrated in FIG. 6C, an organic compound film 103Rf to be the organic compound layer 103R is formed over the conductive layers 152R, 152G, and 152B and the insulating layer 175.

As illustrated in FIG. 6C, the organic compound film 103Rf is not formed over the conductive layer 152C. For example, a mask for defining a film formation area (also referred to as an area mask, a rough metal mask, or the like to be distinguished from a fine metal mask) is used, so that the organic compound film 103Rf can be formed only in a desired region. Employing a film formation step using an area mask and a processing step using a resist mask enables a light-emitting device to be fabricated by a relatively easy process.

The organic compound film 103Rf can be formed by an evaporation method, specifically a vacuum evaporation method, for example. The organic compound film 103Rf may be formed by a transfer method, a printing method, an ink-jet method, a coating method, or the like.

Next, as illustrated in FIG. 6C, a sacrificial film 158Rf to be a sacrificial layer 158R and a mask film 159Rf to be a mask layer 159R are sequentially formed over the organic compound film 103Rf, the conductive layer 152C, and the insulating layer 175.

Although this embodiment shows an example where a mask film having a two-layer structure of the sacrificial film 158Rf and the mask film 159Rf is formed, a mask film may have a single-layer structure or a stacked-layer structure of three or more layers.

Providing the sacrificial layer over the organic compound film 103Rf can reduce damage to the organic compound film 103Rf in the manufacturing process of the display apparatus, resulting in an increase in reliability of the light-emitting device.

As the sacrificial film 158Rf, a film that is highly resistant to the process conditions for the organic compound film 103Rf, specifically, a film having high etching selectivity with respect to the organic compound film 103Rf is used. For the mask film 159Rf, a film having high etching selectivity with respect to the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each lower than or equal to 200° C., preferably lower than or equal to 150° C., further preferably lower than or equal to 120° C., still further preferably lower than or equal to 100° C., yet still further preferably lower than or equal to 80° C.

The sacrificial film 158Rf and the mask film 159Rf are preferably films that can be removed by a wet etching method. The use of a wet etching method can reduce damage to the organic compound film 103Rf in processing of the sacrificial film 158Rf and the mask film 159Rf, as compared to the case of using a dry etching method.

The sacrificial film 158Rf and the mask film 159Rf can be formed by a sputtering method, an ALD method (including a thermal ALD method and a PEALD method), a CVD method, or a vacuum evaporation method, for example. Alternatively, the sacrificial film 158Rf and the mask film 159Rf may be formed by the above-described wet film-formation method.

Note that the sacrificial film 158Rf that is formed over and in contact with the organic compound film 103Rf is preferably formed by a formation method that is less likely to damage the organic compound film 103Rf than a formation method of the mask film 159Rf. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, and an inorganic insulating film, for example, can be used.

For each of the sacrificial film 158Rf and the mask film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. A metal material that can block ultraviolet rays is preferably used for one or both of the sacrificial film 158Rf and the mask film 159Rf, in which case the organic compound film 103Rf can be inhibited from being irradiated with ultraviolet rays and deteriorating.

The sacrificial film 158Rf and the mask film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In place of gallium described above, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

As each of the sacrificial film and the mask film, a film including a material having a light-blocking property, particularly with respect to ultraviolet rays, is preferably used. Although a variety of materials such as a metal, an insulator, a semiconductor, and a metalloid that have a property of blocking ultraviolet rays can be used as a light-blocking material, each of the sacrificial film and the mask film is preferably a film capable of being processed by etching and is particularly preferably a film having good processability because part or the whole of each of the sacrificial film and the mask film is removed in a later step.

The sacrificial film and the mask film are preferably formed using a semiconductor material such as silicon or germanium, for example, for excellent compatibility with a semiconductor manufacturing process. Alternatively, an oxide or a nitride of the semiconductor material can be used. A non-metallic material such as carbon or a compound thereof can be used. A metal such as titanium, tantalum, tungsten, chromium, or aluminum or an alloy containing at least one of these metals can be used. Alternatively, an oxide containing the above-described metal, such as titanium oxide or chromium oxide, or a nitride such as titanium nitride, chromium nitride, or tantalum nitride can be used.

When a film including a material having a property of blocking ultraviolet rays is used as each of the sacrificial film and the mask film, the organic compound layer can be inhibited from being irradiated with ultraviolet rays in a light exposure step, for example. The organic compound layer is inhibited from being damaged by ultraviolet rays, so that the reliability of the light-emitting device can be improved.

Note that the same effect is obtained when a film including a material having a property of blocking ultraviolet rays is used for an after-mentioned inorganic insulating film 125f.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film. For example, an inorganic insulating material such as aluminum oxide, hafnium oxide, or silicon oxide can be used for the sacrificial film 158Rf and the mask film 159Rf. As the sacrificial film 158Rf and the mask film 159Rf, aluminum oxide films can be formed by an ALD method, for example. An ALD method is preferably used, in which case damage to a base (in particular, the organic compound layer) can be reduced.

For example, an inorganic insulating film (e.g., an aluminum oxide film) formed by an ALD method can be used as the sacrificial film 158Rf, and an inorganic film (e.g., an In—Ga—Zn oxide film, an aluminum film, or a tungsten film) formed by a sputtering method can be used as the mask film 159Rf.

Note that the same inorganic insulating film can be used for both the sacrificial film 158Rf and the inorganic insulating layer 125 that is to be formed later. For example, an aluminum oxide film formed by an ALD method can be used for both the sacrificial film 158Rf and the inorganic insulating layer 125. For the sacrificial film 158Rf and the inorganic insulating layer 125, the same film formation conditions may be used or different film formation conditions may be used. For example, when the sacrificial film 158Rf is formed under conditions similar to those of the inorganic insulating layer 125, the sacrificial film 158Rf can be an insulating layer having a high barrier property against at least one of water and oxygen. Meanwhile, since the sacrificial film 158Rf is a layer a large part or the whole of which is to be removed in a later step, it is preferable that the processing of the sacrificial film 158Rf be easy. Therefore, the sacrificial film 158Rf is preferably formed with a substrate temperature lower than that for formation of the inorganic insulating layer 125.

One or both of the sacrificial film 158Rf and the mask film 159Rf may be formed using an organic material. For example, as the organic material, a material that can be dissolved in a solvent chemically stable with respect to at least the uppermost film of the organic compound film 103Rf may be used. Specifically, a material that will be dissolved in water or an alcohol can be suitably used. In forming a film of such a material, it is preferable to apply the material dissolved in a solvent such as water or an alcohol by a wet film-formation method and then perform heat treatment for evaporating the solvent. At this time, the heat treatment is preferably performed in a reduced-pressure atmosphere, in which case the solvent can be removed at a low temperature in a short time and thermal damage to the organic compound film 103Rf can be reduced accordingly.

The sacrificial film 158Rf and the mask film 159Rf may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluorine resin like perfluoropolymer.

For example, an organic film (e.g., a PVA film) formed by an evaporation method or any of the above wet film-formation methods can be used as the sacrificial film 158Rf, and an inorganic film (e.g., a silicon nitride film) formed by a sputtering method can be used as the mask film 159Rf.

Subsequently, a resist mask 190R is formed over the mask film 159Rf as illustrated in FIG. 6C. The resist mask 190R can be formed by application of a photosensitive material (photoresist), light exposure, and development.

The resist mask 190R may be formed using either a positive resist material or a negative resist material.

The resist mask 190R is provided at a position overlapping with the conductive layer 152R. The resist mask 190R is preferably provided also at a position overlapping with the conductive layer 152C. This can inhibit the conductive layer 152C from being damaged during the process of manufacturing the display apparatus. Note that the resist mask 190R is not necessarily provided over the conductive layer 152C. The resist mask 190R is preferably provided to cover the area from an end portion of the organic compound film 103Rf to an end portion of the conductive layer 152C (the end portion closer to the organic compound film 103Rf), as illustrated in the cross-sectional view along the line B1-B2 in FIG. 6C.

Next, as illustrated in FIG. 6D, part of the mask film 159Rf is removed using the resist mask 190R, so that the mask layer 159R is formed. The mask layer 159R remains over the conductive layers 152R and 152C. After that, the resist mask 190R is removed. Then, part of the sacrificial film 158Rf is removed using the mask layer 159R as a mask (also referred to as a hard mask), so that the sacrificial layer 158R is formed.

Each of the sacrificial film 158Rf and the mask film 159Rf can be processed by a wet etching method or a dry etching method. The sacrificial film 158Rf and the mask film 159Rf are preferably processed by isotropic etching.

The use of a wet etching method can reduce damage to the organic compound film 103Rf in processing of the sacrificial film 158Rf and the mask film 159Rf, as compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a chemical solution containing a mixed solution of any of these acids, for example.

Since the organic compound film 103Rf is not exposed in the processing of the mask film 159Rf, the range of choice for a processing method for the mask film 159Rf is wider than that for the sacrificial film 158Rf. Specifically, even in the case where a gas containing oxygen is used as the etching gas in the processing of the mask film 159Rf, deterioration of the organic compound film 103Rf can be inhibited.

In the case of using a dry etching method to process the sacrificial film 158Rf, deterioration of the organic compound film 103Rf can be inhibited by not using a gas containing oxygen as the etching gas. In the case of using a dry etching method, it is preferable to use a gas containing CF₄, C₄F₈, SF₆, CHF₃, Cl₂, H₂O, BCl₃, or a Group 18 element such as He, for example, as the etching gas.

For example, in the case where an aluminum oxide film formed by an ALD method is used as the sacrificial film 158Rf, part of the sacrificial film 158Rf can be removed by a dry etching method using CHF₃ and He or a combination of CHF₃, He, and CH₄. In the case where an In—Ga—Zn oxide film formed by a sputtering method is used as the mask film 159Rf, part of the mask film 159Rf can be removed by a wet etching method using diluted phosphoric acid. Alternatively, part of the mask film 159Rf may be removed by a dry etching method using CH₄ and Ar. Alternatively, part of the mask film 159Rf can be removed by a wet etching method using diluted phosphoric acid. In the case where a tungsten film formed by a sputtering method is used as the mask film 159Rf, part of the mask film 159Rf can be removed by a dry etching method using a combination of SF₆, CF₄, and O₂ or a combination of CF₄, Cl₂, and O₂.

The resist mask 190R can be removed by a method similar to that for the resist mask 191. For example, the resist mask 190R can be removed by ashing using oxygen plasma. Alternatively, an oxygen gas and any of CF₄, C₄F₈, SF₆, CHF₃, Cl₂, H₂O, BCl₃, and a Group 18 element such as He may be used. Alternatively, the resist mask 190R may be removed by wet etching. At this time, the sacrificial film 158Rf is located on the outermost surface, and the organic compound film 103Rf is not exposed; thus, the organic compound film 103Rf can be inhibited from being damaged in the step of removing the resist mask 190R. In addition, the range of choice for the method for removing the resist mask 190R can be widened.

Next, as illustrated in FIG. 6D, the organic compound film 103Rf is processed, so that the organic compound layer 103R is formed. For example, part of the organic compound film 103Rf is removed using the mask layer 159R and the sacrificial layer 158R as a hard mask to form the organic compound layer 103R.

Accordingly, as illustrated in FIG. 6D, the stacked-layer structure of the organic compound layer 103R, the sacrificial layer 158R, and the mask layer 159R remains over the conductive layer 152R. The conductive layers 152G and 152B are exposed.

In the example illustrated in FIG. 6D, an end portion of the organic compound layer 103R is located outward from an end portion of the conductive layer 152R. Such a structure can increase the aperture ratio of the pixel. Although not illustrated in FIG. 6D, by the above etching treatment, a recessed portion may be formed in the insulating layer 175 in a region not overlapping with the organic compound layer 103R.

Since the organic compound layer 103R covers the top surface and the side surface of the conductive layer 152R, the subsequent steps can be performed without exposure of the conductive layer 152R. If the end portion of the conductive layer 152R is exposed, there is a possibility that corrosion occurs in an etching step, for example. A product generated by corrosion of the conductive layer 152R may be unstable, and for example, might be dissolved in a solution when wet etching is performed and might be scattered in an atmosphere when dry etching is performed. By dissolution of the product in a solution or scattering of the product in the atmosphere, the product might be attached to a subject surface and the side surface of the organic compound layer 103R, for example, which might adversely affect the characteristics of the light-emitting device or form a leak path between a plurality of light-emitting devices. In a region where the end portion of the conductive layer 152R is exposed, adhesion between layers in contact with each other might be lowered, which might be likely to cause peeling of the organic compound layer 103R or the conductive layer 152R.

Accordingly, the structure where the organic compound layer 103R covers the top surface and the side surface of the conductive layer 152R can improve the yield and characteristics of the light-emitting device, for example.

As described above, the resist mask 190R is preferably provided to cover the area from the end portion of the organic compound layer 103R to the end portion of the conductive layer 152C (the end portion closer to the organic compound layer 103R) in the cross section along the dashed-dotted line B1-B2. In that case, as illustrated in FIG. 6D, the sacrificial layer 158R and the mask layer 159R are provided to cover the area from the end portion of the organic compound layer 103R to the end portion of the conductive layer 152C (the end portion closer to the organic compound layer 103R) in the cross section along the dashed-dotted line B1-B2. Hence, the insulating layer 175 can be inhibited from being exposed in the cross section along the dashed-dotted line B1-B2, for example. This can prevent the insulating layers 175, 174, and 173 from being partly removed by etching and thus prevent the conductive layer 179 from being exposed. Accordingly, the conductive layer 179 can be inhibited from being unintentionally electrically connected to another conductive layer. For example, a short circuit between the conductive layer 179 and a common electrode 155 formed in a later step can be inhibited.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Accordingly, damage to the organic compound film 103Rf can be reduced. Furthermore, a defect such as attachment of a reaction product generated in the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He and Ar as the etching gas, for example. Alternatively, a gas containing oxygen and at least one of the above is preferably used as the etching gas. Alternatively, an oxygen gas may be used as the etching gas. Specifically, for example, a gas containing H₂ and Ar or a gas containing CF₄ and He can be used as the etching gas. For another example, a gas containing CF₄, He, and oxygen can be used as the etching gas. For another example, a gas containing H₂ and Ar and a gas containing oxygen can be used as the etching gas.

As described above, in one embodiment of the present invention, the mask layer 159R is formed in the following manner: the resist mask 190R is formed over the mask film 159Rf and part of the mask film 159Rf is removed using the resist mask 190R. After that, part of the organic compound film 103Rf is removed using the mask layer 159R as a hard mask, so that the organic compound layer 103R is formed. In other words, the organic compound layer 103R is formed by processing the organic compound film 103Rf by a lithography method. Note that part of the organic compound film 103Rf may be removed using the resist mask 190R. Then, the resist mask 190R may be removed.

Next, hydrophobization treatment for the conductive layer 152G, for example, is preferably performed. At the time of processing the organic compound film 103Rf, the properties of a surface of the conductive layer 152G change to hydrophilic properties in some cases, for example. The hydrophobization treatment for the conductive layer 152G, for example, can increase the adhesion between the conductive layer 152G and a layer to be formed in a later step (which is the organic compound layer 103G here) and inhibit film peeling. Note that the hydrophobization treatment is not necessarily performed.

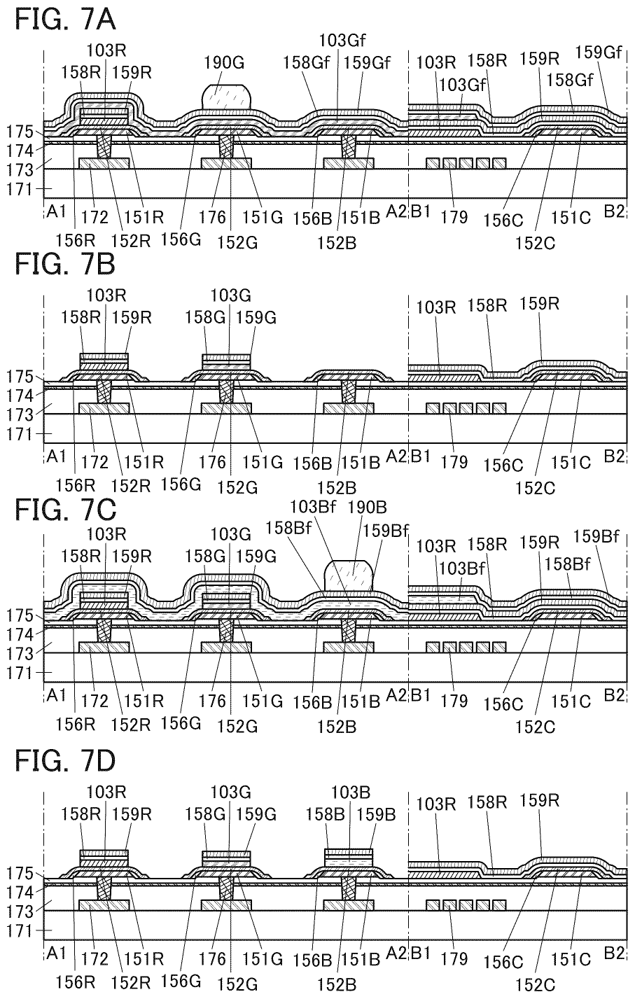

Next, as illustrated in FIG. 7A, an organic compound film 103Gf to be the organic compound layer 103G is formed over the conductive layer 152G, the conductive layer 152B, the mask layer 159R, and the insulating layer 175.

The organic compound film 103Gf can be formed by a method similar to that for forming the organic compound film 103Rf. The organic compound film 103Gf can have a structure similar to that of the organic compound film 103Rf.

Then, as illustrated in FIG. 7A, a sacrificial film 158Gf to be a sacrificial layer 158G and a mask film 159Gf to be a mask layer 159G are sequentially formed over the organic compound film 103Gf and the mask layer 159R. After that, a resist mask 190G is formed. The materials and the formation methods of the sacrificial film 158Gf and the mask film 159Gf are similar to those of the sacrificial film 158Rf and the mask film 159Rf. The material and the formation method of the resist mask 190G are similar to those of the resist mask 190R.

The resist mask 190G is provided at a position overlapping with the conductive layer 152G.

Subsequently, as illustrated in FIG. 7B, part of the mask film 159Gf is removed using the resist mask 190G, so that the mask layer 159G is formed. The mask layer 159G remains over the conductive layer 152G. After that, the resist mask 190G is removed. Then, part of the sacrificial film 158Gf is removed using the mask layer 159G as a mask, so that the sacrificial layer 158G is formed. Next, the organic compound film 103Gf is processed, so that the organic compound layer 103G is formed. For example, part of the organic compound film 103Gf is removed using the mask layer 159G and the sacrificial layer 158G as a hard mask to form the organic compound layer 103G.

Accordingly, as illustrated in FIG. 7B, the stacked-layer structure of the organic compound layer 103G, the sacrificial layer 158G, and the mask layer 159G remains over the conductive layer 152G. The mask layer 159R and the conductive layer 152B are exposed.

Next, hydrophobization treatment for the conductive layer 152B, for example, is preferably performed. At the time of processing the organic compound film 103Gf, the properties of a surface of the conductive layer 152B change to hydrophilic properties in some cases, for example. The hydrophobization treatment for the conductive layer 152B, for example, can increase the adhesion between the conductive layer 152B and a layer to be formed in a later step (which is the organic compound layer 103B here) and inhibit film peeling. Note that the hydrophobization treatment is not necessarily performed.

Next, as illustrated in FIG. 7C, an organic compound film 103Bf to be the organic compound layer 103B is formed over the conductive layer 152B, the mask layer 159R, the mask layer 159G, and the insulating layer 175.

The organic compound film 103Bf can be formed by a method similar to that for forming the organic compound film 103Rf. The organic compound film 103Bf can have a structure similar to that of the organic compound film 103Rf.

Then, as illustrated in FIG. 7C, a sacrificial film 158Bf to be a sacrificial layer 158B and a mask film 159Bf to be a mask layer 159B are sequentially formed over the organic compound film 103Bf and the mask layer 159R. After that, a resist mask 190B is formed. The materials and the formation methods of the sacrificial film 158Bf and the mask film 159Bf are similar to those of the sacrificial film 158Rf and the mask film 159Rf. The material and the formation method of the resist mask 190B are similar to those of the resist mask 190R.

The resist mask 190B is provided at a position overlapping with the conductive layer 152B.

Subsequently, as illustrated in FIG. 7D, part of the mask film 159Bf is removed using the resist mask 190B, so that the mask layer 159B is formed. The mask layer 159B remains over the conductive layer 152B. After that, the resist mask 190B is removed. Then, part of the sacrificial film 158Bf is removed using the mask layer 159B as a mask, so that the sacrificial layer 158B is formed. Next, the organic compound film 103Bf is processed, so that the organic compound layer 103B is formed. For example, part of the organic compound film 103Bf is removed using the mask layer 159B and the sacrificial layer 158B as a hard mask to form the organic compound layer 103B.

Accordingly, as illustrated in FIG. 7D, the stacked-layer structure of the organic compound layer 103B, the sacrificial layer 158B, and the mask layer 159B remains over the conductive layer 152B. The mask layers 159R and 159G are exposed.

Note that the side surfaces of the organic compound layers 103R, 103G, and 103B are preferably perpendicular or substantially perpendicular to their formation surfaces. For example, the angle between the formation surfaces and these side surfaces is preferably greater than or equal to 60° and less than or equal to 90°.

The distance between two adjacent layers among the organic compound layers 103R, 103G, and 103B, which are formed by a lithography method as described above, can be shortened to less than or equal to 8 μm, less than or equal to 5 μm, less than or equal to 3 μm, less than or equal to 2 μm, or less than or equal to 1 μm. Here, the distance can be specified, for example, by the distance between opposite end portions of two adjacent layers among the organic compound layers 103R, 103G, and 103B. Shortening the distance between the island-shaped organic compound layers can provide a display apparatus having high resolution and a high aperture ratio. In addition, the distance between the first electrodes of adjacent light-emitting devices can also be shortened to be, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

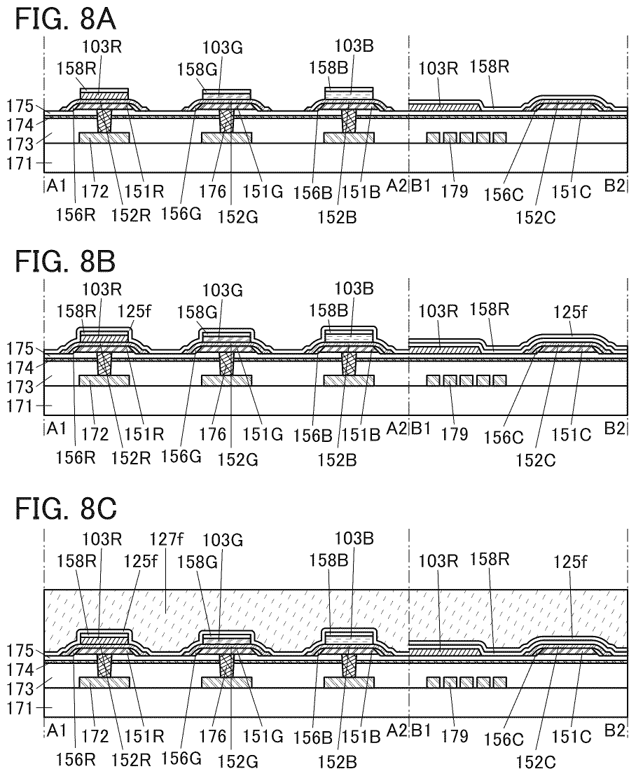

Next, as illustrated in FIG. 8A, the mask layers 159R, 159G, and 159B are preferably removed. The sacrificial layers 158R, 158G, and 158B and the mask layers 159R, 159G, and 159B remain in the display apparatus in some cases depending on the subsequent steps. Removing the mask layers 159R, 159G, and 159B at this stage can inhibit the mask layers 159R, 159G, and 159B from being left in the display apparatus. For example, in the case where a conductive material is used for the mask layers 159R, 159G, and 159B, removing the mask layers 159R, 159G, and 159B in advance can inhibit generation of a leakage current, formation of a capacitor, and the like due to the remaining mask layers 159R, 159G, and 159B.

This embodiment describes an example where the mask layers 159R, 159G, and 159B are removed; however, the mask layers 159R, 159G, and 159B are not necessarily removed. For example, in the case where the mask layers 159R, 159G, and 159B include the above-described material having a property of blocking ultraviolet rays, the procedure preferably proceeds to the next step without removing the mask layers 159R, 159G, and 159B, in which case the organic compound layers can be protected from ultraviolet rays.

The step of removing the mask layers can be performed by a method similar to that for the step of processing the mask films. Specifically, by using a wet etching method, damage applied to the organic compound layers 103R, 103G, and 103B at the time of removing the mask layers can be reduced as compared to the case of using a dry etching method.

The mask layers may be removed by being dissolved in a solvent such as water or an alcohol. Examples of an alcohol include ethyl alcohol, methyl alcohol, isopropyl alcohol (IPA), and glycerin.

After the mask layers are removed, drying treatment may be performed in order to remove water included in the organic compound layers 103R, 103G, and 103B and water adsorbed onto the surfaces of the organic compound layers 103R, 103G, and 103B. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, as illustrated in FIG. 8B, the inorganic insulating film 125f to be the inorganic insulating layer 125 is formed to cover the organic compound layers 103R, 103G, and 103B and the sacrificial layers 158R, 158G, and 158B.

As described later, an insulating film to be the insulating layer 127 is formed in contact with the top surface of the inorganic insulating film 125f. Therefore, the top surface of the inorganic insulating film 125f preferably has a high affinity for the material used for the insulating film (e.g., a photosensitive resin composition containing an acrylic resin). To improve the affinity, surface treatment is preferably performed so that the top surface of the inorganic insulating film 125f is made hydrophobic or its hydrophobic properties are improved. For example, it is preferable to perform the treatment using a silylation agent such as hexamethyldisilazane (HMDS). By making the top surface of the inorganic insulating film 125f hydrophobic in such a manner, an insulating film 127f can be formed with favorable adhesion. Note that the above-described hydrophobization treatment may be performed as the surface treatment.

Then, as illustrated in FIG. 8C, the insulating film 127f to be the insulating layer 127 is formed over the inorganic insulating film 125f.

The inorganic insulating film 125f and the insulating film 127f are preferably formed by a formation method by which the organic compound layers 103R, 103G, and 103B are less damaged. The inorganic insulating film 125f, which is formed in contact with the side surfaces of the organic compound layers 103R, 103G, and 103B, is particularly preferably formed by a formation method that causes less damage to the organic compound layers 103R, 103G, and 103B than the formation method of the insulating film 127f.

Each of the inorganic insulating film 125f and the insulating film 127f is formed at a temperature lower than the upper temperature limits of the organic compound layers 103R, 103G, and 103B. When the inorganic insulating film 125f is formed at a high substrate temperature, the formed inorganic insulating film 125f, even with a small thickness, can have a low impurity concentration and a high barrier property against at least one of water and oxygen.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm is preferably formed in the above-described range of the substrate temperature.

The inorganic insulating film 125f is preferably formed by an ALD method, for example. An ALD method is preferably used, in which case damage due to film formation is reduced and a film with good coverage can be formed. As the inorganic insulating film 125f, an aluminum oxide film is preferably formed by an ALD method, for example.

Alternatively, the inorganic insulating film 125f may be formed by a sputtering method, a CVD method, or a PECVD method, each of which has a higher film formation rate than an ALD method. In that case, a highly reliable display apparatus can be manufactured with high productivity.

The insulating film 127f is preferably formed by the aforementioned wet film-formation method. The insulating film 127f is preferably formed by spin coating using a photosensitive material, for example, and specifically preferably formed using a photosensitive resin composition containing an acrylic resin.

The insulating film 127f is preferably formed using a resin composition containing a polymer, an acid-generating agent, and a solvent, for example. The polymer is formed using one or more kinds of monomers and has a structure where one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

Heat treatment (also referred to as prebaking) is preferably performed after the insulating film 127f is formed. The heat treatment is performed at a temperature lower than the upper temperature limits of the organic compound layers 103R, 103G, and 103B. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, the solvent included in the insulating film 127f can be removed.

Then, part of the insulating film 127f is exposed to visible light or ultraviolet rays. Here, when a positive photosensitive resin composition containing an acrylic resin is used for the insulating film 127f, a region where the insulating layer 127 is not formed in a later step is irradiated with visible light or ultraviolet rays. The insulating layer 127 is formed in regions that are sandwiched between any two of the conductive layers 152R, 152G, and 152B and around the conductive layer 152C. Thus, the top surfaces of the conductive layers 152R, 152G, 152B, and 152C are irradiated with visible light or ultraviolet rays. Note that when a negative photosensitive material is used for the insulating film 127f, the region where the insulating layer 127 is to be formed is irradiated with visible light or ultraviolet rays.

The width of the insulating layer 127 that is to be formed later can be controlled in accordance with the exposed region of the insulating film 127f. In this embodiment, processing is performed such that the insulating layer 127 includes a portion overlapping with the top surface of the conductive layer 151.

The light used for the exposure preferably includes the i-line (wavelength: 365 nm). Furthermore, the light used for the exposure may include at least one of the g-line (wavelength: 436 nm) and the h-line (wavelength: 405 nm).

Here, when a barrier insulating layer against oxygen (e.g., an aluminum oxide film) is provided as one or both of the sacrificial layer 158 (the sacrificial layers 158R, 158G, and 158B) and the inorganic insulating film 125f, diffusion of oxygen into the organic compound layers 103R, 103G, and 103B can be inhibited. When the organic compound layer is irradiated with light (visible light or ultraviolet rays), the organic compound included in the organic compound layer is brought into an excited state and a reaction between the organic compound and oxygen in the atmosphere is promoted in some cases. Specifically, when the organic compound layer is irradiated with light (visible light or ultraviolet rays) in an atmosphere containing oxygen, oxygen might be bonded to the organic compound included in the organic compound layer. By providing the sacrificial layer 158 and the inorganic insulating film 125f over the island-shaped organic compound layer, bonding of oxygen in the atmosphere to the organic compound included in the organic compound layer can be inhibited.

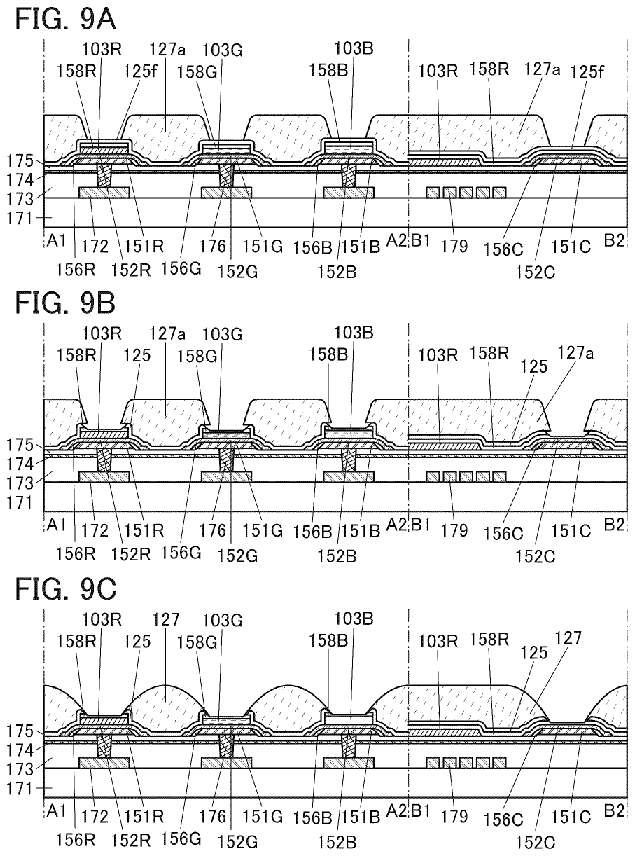

Next, as illustrated in FIG. 9A, development is performed to remove the exposed region of the insulating film 127f, so that an insulating layer 127a is formed. The insulating layer 127a is formed in regions that are sandwiched between any two of the conductive layers 152R, 152G, and 152B and a region surrounding the conductive layer 152C. Here, when an acrylic resin is used for the insulating film 127f, an alkaline solution, such as TMAH, can be used as a developer.

Then, a residue (scum) due to the development may be removed. For example, the residue can be removed by ashing using oxygen plasma.

Etching may be performed to adjust the surface level of the insulating layer 127a. The insulating layer 127a may be processed by ashing using oxygen plasma, for example. In the case where a non-photosensitive material is used for the insulating film 127f, the surface level of the insulating film 127f can be adjusted by the ashing, for example.

Next, as illustrated in FIG. 9B, etching treatment is performed using the insulating layer 127a as a mask to remove part of the inorganic insulating film 125f and reduce the thickness of part of the sacrificial layers 158R, 158G, and 158B. Thus, the inorganic insulating layer 125 is formed under the insulating layer 127a. Moreover, the surfaces of the thin portions in the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layers 158R, 158G, and 158B, in which case the first etching treatment can be performed collectively.

By etching using the insulating layer 127a with a tapered side surface as a mask, the side surface of the inorganic insulating layer 125 and upper end portions of the side surfaces of the sacrificial layers 158R, 158G, and 158B can be made to have a tapered shape relatively easily.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layers 158R, 158G, and 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used. The capacitively coupled plasma etching apparatus including parallel plate electrodes may have a structure where a high-frequency voltage is applied to one of the parallel plate electrodes. Alternatively, the capacitively coupled plasma etching apparatus may have a structure where different high-frequency voltages are applied to one of the parallel-plate electrodes. Alternatively, the capacitively coupled plasma etching apparatus may have a structure where high-frequency voltages with the same frequency are applied to the parallel-plate electrodes. Alternatively, the capacitively coupled plasma etching apparatus may have a structure where high-frequency voltages with different frequencies are applied to the parallel-plate electrodes.

In the case of performing dry etching, a by-product or the like generated by the dry etching might be deposited on the top surface and the side surface of the insulating layer 127a, for example. Accordingly, a component of the etching gas, a component of the inorganic insulating film 125f, a component of the sacrificial layers 158R, 158G, and 158B, and the like might be included in the insulating layer 127 in the completed display apparatus.

The first etching treatment is preferably performed by wet etching. The use of a wet etching method can reduce damage to the organic compound layers 103R, 103G, and 103B, as compared to the case of using a dry etching method. For example, the wet etching can be performed using an alkaline solution. For instance, TMAH, which is an alkaline solution, can be used for the wet etching of an aluminum oxide film. In this case, puddle wet etching can be performed. Note that the inorganic insulating film 125f is preferably formed using a material similar to that of the sacrificial layers 158R, 158G, and 158B, in which case the above etching treatment can be performed collectively.

The sacrificial layers 158R, 158G, and 158B are not removed completely by the first etching treatment, and the etching treatment is stopped when the thicknesses of the sacrificial layers 158R, 158G, and 158B are reduced. The sacrificial layers 158R, 158G, and 158B remain over the corresponding organic compound layers 103R, 103G, and 103B in this manner, whereby the organic compound layers 103R, 103G, and 103B can be prevented from being damaged by treatment in a later step.

Next, the insulating layer 127a is preferably irradiated with visible light or ultraviolet rays by performing light exposure on the entire substrate. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a to a tapered shape.

Here, when a barrier insulating layer against oxygen (e.g., an aluminum oxide film) exists as each of the sacrificial layers 158R, 158G, and 158B, diffusion of oxygen into the organic compound layers 103R, 103G, and 103B can be inhibited. When the organic compound layer is irradiated with light (visible light or ultraviolet rays), the organic compound included in the organic compound layer is brought into an excited state and a reaction between the organic compound and oxygen in the atmosphere is promoted in some cases. Specifically, when the organic compound layer is irradiated with light (visible light or ultraviolet rays) in an atmosphere containing oxygen, oxygen might be bonded to the organic compound included in the organic compound layer. By providing the sacrificial layers 158R, 158G, and 158B over the island-shaped organic compound layers, bonding of oxygen in the atmosphere to the organic compounds included in the organic compound layers can be inhibited.

Then, heat treatment (also referred to as post-baking) is performed. The heat treatment can change the insulating layer 127a into the insulating layer 127 having a tapered side surface (FIG. 9C). The heat treatment is performed at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. The substrate temperature in the heat treatment of this step is preferably higher than that in the heat treatment (prebaking) after the formation of the insulating film 127f. In that case, adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 158R, 158G, and 158B are left, the organic compound layers 103R, 103G, and 103B can be prevented from being damaged and deteriorating in the heat treatment. This increases the reliability of the light-emitting devices.

Note that the side surface of the insulating layer 127 may have a concave shape depending on the material of the insulating layer 127 and the temperature, time, and atmosphere of the post-baking. For example, when the temperature of the post-baking is higher or the duration of the post-baking is longer, the insulating layer 127 is more likely to change in shape and thus a concave shape may be more likely to be formed.

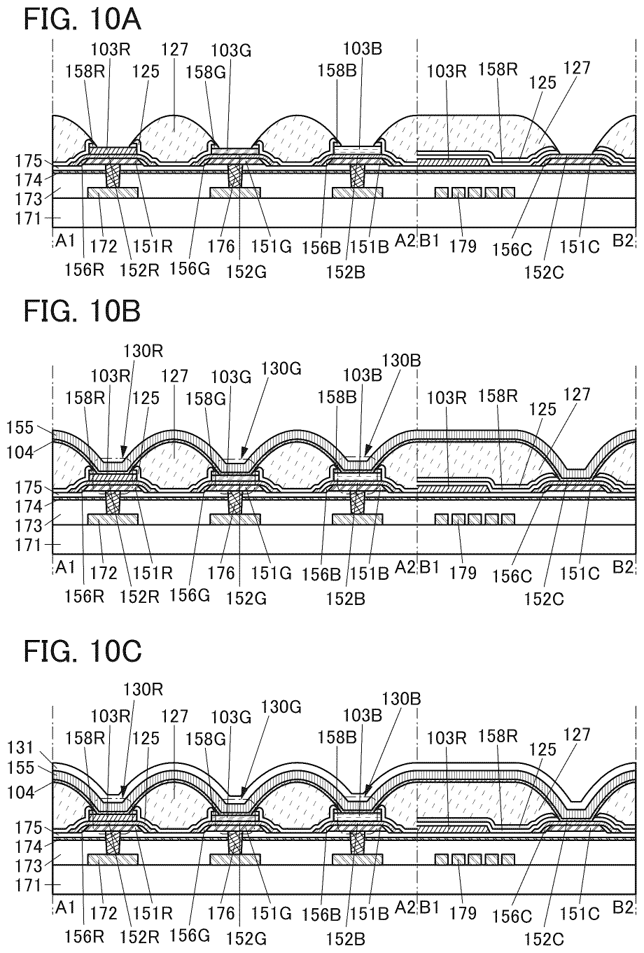

Next, as illustrated in FIG. 10A, etching treatment is performed using the insulating layer 127 as a mask to remove part of the sacrificial layers 158R, 158G, and 158B. Note that part of the inorganic insulating layer 125 is also removed in some cases. Thus, openings are formed in the sacrificial layers 158R, 158G, and 158B, and the top surfaces of the organic compound layers 103R, 103G, and 103B and the conductive layer 152C are exposed. Note that the etching treatment using the insulating layer 127 as a mask may be hereinafter referred to as second etching treatment.

An end portion of the inorganic insulating layer 125 is covered with the insulating layer 127. FIG. 10A illustrates an example where part of an end portion of the sacrificial layer 158G (specifically a tapered portion formed by the first etching treatment) is covered with the insulating layer 127 and a tapered portion formed by the second etching treatment is exposed.

If the first etching treatment is not performed and the inorganic insulating layer 125 and the mask layer are collectively etched after the post-baking, the inorganic insulating layer 125 and the mask layer under an end portion of the insulating layer 127 may disappear because of side etching and a void may be formed. The void causes unevenness on the formation surface of the common electrode 155, so that step disconnection is more likely to be caused in the common electrode 155. Even when a void is formed owing to side etching of the inorganic insulating layer 125 and the mask layer by the first etching treatment, the post-baking performed subsequently can make the insulating layer 127 fill the void. After that, the thinned mask layer is etched by the second etching treatment; thus, the amount of side etching decreases, a void is less likely to be formed, and even if a void is formed, it can be extremely small. Consequently, the formation surface of the common electrode 155 can be made flatter.

Note that the insulating layer 127 may cover the entire end portion of the sacrificial layer 158G. For example, the end portion of the insulating layer 127 may droop to cover the end portion of the sacrificial layer 158G. For another example, the end portion of the insulating layer 127 may be in contact with the top surface of at least one of the organic compound layers 103R, 103G, and 103B. As described above, when light exposure is not performed on the insulating layer 127a after the development, the shape of the insulating layer 127 may be likely to change.

The second etching treatment is performed by wet etching. The use of a wet etching method can reduce damage to the organic compound layers 103R, 103G, and 103B, as compared to the case of using a dry etching method. The wet etching can be performed using an alkaline solution such as TMAH, for example.

Meanwhile, in the case where the second etching treatment is performed by a wet etching method and gaps due to, for example, poor adhesion between the organic compound layer 103 and another layer exist at the interface between the organic compound layer 103 and the sacrificial layer 158, the interface between the organic compound layer 103 and the inorganic insulating layer 125, and the interface between the organic compound layer 103 and the insulating layer 175, the chemical solution used in the second etching treatment sometimes enters the gaps to come into contact with the pixel electrode. Here, when the chemical solution comes into contact with both the conductive layer 151 and the conductive layer 152, one of the conductive layers 151 and 152 that has a lower spontaneous potential than the other suffers from galvanic corrosion in some cases. For example, when the conductive layer 151 is formed using aluminum and the conductive layer 152 is formed using indium tin oxide, the conductive layer 152 sometimes corrodes. As a result, the yield of the display apparatus decreases in some cases. Moreover, the reliability of the display apparatus decreases in some cases.

The conductive layer 152, which covers the top and side surfaces of the conductive layer 151 as described above, can prevent the chemical solution from coming into contact with the conductive layer 151 in the second etching treatment even when gaps exist at the interface between the organic compound layer 103 and the sacrificial layer 158, the interface between the organic compound layer 103 and the inorganic insulating layer 125, and the interface between the organic compound layer 103 and the insulating layer 175. Thus, corrosion of the pixel electrode, e.g., the conductive layer 152, can be prevented.

Furthermore, when the insulating layer 156 is formed to include a region overlapping with the side surface of the conductive layer 151 and the conductive layer 152 is formed to cover the conductive layer 151 and the insulating layer 156, the step disconnection can be prevented, whereby the chemical solution can be prevented from coming into contact with the conductive layer 151 in the second etching treatment, for example. Thus, corrosion of the pixel electrode, e.g., the conductive layer 152, can be prevented.

As described above, by providing the insulating layer 127, the inorganic insulating layer 125, and the sacrificial layers 158R, 158G, and 158B, poor connection due to a disconnected portion and an increase in electrical resistance due to a locally thinned portion can be inhibited from occurring in the common electrode 155 between the light-emitting devices. Thus, the display apparatus of one embodiment of the present invention can have improved display quality.

Heat treatment is performed after the organic compound layers 103R, 103G, and 103B are partly exposed. By the heat treatment, water included in the organic compound layers and water adsorbed onto the surfaces of the organic compound layers, for example, can be removed. The shape of the insulating layer 127 may be changed by the heat treatment. Specifically, the insulating layer 127 may be widened to cover at least one of the end portion of the inorganic insulating layer 125, the end portions of the sacrificial layers 158R, 158G, and 158B, and the top surfaces of the organic compound layers 103R, 103G, and 103B.

If the temperature of the heat treatment is too low, water included in the organic compound layers and water adsorbed onto the surfaces of the organic compound layers, for example, cannot be sufficiently removed. If the temperature of the heat treatment is too high, the organic compound layer 103 might deteriorate and the insulating layer 127 might change in shape excessively. Therefore, the temperature of the heat treatment is preferably higher than the temperature at which water is released from the organic compound layer 103 and lower than the glass transition temperature of the organic compound included in the organic compound layer 103, further preferably lower than the glass transition temperature of the organic compound included in the upper surface of the organic compound layer 103. Specifically, the substrate temperature is preferably higher than or equal to 80° C. and lower than or equal to 130° C., further preferably higher than or equal to 90° C. and lower than or equal to 120° C., still further preferably higher than or equal to 100° C. and lower than or equal to 120° C., yet still further preferably higher than or equal to 100° C. and lower than or equal to 110° C. The heating atmosphere may be an air atmosphere or an inert gas atmosphere. Although the heating atmosphere may be an atmospheric-pressure atmosphere or a reduced-pressure atmosphere, a reduced-pressure atmosphere is preferably employed to prevent re-adsorption of water released from the organic compound layer 103.

By the heat treatment, water included in the organic compound layers and water adsorbed onto the surfaces of the organic compound layers, for example, can be sufficiently removed without deterioration of the organic compound layers 103R, 103G, and 103B and an excessive change in the shape of the insulating layer 127. Thus, degradation of the characteristics of the light-emitting device can be prevented.

Next, as illustrated in FIG. 10B, the common layer 104 and the common electrode 155 are formed over the organic compound layers 103R, 103G, and 103B, the conductive layer 152C, and the insulating layer 127. The common layer 104 and common electrode 155 can be formed by a sputtering method, a vacuum evaporation method, or the like. The common layer 104 may be formed by an evaporation method while the common electrode 155 may be formed by a sputtering method.

Next, as illustrated in FIG. 10C, the protective layer 131 is formed over the common electrode 155. The protective layer 131 can be formed by a vacuum evaporation method, a sputtering method, a CVD method, an ALD method, or the like.

Then, the substrate 120 is attached to the protective layer 131 using the resin layer 122, so that the display apparatus can be manufactured. In the method for manufacturing the display apparatus of one embodiment of the present invention, the insulating layer 156 is formed to include a region overlapping with the side surface of the conductive layer 151 and the conductive layer 152 is formed to cover the conductive layer 151 and the insulating layer 156 as described above. This can increase the yield of the display apparatus and inhibit generation of defects.

As described above, in the method for manufacturing the display apparatus of one embodiment of the present invention, the island-shaped organic compound layers 103R, 103G, and 103B are each formed not by using a fine metal mask but by processing a film formed on the entire surface; thus, the island-shaped layers can be formed to have a uniform thickness. Consequently, a high-resolution display apparatus or a display apparatus with a high aperture ratio can be obtained. Furthermore, even when the resolution or the aperture ratio is high and the distance between the subpixels is extremely short, the organic compound layers 103R, 103G, and 103B can be inhibited from being in contact with each other in the adjacent subpixels. As a result, generation of a leakage current between the subpixels can be inhibited. This can prevent crosstalk, so that a display apparatus with extremely high contrast can be obtained. Moreover, even a display apparatus that includes tandem light-emitting devices formed by a lithography method can have favorable characteristics.

The structure described in this embodiment can be used in combination with any of the structures described in other embodiments as appropriate.

### Embodiment 4

In this embodiment, a display apparatus of one embodiment of the present invention will be described.

The display apparatus in this embodiment can be a high-resolution display apparatus. Thus, the display apparatus in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display apparatus in this embodiment can be a high-definition display apparatus or a large-sized display apparatus. Accordingly, the display apparatus in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

### [Display Module]

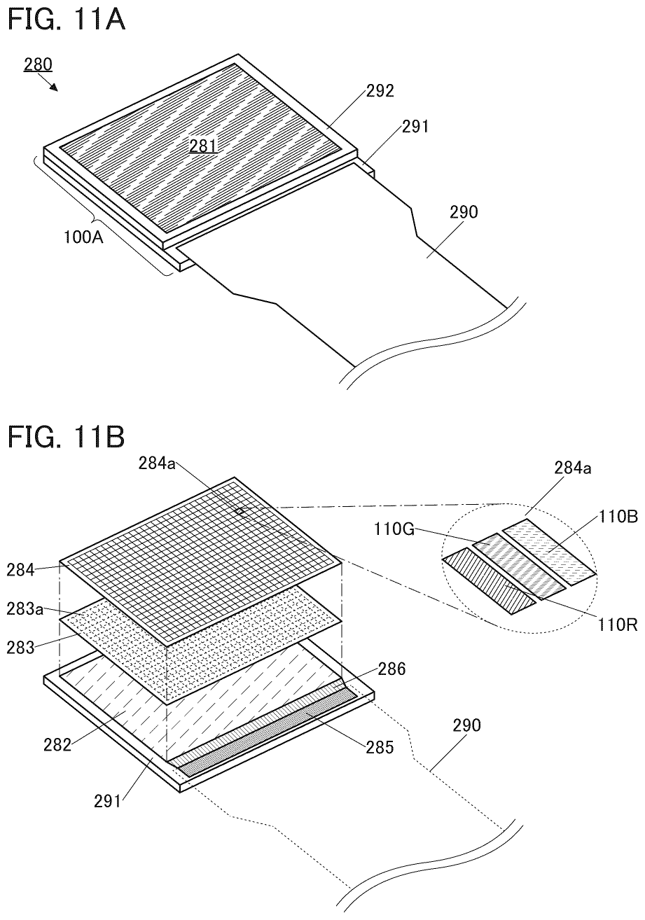

FIG. 11A is a perspective view of a display module 280. The display module 280 includes a display apparatus 100A and an FPC 290.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 11B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 11B. The pixels 284a can employ any of the structures described in the above embodiments. FIG. 11B illustrates an example where the pixel 284a has a structure similar to that of the pixel 178 illustrated in FIGS. 3A and 3B.

The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each of which controls light emission of one light-emitting device. For example, the pixel circuit 283a can include at least one selection transistor, one current control transistor (driving transistor), and a capacitor for one light-emitting device. A gate signal is input to a gate of the selection transistor, and a video signal is input to a source or a drain of the selection transistor. With such a structure, an active-matrix display apparatus is obtained.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have significantly high resolution. For example, the pixels 284a are preferably arranged in the display portion 281 with a resolution higher than or equal to 2000 ppi, further preferably higher than or equal to 3000 ppi, still further preferably higher than or equal to 5000 ppi, yet still further preferably higher than or equal to 6000 ppi, and lower than or equal to 20000 ppi or lower than or equal to 30000 ppi.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion. For example, the display module 280 can be favorably used in a display portion of a wearable electronic appliance, such as a wrist watch.

### [Display Apparatus 100A]

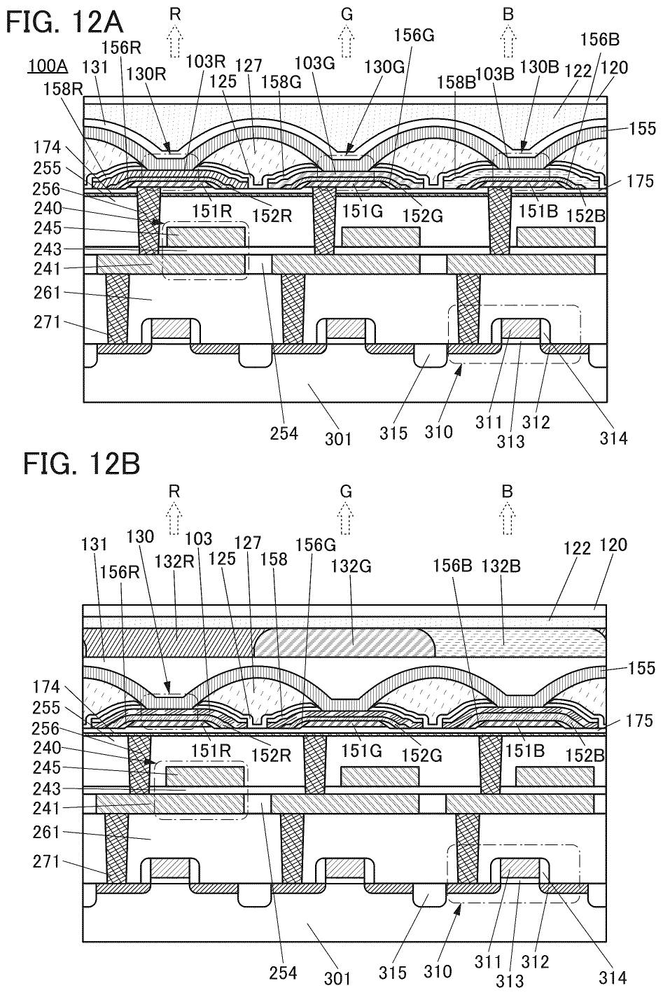

The display apparatus 100A illustrated in FIG. 12A includes a substrate 301, the light-emitting devices 130R, 130G, and 130B, a capacitor 240, and a transistor 310.

The substrate 301 corresponds to the substrate 291 in FIGS. 11A and 11B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is located between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 sandwiched therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. FIG. 12A illustrates an example in which the light-emitting devices 130R, 130G, and 130B each have the stacked-layer structure illustrated in FIG. 2B. An insulator is provided in regions between adjacent light-emitting devices. For example, in FIG. 12A, the inorganic insulating layer 125 and the insulating layer 127 over the inorganic insulating layer 125 are provided in those regions.

The insulating layer 156R is provided to include a region overlapping with the side surface of the conductive layer 151R of the light-emitting device 130R. The insulating layer 156G is provided to include a region overlapping with the side surface of the conductive layer 151G of the light-emitting device 130G. The insulating layer 156B is provided to include a region overlapping with the side surface of the conductive layer 151B of the light-emitting device 130B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is located over the organic compound layer 103R of the light-emitting device 130R. The sacrificial layer 158G is located over the organic compound layer 103G of the light-emitting device 130G. The sacrificial layer 158B is located over the organic compound layer 103B of the light-emitting device 130B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. The top surface of the insulating layer 175 and the top surface of the plug 256 are level with or substantially level with each other. Any of a variety of conductive materials can be used for the plugs.

The protective layer 131 is provided over the light-emitting devices 130R, 130G, and 130B. A substrate 120 is attached to the protective layer 131 with the resin layer 122. Embodiment 3 can be referred to for the details of the light-emitting device 130 and the components thereover up to the substrate 120. The substrate 120 corresponds to the substrate 292 in FIG. 11A.

FIG. 12B illustrates a variation example of the display apparatus 100A illustrated in FIG. 12A. The display apparatus illustrated in FIG. 12B includes the coloring layers 132R, 132G, and 132B, and each of the light-emitting devices 130 includes a region overlapping with one of the coloring layers 132R, 132G, and 132B. In the display apparatus illustrated in FIG. 12B, the light-emitting device 130 can emit white light, for example. For example, the coloring layer 132R, the coloring layer 132G, and the coloring layer 132B can transmit red light, green light, and blue light, respectively.

This embodiment can be combined as appropriate with any of the other embodiments and examples. In this specification, in the case where a plurality of structure examples are shown in one embodiment, the structure examples can be combined as appropriate.

### Embodiment 5

In this embodiment, electronic appliances of embodiments of the present invention will be described.

Electronic appliances of this embodiment include the display apparatus of one embodiment of the present invention in their display portions. The display apparatus of one embodiment of the present invention is highly reliable and can be easily increased in resolution and definition. Thus, the display apparatus of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the display apparatus of one embodiment of the present invention can have high resolution, and thus can be favorably used for an electronic appliance having a relatively small display portion. Examples of such an electronic appliance include watch-type and bracelet-type information terminal devices (wearable devices) and wearable devices capable of being worn on a head, such as a VR device like a head-mounted display, a glasses-type AR device, and an MR device.

The definition of the display apparatus of one embodiment of the present invention is preferably as high as HD (number of pixels: 1280′720), FHD (number of pixels: 1920′1080), WQHD (number of pixels: 2560′1440), WQXGA (number of pixels: 2560′1600), 4K (number of pixels: 3840′2160), or 8K (number of pixels: 7680′4320). In particular, definition of 4K, 8K, or higher is preferable. The pixel density (resolution) of the display apparatus of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, yet still further preferably higher than or equal to 3000 ppi, yet still further preferably higher than or equal to 5000 ppi, yet still further preferably higher than or equal to 7000 ppi. With such a display apparatus having one or both of high definition and high resolution, the electronic appliance can provide higher realistic sensation, sense of depth, and the like in personal use such as portable use or home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic appliance in this embodiment can have a variety of functions. For example, the electronic appliance in this embodiment can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

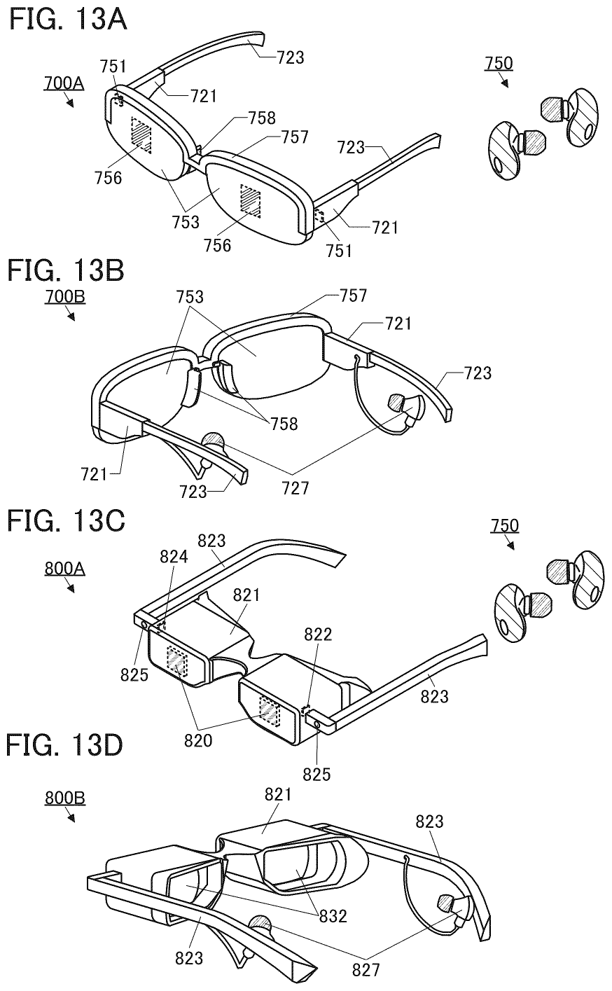

Examples of head-mounted wearable devices are described with reference to FIGS. 13A to 13D. These wearable devices have at least one of a function of displaying AR contents, a function of displaying VR contents, a function of displaying SR contents, and a function of displaying MR contents. The electronic appliance having a function of displaying contents of at least one of AR, VR, SR, MR, and the like enables the user to feel a higher level of immersion.

An electronic appliance 700A illustrated in FIG. 13A and an electronic appliance 700B illustrated in FIG. 13B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic appliances can be highly reliable.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliances 700A and 700B are electronic appliances capable of performing AR display.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a moving image can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving element. One or both of an inorganic semiconductor and an organic semiconductor can be used for an active layer of the photoelectric conversion device.

An electronic appliance 800A illustrated in FIG. 13C and an electronic appliance 800B illustrated in FIG. 13D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, the electronic appliances can be highly reliable.

The display portions 820 are located inside the housing 821 so as to be seen through the lenses 832. When the pair of display portions 820 display different images, three-dimensional display using parallax can be performed.

The electronic appliances 800A and 800B can be regarded as electronic appliances for VR. The user who wears the electronic appliance 800A or 800B can see images displayed on the display portions 820 through the lenses 832.

The electronic appliances 800A and 800B preferably include a mechanism for adjusting the lateral positions of the lenses 832 and the display portions 820 so that the lenses 832 and the display portions 820 are located optimally in accordance with the positions of the user's eyes. Moreover, the electronic appliances 800A and 800B preferably include a mechanism for adjusting focus by changing the distance between the lenses 832 and the display portions 820.

The electronic appliance 800A or 800B can be mounted on the user's head with the wearing portions 823. FIG. 13C, for instance, shows an example where the wearing portion 823 has a shape like a temple (also referred to as a joint or the like) of glasses; however, one embodiment of the present invention is not limited thereto. The wearing portion 823 may have any shape with which the user can wear the electronic appliance, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is described here, a range sensor (hereinafter also referred to as a sensing portion) capable of measuring the distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic appliance 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic appliance 800A.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750. The earphones 750 include a communication portion (not illustrated) and have a wireless communication function. The earphones 750 can receive information (e.g., audio data) from the electronic appliance with the wireless communication function. For example, the electronic appliance 700A in FIG. 13A has a function of transmitting information to the earphones 750 with the wireless communication function. For another example, the electronic appliance 800A in FIG. 13C has a function of transmitting information to the earphones 750 with the wireless communication function.

The electronic appliance may include an earphone portion. The electronic appliance 700B in FIG. 13B includes earphone portions 727. For example, the earphone portion 727 can be connected to the control portion by wire. Part of a wiring that connects the earphone portion 727 and the control portion may be located inside the housing 721 or the wearing portion 723.

Similarly, the electronic appliance 800B in FIG. 13D includes earphone portions 827. For example, the earphone portion 827 can be connected to the control portion 824 by wire. Part of a wiring that connects the earphone portion 827 and the control portion 824 may be located inside the housing 821 or the wearing portion 823. Alternatively, the earphone portions 827 and the wearing portions 823 may include magnets. This structure is preferably employed, in which case the earphone portions 827 can be fixed to the wearing portions 823 with magnetic force and thus can be easily housed.

The electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of a headset by including the audio input mechanism.

As described above, both the glasses-type device (e.g., the electronic appliances 700A and 700B) and the goggles-type device (e.g., the electronic appliances 800A and 800B) are preferable as the electronic appliance of one embodiment of the present invention.

The electronic appliance of one embodiment of the present invention can transmit information to earphones by wire or wirelessly.

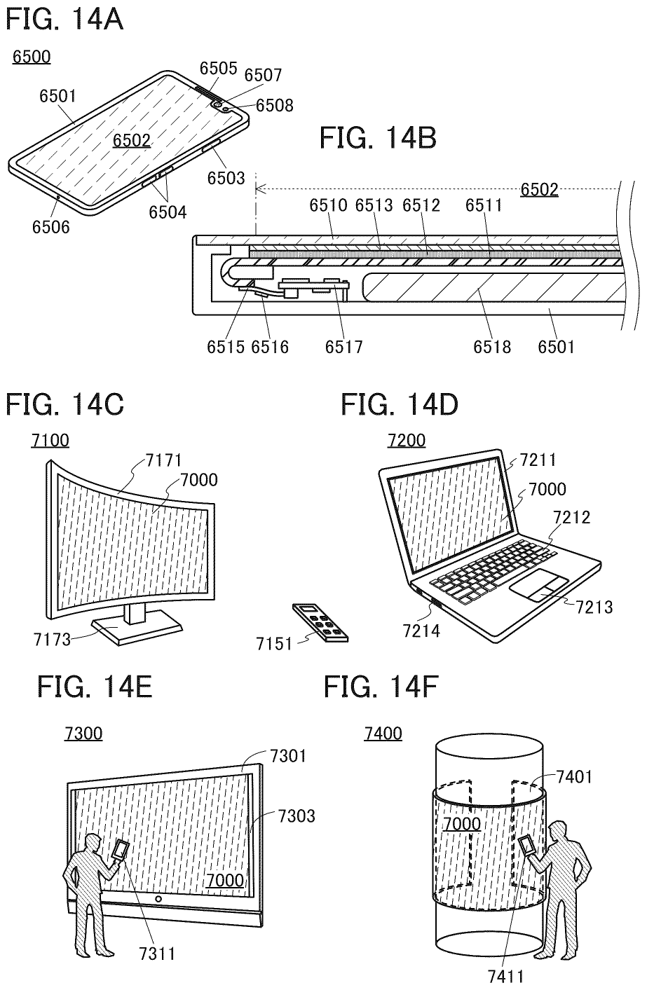

An electronic appliance 6500 illustrated in FIG. 14A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502. Thus, the electronic appliance can be highly reliable.

FIG. 14B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used in the display panel 6511. Thus, the electronic appliance can be extremely lightweight. Since the display panel 6511 is extremely thin, the battery 6518 with high capacity can be mounted without an increase in the thickness of the electronic appliance. The electronic appliance can have a narrow bezel when part of the display panel 6511 is folded back so that the portion connected to the FPC 6515 is provided on the back side of a pixel portion.

FIG. 14C illustrates an example of a television device. In a television device 7100, a display portion 7000 is incorporated in a housing 7171. Here, the housing 7171 is supported by a stand 7173.

The display apparatus of one embodiment of the present invention can be used in the display portion 7000. Thus, a highly reliable electronic appliance can be obtained.

Operation of the television device 7100 illustrated in FIG. 14C can be performed with an operation switch provided in the housing 7171 and a separate remote control 7151. Alternatively, the display portion 7000 may include a touch sensor, and the television device 7100 may be operated by touch on the display portion 7000 with a finger or the like. The remote control 7151 may be provided with a display portion for displaying information output from the remote control 7151. With operation keys or a touch panel of the remote control 7151, channels and volume can be controlled and video displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 14D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used in the display portion 7000. Thus, a highly reliable electronic appliance can be obtained.

FIGS. 14E and 14F illustrate examples of digital signage.

Digital signage 7300 illustrated in FIG. 14E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 14F shows digital signage 7400 attached to a cylindrical pillar 7401. The digital signage 7400 includes the display portion 7000 provided along a curved surface of the pillar 7401.

In FIGS. 14E and 14F, the display apparatus of one embodiment of the present invention can be used in the display portion 7000. Thus, a highly reliable electronic appliance can be obtained.

A larger area of the display portion 7000 can increase the amount of information that can be provided at a time. The display portion 7000 having a larger area attracts more attention, so that the effectiveness of the advertisement can be increased, for example.

The touch panel is preferably used in the display portion 7000, in which case in addition to display of still or moving images on the display portion 7000, intuitive operation by a user is possible. Moreover, in the case of an application for providing information such as route information or traffic information, usability can be enhanced by intuitive operation.

As illustrated in FIGS. 14E and 14F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, a displayed image on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

This embodiment can be combined as appropriate with any of the other embodiments and examples. In this specification, in the case where a plurality of structure examples are shown in one embodiment, the structure examples can be combined as appropriate.

### Example 1

In this example, light-emitting devices 1 to 3 that are embodiments of the present invention and reference light-emitting devices 4 to 6 are described. The light-emitting devices 1 to 3 were fabricated by a process in which an organic compound layer is formed through processing by a photolithography method. The reference light-emitting devices 4 to 6 were fabricated by a fabrication method (what is called a continuous vacuum process) that does not include a process of forming an organic compound layer through processing by a photolithography method. The structural formulae of the organic compounds used in the light-emitting devices 1 to 3 and the reference light-emitting devices 4 to 6 are shown below.

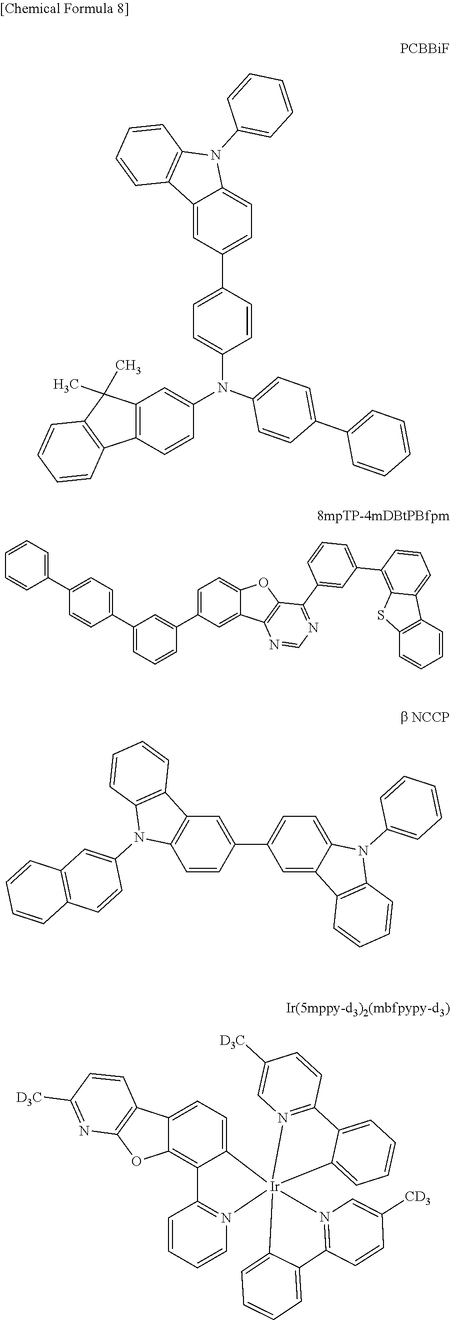

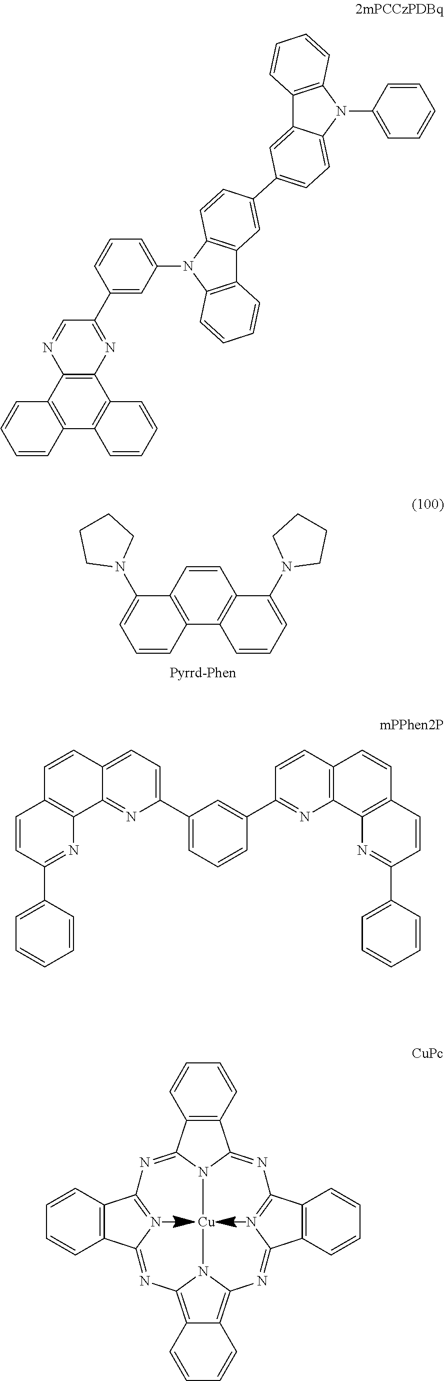

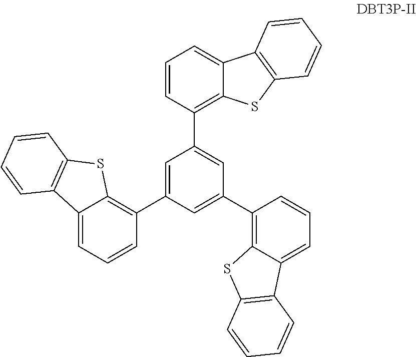 [SMILES: c1ccc2c(c1)sc1c(-c3cc(-c4cccc5c4sc4ccccc45)cc(-c4cccc5c4sc4ccccc45)c3)cccc12]

### (Method for Fabricating Light-Emitting Device 1)

First, as a reflective electrode, an alloy containing silver (Ag), palladium (Pd), and copper (Cu) (abbreviation: APC) was deposited over a glass substrate to a thickness of 100 nm by a sputtering method, and then, as a transparent electrode, indium tin oxide containing silicon oxide (ITSO) was deposited to a thickness of 50 nm by a sputtering method, so that a first electrode was formed. The electrode area was set to 4 mm² (2 mm 2 mm). Note that the transparent electrode functions as an anode, and the transparent electrode and the reflective electrode can be collectively regarded as the first electrode.

Next, in pretreatment for forming the light-emitting device over the substrate, the surface of the substrate was washed with water, and baking was performed at 200° C. for 1 hour.

After that, the substrate was transferred into a vacuum evaporation apparatus where the pressure had been reduced to approximately 1′10⁻⁴ Pa, and was subjected to heat treatment at 170° C. for 30 minutes in a heating chamber of the vacuum evaporation apparatus, and then the substrate was cooled down for approximately 30 minutes.

Then, the substrate was fixed to a substrate holder provided in the vacuum evaporation apparatus such that the surface on which the first electrode was formed faced downward. Over the first electrode, N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material with a molecular weight of 672 and four or more fluorine atoms (OCHD-003) were deposited by co-evaporation to a thickness of 10 nm such that the weight ratio of PCBBiF to OCHD-003 was 1:0.03, so that a hole-injection layer was formed.

Over the hole-injection layer, PCBBiF was deposited by evaporation to a thickness of 135 nm, so that a first hole-transport layer was formed.

Then, over the first hole-transport layer, 8-(1,1′: 4′,1″-terphenyl-3-yl)-4-[3-(dibenzothiophen-4-yl)phenyl]-[1]benzofuro[3,2-d]pyrimidine (abbreviation: 8mpTP-4mDBtPBfpm), 9-(2-naphthyl)-9′-phenyl-9H,9′H-3,3′-bicarbazole (abbreviation: βNCCP), and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)) were deposited by co-evaporation to a thickness of 40 nm such that the weight ratio of 8mpTP-4mDBtPBfpm to βNCCP to Ir(5mppy-d₃)₂(mbfpypy-d₃) was 0.5:0.5:0.1, whereby a first light-emitting layer was formed.

After that, 2-{3-[3-(N-phenyl-9H-carbazol-3-yl)-9H-carbazol-9-yl]phenyl}dibenzo[f,h]quinoxaline (abbreviation: 2mPCCzPDBq) was deposited by evaporation to a thickness of 10 nm, so that a first electron-transport layer was formed.

After the formation of the first electron-transport layer, 2,2′-(1,3-phenylene)bis(9-phenyl-1,10-phenanthroline) (abbreviation: mPPhen2P), 4,7-di-1-pyrrolidinyl-1,10-phenanthroline (abbreviation: Pyrrd-Phen) (Structural Formula (100)), which is an organic compound having a phenanthroline ring with an electron-donating group, and indium (In) were deposited by co-evaporation to a thickness of 5 nm such that the volume ratio of mPPhen2P to Pyrrd-Phen to In was 0.5:0.5:0.02, whereby a first layer of an intermediate layer was formed.

Then, a film of copper phthalocyanine (abbreviation: CuPc) was formed to have a thickness of 2 nm, so that a third layer of the intermediate layer was formed.

Furthermore, PCBBiF and OCHD-003 were deposited by co-evaporation to a thickness of 10 nm such that the weight ratio of PCBBiF to OCHD-003 was 1:0.15, whereby a second layer of the intermediate layer was formed.

Next, over the intermediate layer, PCBBiF was deposited by evaporation to a thickness of 55 nm, so that a second hole-transport layer was formed.

Over the second hole-transport layer, 8mpTP-4mDBtPBfpm, βNCCP, and Ir(5mppy-d₃)₂(mbfpypy-d₃) were deposited by co-evaporation to a thickness of 40 nm such that the weight ratio of 8mpTP-4mDBtPBfpm to βNCCP to Ir(5mppy-d₃)₂(mbfpypy-d₃) was 0.5:0.5:0.1, whereby a second light-emitting layer was formed.

After that, 2mPCCzPDBq was deposited by evaporation to a thickness of 20 nm and mPPhen2P was further deposited by evaporation to a thickness of 20 nm, so that a second electron-transport layer was formed.

After the formation of the second electron-transport layer, processing by a photolithography method and heat treatment were performed.

### <<Processing by Photolithography Method and Heat Treatment 1>>

Here, the processing by a photolithography method and the heat treatment are described. First, the substrate was taken out from the vacuum evaporation apparatus and exposed to the air, and then aluminum oxide was deposited to a thickness of 30 nm by an ALD method using trimethylaluminum (abbreviation: TMA) as a precursor and water vapor as an oxidizer to form a first sacrificial layer.

Next, over the first sacrificial layer, molybdenum was deposited to a thickness of 50 nm by a sputtering method to form a second sacrificial layer.

A resist was formed using a photoresist over the second sacrificial layer, and processing was performed by a photolithography method to form a slit having a width of 3 μm in a position 3.5 μm away from an end portion of the first electrode.

Specifically, the second sacrificial layer was processed using a chemical solution containing an aqueous solution of phosphoric acid with the use of the resist as a mask and then, the first sacrificial layer was processed using an etching gas containing fluoroform (CHF₃) and helium (He) at a flow rate ratio of CHF₃:He=1:9 with the use of the second sacrificial layer as a hard mask. Then, the second electron-transport layer, the second light-emitting layer, the second hole-transport layer, the intermediate layer, the first electron-transport layer, the first light-emitting layer, the first hole-transport layer, and the hole-injection layer were processed using an etching gas containing oxygen (O₂).

After the processing by a photolithography method, the first and second sacrificial layers were removed using a basic chemical solution containing water as a solvent, so that the top surface of the second electron-transport layer was exposed. Then, the substrate was transferred into a vacuum evaporation apparatus where the pressure had been reduced to approximately 1′10⁻⁴ Pa, and heat treatment was performed at 110° C. for 1 hour in a heating chamber of the vacuum evaporation apparatus.

The above is the description of the processing by a photolithography method and the heat treatment. As described above, in the processing by a photolithography method and the heat treatment, treatment using water or a chemical solution containing water as a solvent is performed.

After the processing by a photolithography method and the heat treatment, over the exposed second electron-transport layer, lithium fluoride (LiF) and ytterbium (Yb) were deposited by co-evaporation to a thickness of 1.5 nm such that the volume ratio of LiF to Yb was 1:0.5 to form an electron-injection layer, and lastly silver (Ag) and magnesium (Mg) were deposited by co-evaporation to a thickness of 15 nm such that the volume ratio of Ag to Mg was 1:0.1 to form a second electrode, whereby the light-emitting device 1 was fabricated.

The second electrode is a semi-transmissive and semi-reflective electrode having a function of reflecting light and a function of transmitting light; thus, the light-emitting device of this example is a top-emission tandem device in which light is extracted through the second electrode. Over the second electrode, 4,4′,4″-(benzene-1,3,5-triyl)tri(dibenzothiophene) (abbreviation: DBT3P-II) was deposited by evaporation to a thickness of 70 nm as a cap layer to improve light extraction efficiency.

### (Method for Fabricating Light-Emitting Device 2)

The light-emitting device 2 is different from the light-emitting device 1 in that not In but silver (Ag) was used in the first layer of the intermediate layer. The other components were formed in the same manner as those in the light-emitting device 1.

### (Method for Fabricating Light-Emitting Device 3)

The light-emitting device 3 is different from the light-emitting device 1 in that not In but ytterbium (Yb) was used in the first layer of the intermediate layer. The other components were formed in the same manner as those in the light-emitting device 1.

### (Method for Fabricating Reference Light-Emitting Device 4)

The reference light-emitting device 4 was fabricated through what is called a continuous vacuum process, which does not include a process of forming an organic compound layer through processing by a photolithography method, unlike the light-emitting device 1. That is, the method for fabricating the reference light-emitting device 4 is different from the method for fabricating the light-emitting device 1 in that, after the formation of the second electron-transport layer, the electron-injection layer was successively formed without performing processing by a photolithography method or heat treatment; the other components were formed in the same manner as those in the light-emitting device 1.

### (Method for Fabricating Reference Light-Emitting Device 5)

The reference light-emitting device 5 was fabricated through what is called a continuous vacuum process, which does not include a process of forming an organic compound layer through processing by a photolithography method, unlike the light-emitting device 2. That is, the method for fabricating the reference light-emitting device 5 is different from the method for fabricating the light-emitting device 2 in that, after the formation of the second electron-transport layer, the electron-injection layer was successively formed without performing processing by a photolithography method or heat treatment; the other components were formed in the same manner as those in the light-emitting device 2.

### (Method for Fabricating Reference Light-Emitting Device 6)

The reference light-emitting device 6 was fabricated through what is called a continuous vacuum process, which does not include a process of forming an organic compound layer through processing by a photolithography method, unlike the light-emitting device 3. That is, the method for fabricating the reference light-emitting device 6 is different from the method for fabricating the light-emitting device 3 in that, after the formation of the second electron-transport layer, the electron-injection layer was successively formed without performing processing by a photolithography method or heat treatment; the other components were formed in the same manner as those in the light-emitting device 3.

The tables below list the structures of the light-emitting devices 1 to 3 and the reference light-emitting devices 4 to 6.

TABLE 5

| | | | Light- | Light- | Light- |
|---|---|---|---|---|---|
| | | | emitting | emitting | emitting |
| | | Thickness | device 1 | device 2 | device 3 |
| Cap layer | | 70 nm | DBT3P-II | | |
| Second electrode | | 15 nm | Ag:Mg (1:0.1) | | |
| Electron-injection layer | | 1.5 nm | LiF:Yb (1:0.5) | | |
| — | | | Processing was performed by | | |
| | | | photolithography method. | | |
| Second electron- | 2 | 20 nm | mPPhen2P | | |
| transport layer | 1 | 20 nm | 2mPCCzPDBq | | |
| Second light-emitting layer | | 40 nm | 8mpTP-4mDBtPBfpm:βNCCP: | | |
| | | | Ir(5mppy-d₃)₂(mbfpypy-d₃) | | |
| | | | (0.5:0.5:0.1) | | |
| Second hole-transport layer | | 55 nm | PCBBiF | | |
| Intermediate | Second layer | 10 nm | PCBBiF:OCHD-003 (1:0.15) | | |
| layer | Third layer | 2 nm | CuPc | | |
| | First layer | 5 nm | mPPhen2P: | mPPhen2P: | mPPhen2P: |
| | | | Pyrrd-Phen:In | Pyrrd-Phen:Ag | Pyrrd-Phen:Yb |
| | | | (0.5:0.5:0.02) | (0.5:0.5:0.02) | (0.5:0.5:0.02) |

| First electron-transport layer | | 10 nm | 2mPCCzPDBq |
|---|---|---|---|
| First light-emitting layer | | 40 nm | 8mpTP-4mDBtPBfpm:βNCCP: |
| | | | Ir(5mppy-d₃)₂(mbfpypy-d₃) |
| | | | (0.5:0.5:0.1) |
| First hole-transport layer | | 135 nm | PCBBiF |
| Hole-injection layer | | 10 nm | PCBBiF:OCHD-003 (1:0.03) |
| First electrode | 2 | 50 nm | ITSO |
| | 1 | 100 nm | APC |

TABLE 6

| | | | Reference | Reference | Reference |
|---|---|---|---|---|---|
| | | | light-emitting | light-emitting | light-emitting |
| | | Thickness | device 4 | device 5 | device 6 |
| Cap layer | | 70 nm | DBT3P-II | | |
| Second electrode | | 15 nm | Ag:Mg (1:0.1) | | |
| Electron-injection layer | | 1.5 nm | LiF:Yb (1:0.5) | | |
| Second electron- | 2 | 20 nm | mPPhen2P | | |
| transport layer | 1 | 20 nm | 2mPCCzPDBq | | |
| Second light-emitting layer | | 40 nm | 8mpTP-4mDBtPBfpm:βNCCP: | | |
| | | | Ir(5mppy-d₃)₂(mbfpypy-d₃) | | |
| | | | (0.5:0.5:0.1) | | |
| Second hole-transport layer | | 55 nm | PCBBiF | | |
| Intermediate | Second layer | 10 nm | PCBBiF:OCHD-003 (1:0.15) | | |
| layer | Third layer | 2 nm | CuPc | | |
| | First layer | 5 nm | mPPhen2P: | mPPhen2P: | mPPhen2P: |
| | | | Pyrrd-Phen:In | Pyrrd-Phen:Ag | Pyrrd-Phen:Yb |
| | | | (0.5:0.5:0.02) | (0.5:0.5:0.02) | (0.5:0.5:0.02) |

| First electron-transport layer | | 10 nm | 2mPCCzPDBq |
|---|---|---|---|
| First light-emitting layer | | 40 nm | 8mpTP-4mDBtPBfpm:βNCCP: |
| | | | Ir(5mppy-d₃)₂(mbfpypy-d₃) |
| | | | (0.5:0.5:0.1) |
| First hole-transport layer | | 135 nm | PCBBiF |
| Hole-injection layer | | 10 nm | PCBBiF:OCHD-003 (1:0.03) |
| First electrode | 2 | 50 nm | ITSO |
| | 1 | 100 nm | APC |

The light-emitting devices fabricated were each sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for 1 hour. Then, the initial characteristics of the light-emitting devices were measured.

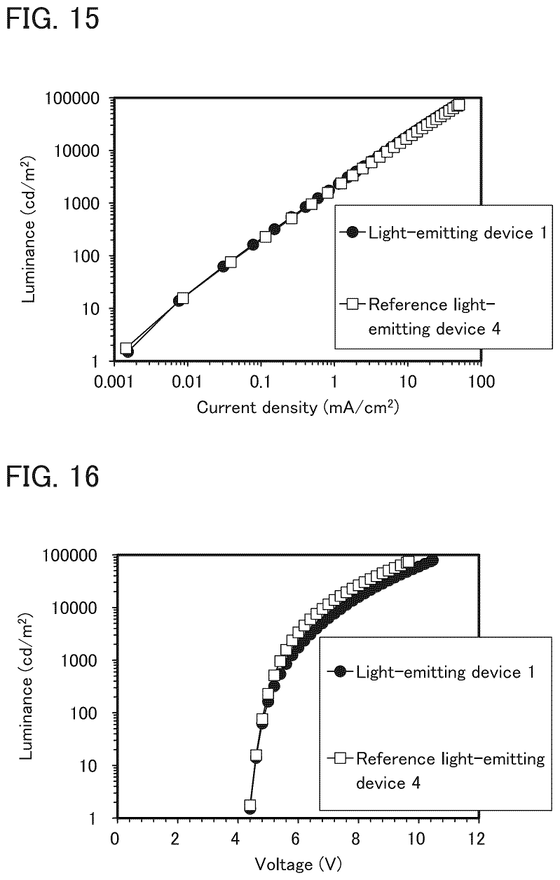

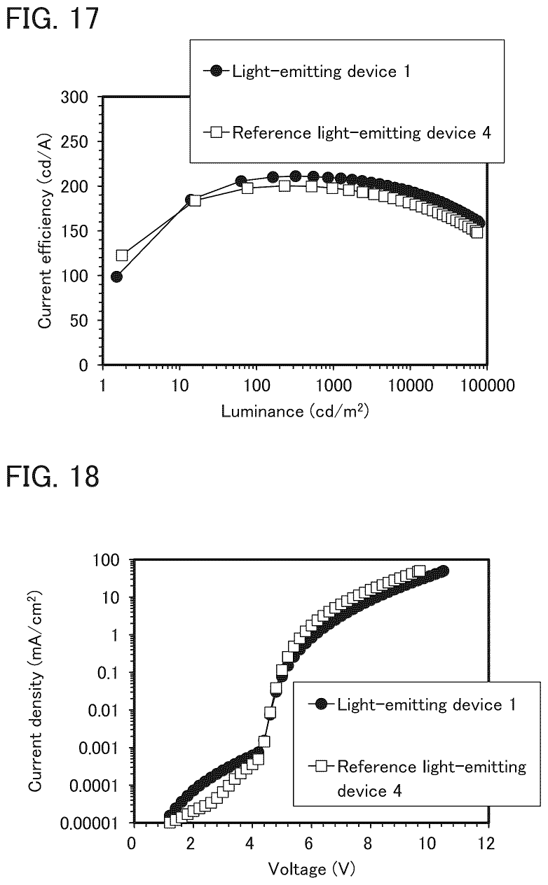

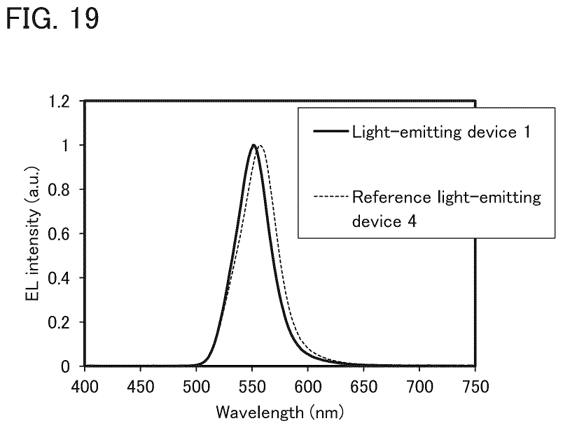

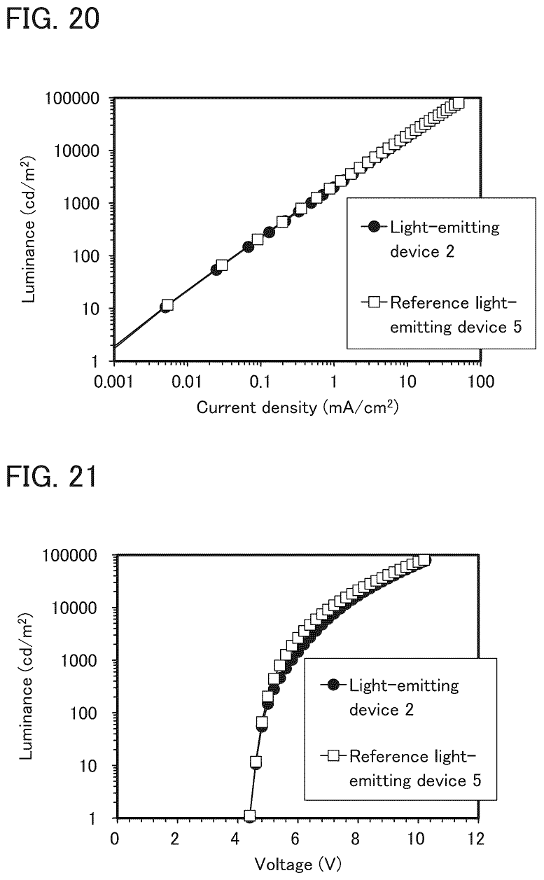

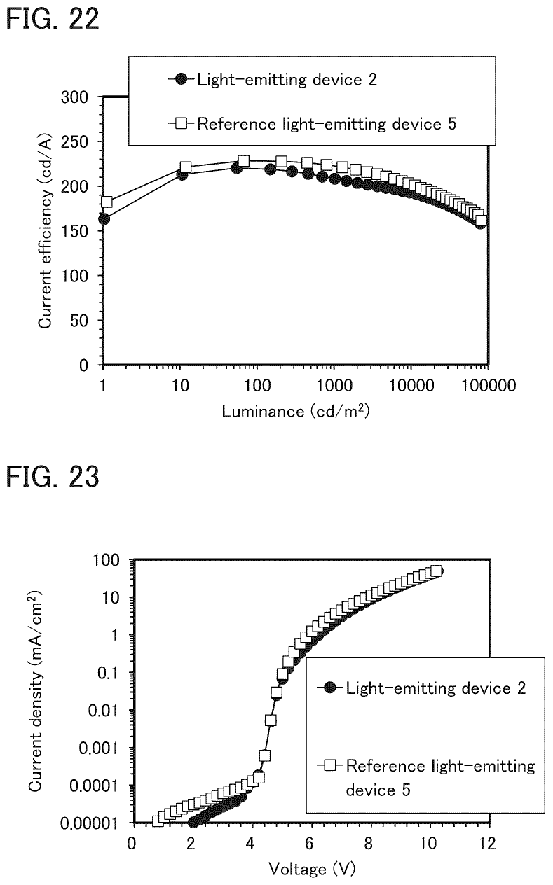

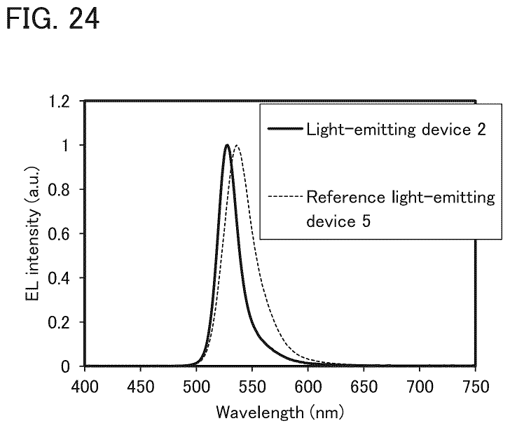

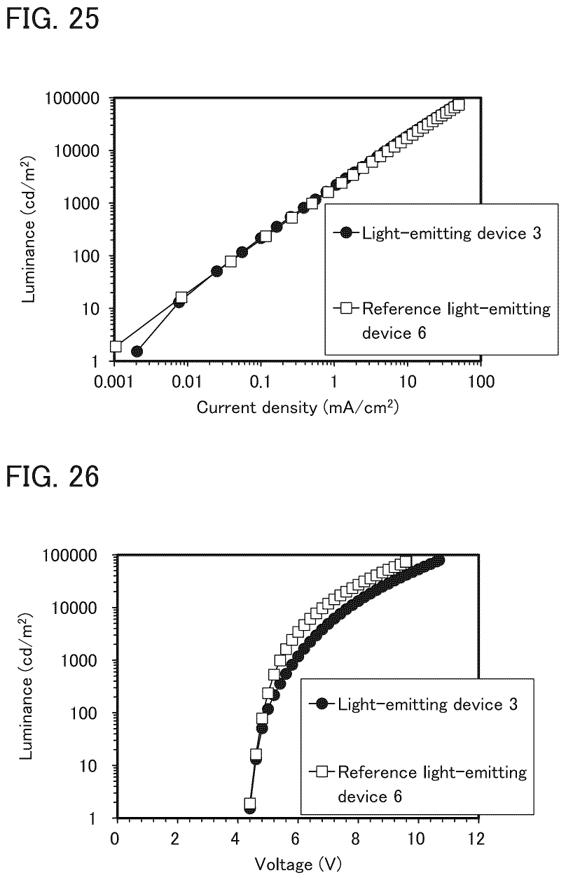

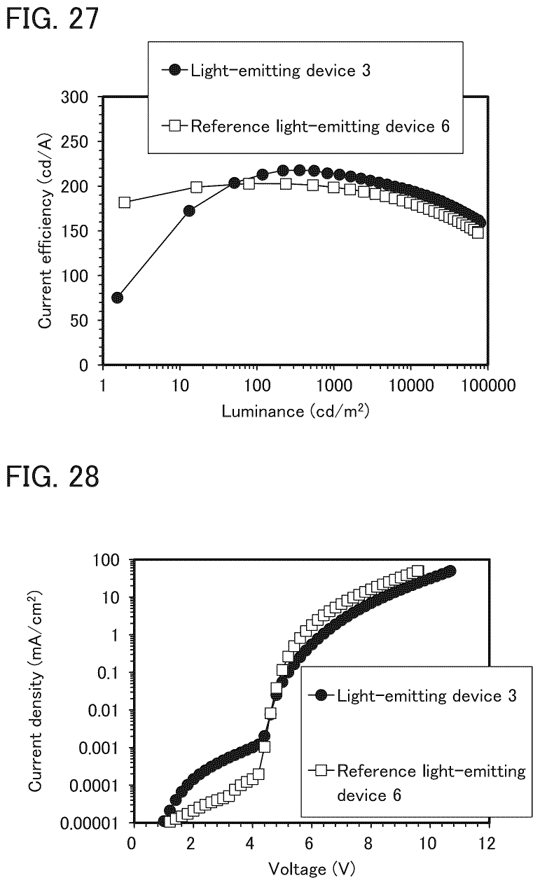

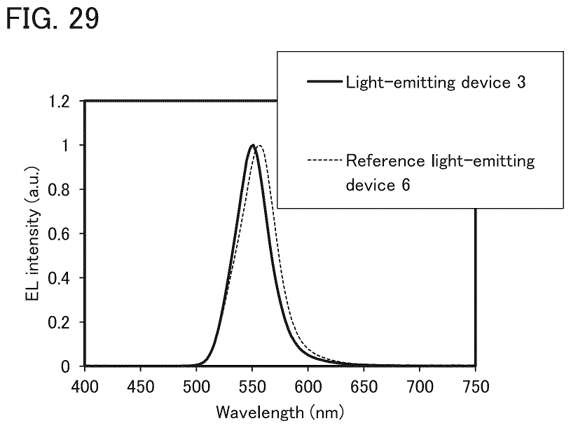

FIG. 15 shows the luminance-current density characteristics of the light-emitting device 1 and the reference light-emitting device 4, FIG. 16 shows the luminance-voltage characteristics thereof, FIG. 17 shows the current efficiency-luminance characteristics thereof, FIG. 18 shows the current density-voltage characteristics thereof, and FIG. 19 shows the electroluminescence spectra thereof. FIG. 20 shows the luminance-current density characteristics of the light-emitting device 2 and the reference light-emitting device 5, FIG. 21 shows the luminance-voltage characteristics thereof, FIG. 22 shows the current efficiency-luminance characteristics thereof, FIG. 23 shows the current density-voltage characteristics thereof, and FIG. 24 shows the electroluminescence spectra thereof. FIG. 25 shows the luminance-current density characteristics of the light-emitting device 3 and the reference light-emitting device 6, FIG. 26 shows the luminance-voltage characteristics thereof, FIG. 27 shows the current efficiency-luminance characteristics thereof, FIG. 28 shows the current density-voltage characteristics thereof, and FIG. 29 shows the electroluminescence spectra thereof.

The table below shows the main characteristics of the light-emitting devices 1 to 3 and the reference light-emitting devices 4 to 6 at a luminance of approximately 1000 cd/m². The luminance, CIE chromaticity, and electroluminescence spectra were measured at normal temperature with a spectroradiometer (SR-UL1R manufactured by TOPCON TECHNOHOUSE CORPORATION).

TABLE 7

| | | | Current | | | | Current |
|---|---|---|---|---|---|---|---|
| | Voltage | Current | density | | | Luminance | efficiency |
| | (V) | (mA) | (mA/cm²) | Chromaticity x | Chromaticity y | (cd/m²) | (cd/A) |
| Light-emitting device 1 | 5.6 | 0.0162 | 0.406 | 0.340 | 0.648 | 850 | 210 |
| Light-emitting device 2 | 5.8 | 0.0195 | 0.488 | 0.211 | 0.745 | 1017 | 208 |
| Light-emitting device 3 | 6.0 | 0.0221 | 0.553 | 0.336 | 0.652 | 1179 | 213 |
| Reference light-emitting device 4 | 5.4 | 0.0195 | 0.487 | 0.367 | 0.623 | 965 | 198 |
| Reference light-emitting device 5 | 5.4 | 0.0142 | 0.355 | 0.277 | 0.698 | 795 | 224 |
| Reference light-emitting device 6 | 5.4 | 0.0199 | 0.497 | 0.363 | 0.627 | 987 | 199 |

FIGS. 15 to 19 and the above table reveal that the light-emitting device 1 exhibits green light emission derived from Ir(5mppy-d₃)₂(mbfpypy-d₃) and has favorable emission characteristics. It can be said that the light-emitting device 1 has high current efficiency and was driven as a tandem light-emitting device. Although processing by a photolithography method was performed in the light-emitting device 1, the characteristics of the light-emitting device 1 are equivalent to those of the reference light-emitting device 4 fabricated without performing processing by a photolithography method. As shown in FIGS. 20 to 29 and the above table, the results of the light-emitting devices 2 and 3 are similar to those of the light-emitting device 1.

The acid dissociation constant pKₐ of Pyrrd-Phen is 11.23 and that of mPPhen2P is 5.16. Thus, using these organic compounds for the first layer of the intermediate layer, which is located on the anode side, led to a lower hole-transport property, prevented holes from reaching the second layer of the intermediate layer, which is located on the cathode side, and enabled the intermediate layer to function as a charge-generation layer.

Furthermore, mPPhen2P has a glass transition temperature of 135° C., i.e., high heat resistance. This enabled formation of a stable intermediate layer that is not easily crystallized and that can withstand the heat treatment step performed after the lithography step.

The HOMO levels and the LUMO levels of Pyrrd-Phen and mPPhen2P used for the intermediate layer were measured by cyclic voltammetry (CV). An electrochemical analyzer (ALS model 600A or 600C, produced by BAS Inc.) was used for the CV measurement. A solvent of the solution used in the measurement was dehydrated dimethylformamide (DMF). In the measurement, the potential of a working electrode with respect to a reference electrode was changed within an appropriate range, so that the oxidation peak potential and the reduction peak potential were obtained. A platinum electrode (PTE platinum electrode, manufactured by BAS Inc.) was used as a working electrode, another platinum electrode (Pt counter electrode for VC-3 (5 cm), manufactured by BAS Inc.) was used as an auxiliary electrode, and an Ag/Ag⁺ electrode (RE7 reference electrode for nonaqueous solvent, manufactured by BAS Inc.) was used as a reference electrode. The HOMO and LUMO levels of the compounds were calculated from the estimated redox potential of the reference electrode of −4.94 eV and the obtained peak potentials. The HOMO level and LUMO level of Pyrrd-Phen were found to be −5.8 eV and −2.55 eV, respectively. Since mPPhen2P has a high oxidation potential and a low HOMO level, the HOMO level of mPPhen2P was not observed, and the LUMO level thereof was −2.71 eV. It was thus found that mPPhen2P has a lower LUMO level than Pyrrd-Phen and easily accepts electrons.

The HOMO levels and the LUMO levels of Pyrrd-Phen and mPPhen2P were calculated from the results of ionization potential measurement (IP measurement) and absorption spectrum measurement. The ionization potential measurement (IP measurement) was performed in the air using a photoemission yield spectrometer in air (AC-3 produced by RIKEN KEIKI Co., Ltd.). The LUMO level was calculated using the HOMO level and an optical band gap (energy (eV) calculated from an absorption edge on the long wavelength side of an absorption spectrum of a thin film). Specifically, the LUMO level was calculated by adding the energy (eV) calculated from the band gap to the HOMO level. The HOMO level and LUMO level of Pyrrd-Phen were found to be −5.34 eV and −2.11 eV, respectively. The HOMO level and LUMO level of mPPhen2P were found to be −5.88 eV and −2.60 eV, respectively. It was thus found that mPPhen2P has a lower LUMO level than Pyrrd-Phen and easily accepts electrons.

Thus, in the intermediate layer of the light-emitting device of one embodiment of the present invention, mPPhen2P easily accepts electrons from the donor level formed by the metal and Pyrrd-Phen. With this structure, electrons are easily injected and transported from the intermediate layer into the electron-transport layer, so that the light-emitting device can be driven at a low voltage.

It was thus found that even when fabricated by a method that includes a process of forming an organic compound layer through processing by a photolithography method, a light-emitting device having the structure of one embodiment of the present invention suffers from little variation in characteristics and has favorable characteristics as compared with a light-emitting device fabricated by a continuous vacuum process. It was also found that a tandem light-emitting device with a low driving voltage and high emission efficiency can be fabricated.

### Example 2

In this example, description is given for results of comparing the external shapes of the light-emitting devices 1 to 3 and the reference light-emitting devices 4 to 6, which are described in Example 1, and comparative light-emitting devices 7 and 8.

### (Comparative Light-Emitting Device 7)

The comparative light-emitting device 7 is different from the light-emitting device 1 in the structure of the first layer of the intermediate layer. That is, the method for fabricating the comparative light-emitting device 7 is different from the method for fabricating the light-emitting device 1 in that to form the first layer of the intermediate layer after the formation of the first electron-transport layer, Pyrrd-Phen and indium (In) were deposited by co-evaporation to a thickness of 5 nm such that the volume ratio of Pyrrd-Phen to In was 1:0.1; the other components were formed in the same manner as those in the light-emitting device 1.

### (Comparative Light-Emitting Device 8)

The comparative light-emitting device 8 was fabricated through what is called a continuous vacuum process, which does not include a process of forming an organic compound layer through processing by a photolithography method, unlike the comparative light-emitting device 7. That is, the method for fabricating the comparative light-emitting device 8 is different from the method for fabricating the comparative light-emitting device 7 in that, after the formation of the second electron-transport layer, the electron-injection layer was successively formed without performing processing by a photolithography method or heat treatment; the other components were formed in the same manner as those in the comparative light-emitting device 7.

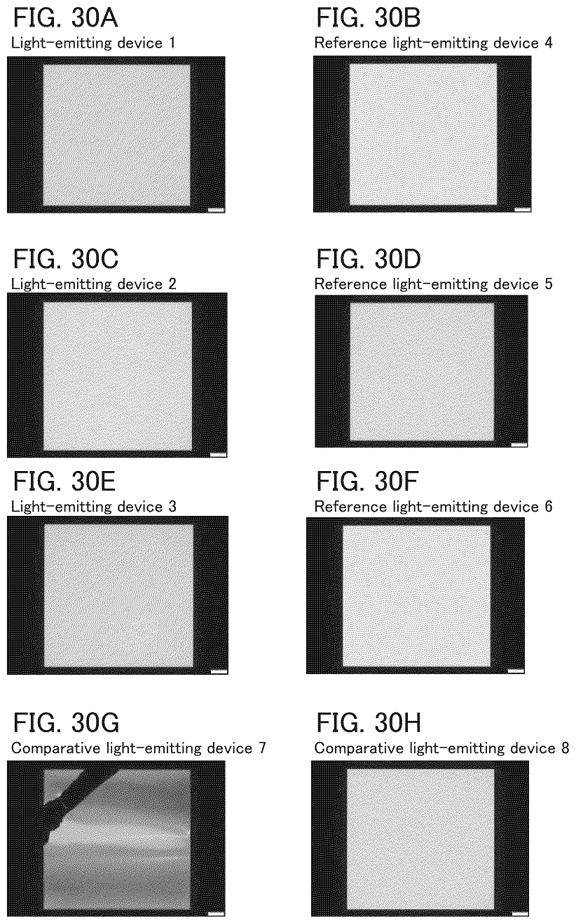

Optical micrographs of the light-emitting devices were taken. The optical micrographs were taken while each light-emitting device having a size of 2 mm×2 mm emitted light by a current of 0.1 mA flowing therethrough, and the light exposure time was 2 ms. FIGS. 30A, 30B, 30C, 30D, 30E, 30F, 30G, and 30H respectively show the optical micrographs of the light-emitting device 1, the reference light-emitting device 4, the light-emitting device 2, the reference light-emitting device 5, the light-emitting device 3, the reference light-emitting device 6, the comparative light-emitting device 7, and the comparative light-emitting device 8.

FIG. 30G shows that film peeling occurred in the comparative light-emitting device 7. This film peeling occurred because the comparative light-emitting device 7 underwent the processing by a lithography method and the quality of the organic compound layer thereby degraded.

Meanwhile, it was found from FIGS. 30A, 30C, and 30E that film peeling did not occur in the light-emitting devices 1 to 3, which underwent the processing step by a lithography method like the comparative light-emitting device 7. This is because not only the metal and Pyrrd-Phen as the first organic compound but also mPPhen2P as the second organic compound are included in the first layer of the intermediate layer of each of the light-emitting devices 1 to 3 to improve the film quality and inhibit film peeling.

### Example 3

In this example, samples imitating the first layer of the intermediate layer of the light-emitting device of one embodiment of the present invention were evaluated by an electron spin resonance method, and the evaluation results are described.

First, methods for fabricating the samples used in this example are described.

### (Method for Fabricating Sample 1)

First, a quartz substrate was fixed to a holder in a vacuum evaporation apparatus such that the surface to be subjected to vapor deposition faced downward. Next, the pressure in the vacuum evaporation apparatus was reduced to 1×10⁻⁴ Pa and then, mPPhen2P, Pyrrd-Phen, and In were deposited by co-evaporation to a thickness of 50 nm such that the volume ratio of mPPhen2P to Pyrrd-Phen to In was 0.5:0.5:0.02, whereby a sample 1 was fabricated. Note that the size of the quartz substrate was 3.0 mm 20 mm.

### (Method for Fabricating Sample 2)

A sample 2 was fabricated by replacing In used in the sample 1 with Ag. The other conditions were similar to those of the sample 1.

### (Method for Fabricating Comparative Sample 3)

A comparative sample 3 was fabricated by omitting mPPhen2P from the sample 1; that is, the comparative sample 3 was fabricated by depositing Pyrrd-Phen and In by co-evaporation to a thickness of 50 nm such that the volume ratio of Pyrrd-Phen to In was 1:0.02. The other conditions were similar to those of the sample 1.

### (Method for Fabricating Comparative Sample 4)

A comparative sample 4 was fabricated by omitting Pyrrd-Phen from the sample 1; that is, the comparative sample 4 was fabricated by depositing mPPhen2P and In by co-evaporation to a thickness of 50 nm such that the volume ratio of mPPhen2P to In was 1:0.02. The other conditions were similar to those of the sample 1.

### (Method for Fabricating Comparative Sample 5)

A comparative sample 5 was fabricated by omitting mPPhen2P from the sample 2; that is, the comparative sample 5 was fabricated by depositing Pyrrd-Phen and Ag by co-evaporation to a thickness of 50 nm such that the volume ratio of Pyrrd-Phen to Ag was 1:0.02. The other conditions were similar to those of the sample 2.

### (Method for Fabricating Comparative Sample 6)

A comparative sample 6 was fabricated by omitting In from the sample 1; that is, the comparative sample 6 was fabricated by depositing Pyrrd-Phen and mPPhen2P by co-evaporation to a thickness of 50 nm such that the weight ratio of Pyrrd-Phen to mPPhen2P was 0.5:0.5. The other conditions were similar to those of the sample 1.

### (Method for Fabricating Comparative Samples 7 to 9)

A comparative sample 7 was fabricated by depositing Pyrrd-Phen by evaporation. A comparative sample 8 was fabricated by depositing mPPhen2P by evaporation. A comparative sample 9 was fabricated by depositing In by evaporation. The other conditions were similar to those of the sample 1.

The fabricated samples were evaluated by an electron spin resonance (ESR) method. Note that the measurement of the electron spin resonance spectrum using an ESR method was performed with an electron spin resonance spectrometer E500 (manufactured by Bruker Corporation). The measurement was performed at room temperature under the conditions where the resonance frequency was 9.56 GHz, the output power was 1 mW, the modulated magnetic field was 50 mT, the modulation width was 0.5 mT, the time constant was 0.04 s, and the sweep time was 1 min.

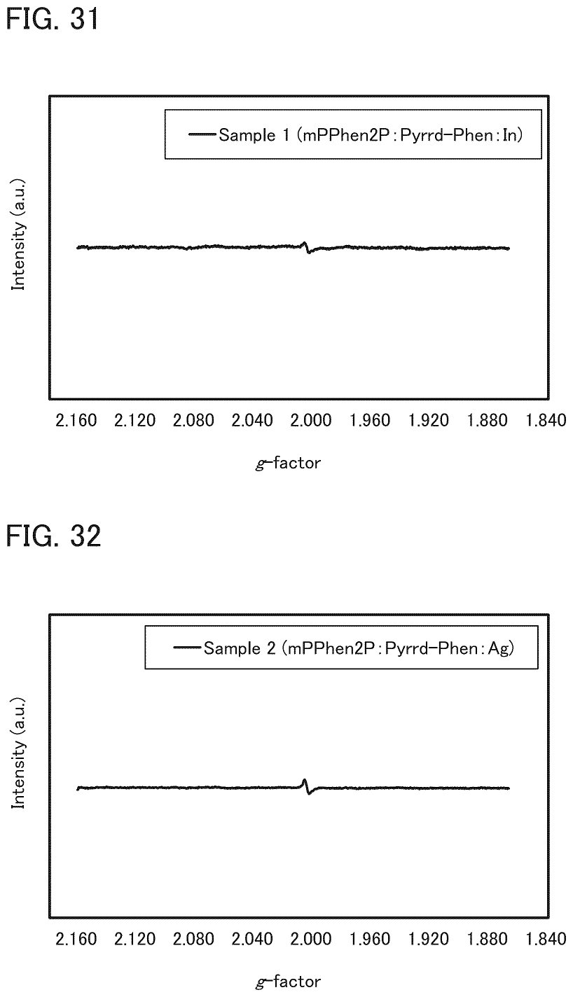

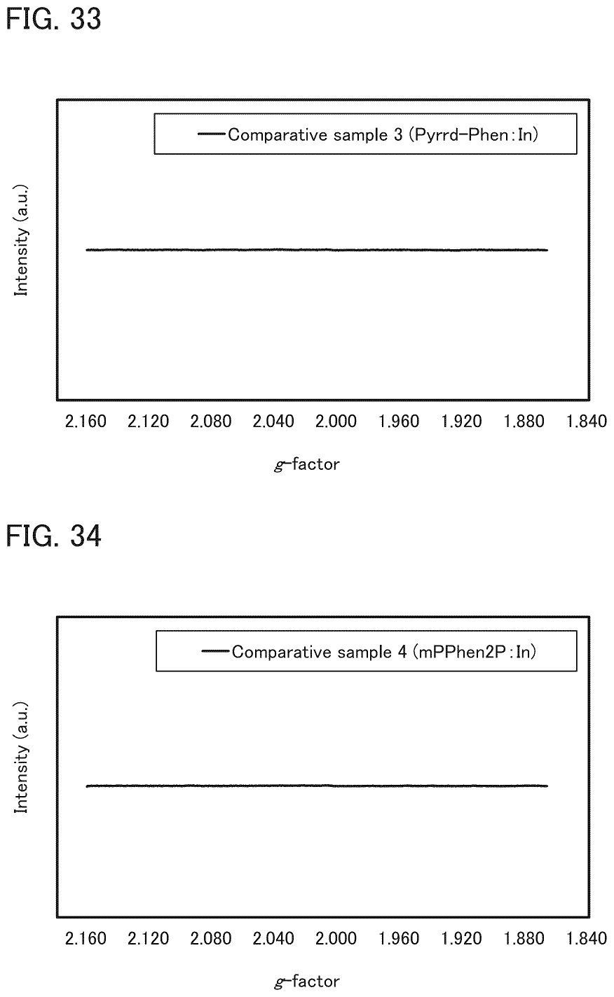

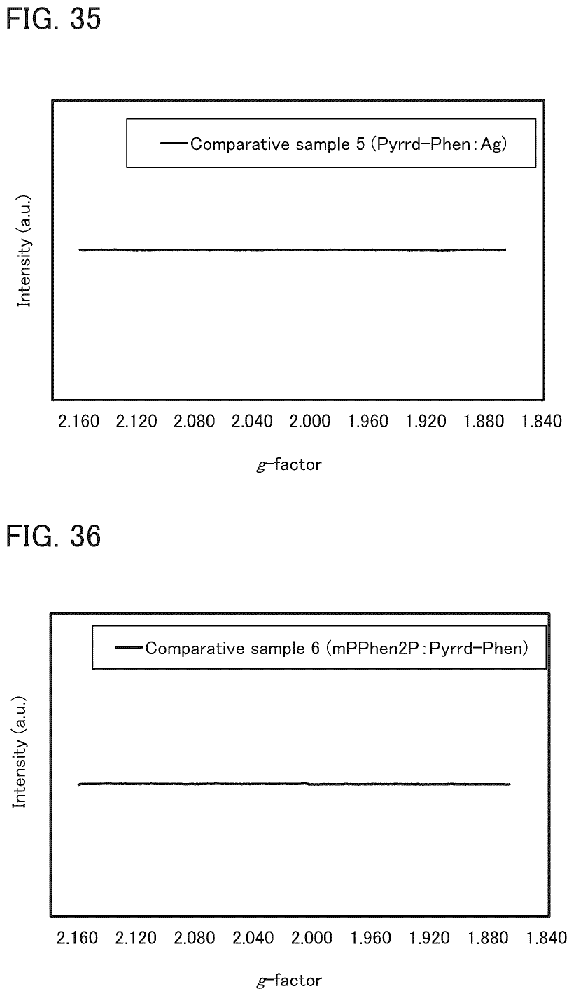

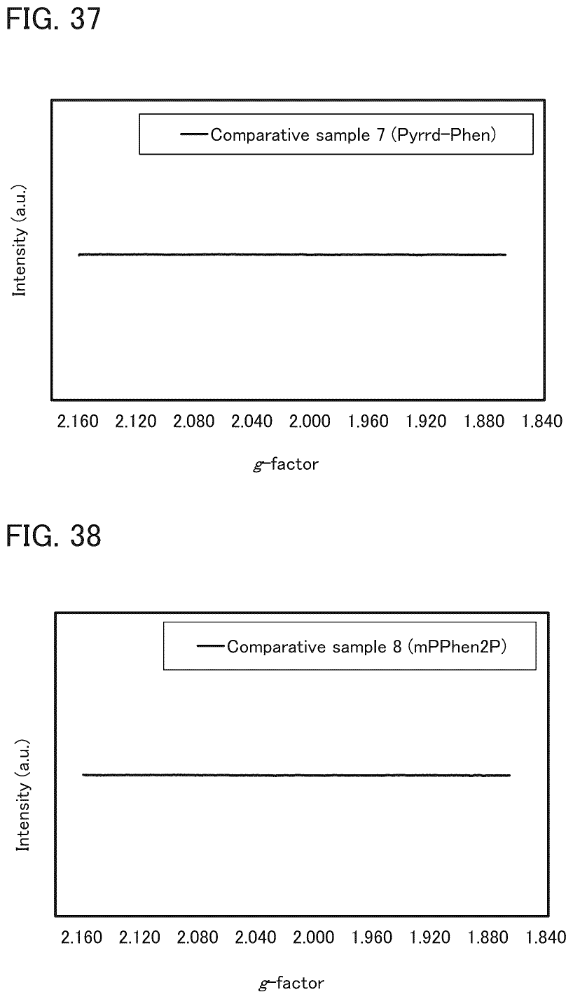

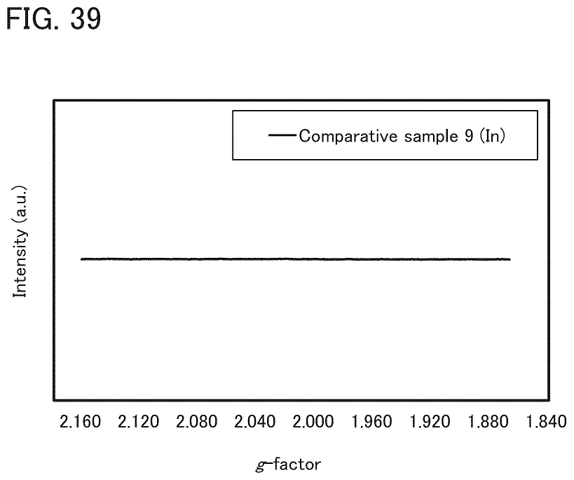

FIGS. 31 to 39 show ESR measurement results of the fabricated samples. FIGS. 31, 32, 33, 34, 35, 36, 37, 38, and 39 respectively show the ESR spectra of the sample 1, the sample 2, the comparative sample 3, the comparative sample 4, the comparative sample 5, the comparative sample 6, the comparative sample 7, the comparative sample 8, and the comparative sample 9. The table below shows the structure of each sample and the density of spins attributed to a signal at a g-factor of approximately 2.00.

TABLE 8

| | | Spin density |
|---|---|---|
| | Structure | (spins/cm³) |
| Sample 1 | mPPhen2P:Pyrrd-Phen:In | 8.7 × 10¹⁶ |
| | (0.5:0.5:0.02) | |
| Sample 2 | mPPhen2P:Pyrrd-Phen:Ag | 1.3 × 10¹⁷ |
| | (0.5:0.5:0.02) | |
| Comparative | Pyrrd-Phen:In (1:0.02) | 0 |
| sample 3 | | |
| Comparative | mPPhen2P:In (1:0.02) | 0 |
| sample 4 | | |
| Comparative | Pyrrd-Phen:Ag (1:0.02) | 0 |
| sample 5 | | |
| Comparative | mPPhen2P:Pyrrd-Phen | 0 |
| sample 6 | (0.5:0.5) | |
| Comparative | Pyrrd-Phen | 0 |
| sample 7 | | |
| Comparative | mPPhen2P | 0 |
| sample 8 | | |
| Comparative | In | 0 |
| sample 9 | | |

*Lower detection limit: 1.4 × 10¹⁶ spins/cm³

FIGS. 31 to 39 and the above table show that the samples 1 and 2 exhibited a signal at a g-factor of approximately 2.00 and the measured spin density of the samples 1 and 2 was higher than or equal to 5×10¹⁶ spins/cm³, whereas the comparative samples 3 to 9 exhibited no signal at a g-factor of approximately 2.00 and the spin density of the comparative samples 3 to 9 was lower than 1.4×10¹⁶ spins/cm³, which is the lower detection limit of the electron spin resonance spectrometer. It was thus found that the spin density of the samples 1 and 2 in which three kinds of materials were combined was higher than that of the samples in which two kinds of materials were combined and the samples formed using a single material.

The above showed that in each of the layers including the combination of the metal, the first organic compound, and the second organic compound, interaction between the materials occurred and a SOMO level was formed.

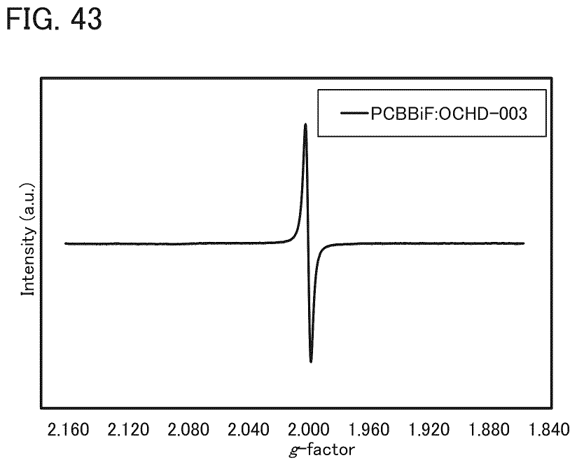

Similarly, an electron spin resonance spectrum of a thin film formed in the following manner was measured at room temperature: PCBBiF and OCHD-003 were deposited by co-evaporation to a thickness of 100 nm over a quartz substrate such that the weight ratio of PCBBiF to OCHD-003 was 1:0.1. The measurement of the electron spin resonance spectrum using an ESR method was performed with an electron spin resonance spectrometer JES FA300 (manufactured by JEOL Ltd.). The measurement was performed at room temperature under the conditions where the resonance frequency was 9.18 GHz, the output power was 1 mW, the modulated magnetic field was 50 mT, the modulation width was 0.5 mT, the time constant was 0.03 s, and the sweep time was 1 min. FIG. 43 shows the measurement results. From FIG. 43, it was found that a signal was observed at a g-factor of approximately 2.00 and the spin density was 5′10¹⁹ spins/cm³. This shows that OCHD-003 has an electron-accepting property with respect to PCBBiF and a layer including PCBBiF and OCHD-003 functions as a charge-generation layer.

### Example 4

In this example, light-emitting devices 9G, 9R, and 9B that are embodiments of the present invention and comparative light-emitting devices 10G, 10R, 10B, 11G, 11R, and 11B are described. Note that the light-emitting devices 9G, 9R, and 9B and the comparative light-emitting devices 10G, 10R, 10B, 11G, 11R, and 11B were fabricated by a process in which an organic compound layer is formed through processing by a photolithography method. In each of the light-emitting devices 9G, 9R, and 9B and the comparative light-emitting devices 10G, 10R, and 10B, the organic compound layer was formed such that a resolution of 508 ppi would be achieved, and in each of the comparative light-emitting devices 11G, 11R, and 11B, the organic compound layer was formed such that a resolution of 3207 ppi would be achieved. The structural formulae of the organic compounds used in the light-emitting devices 9G, 9R, and 9B and the comparative light-emitting devices 10G, 10R, 10B, 11G, 11R, and 11B are shown below.

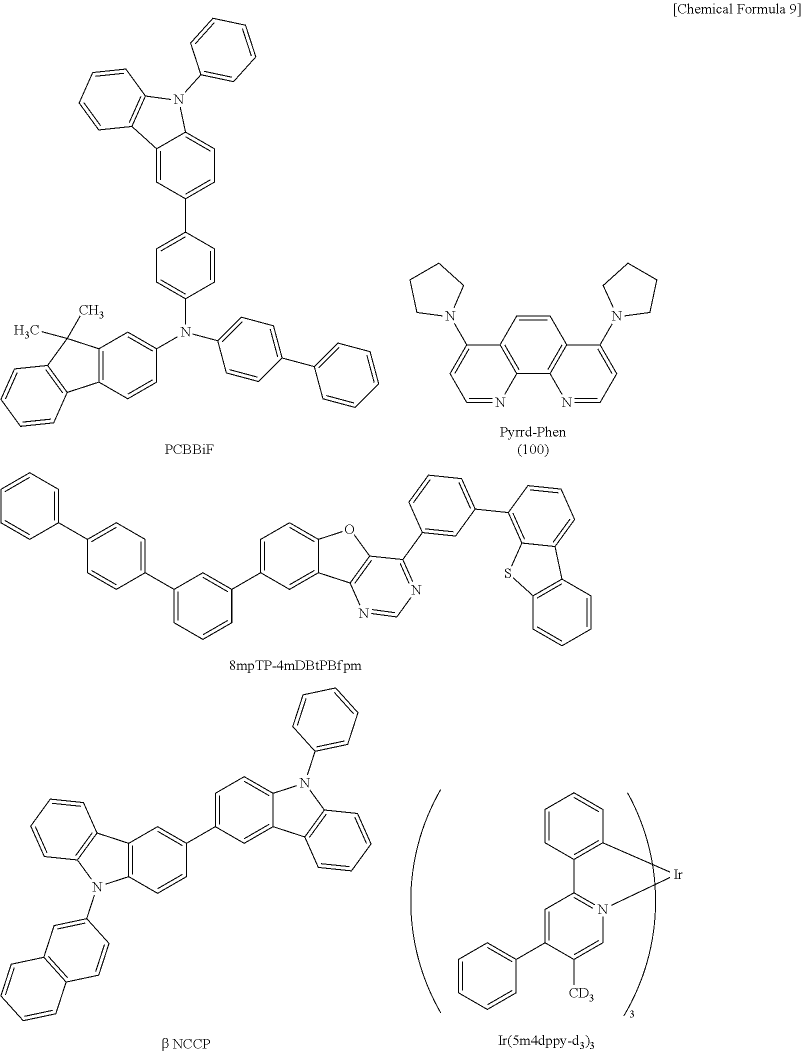

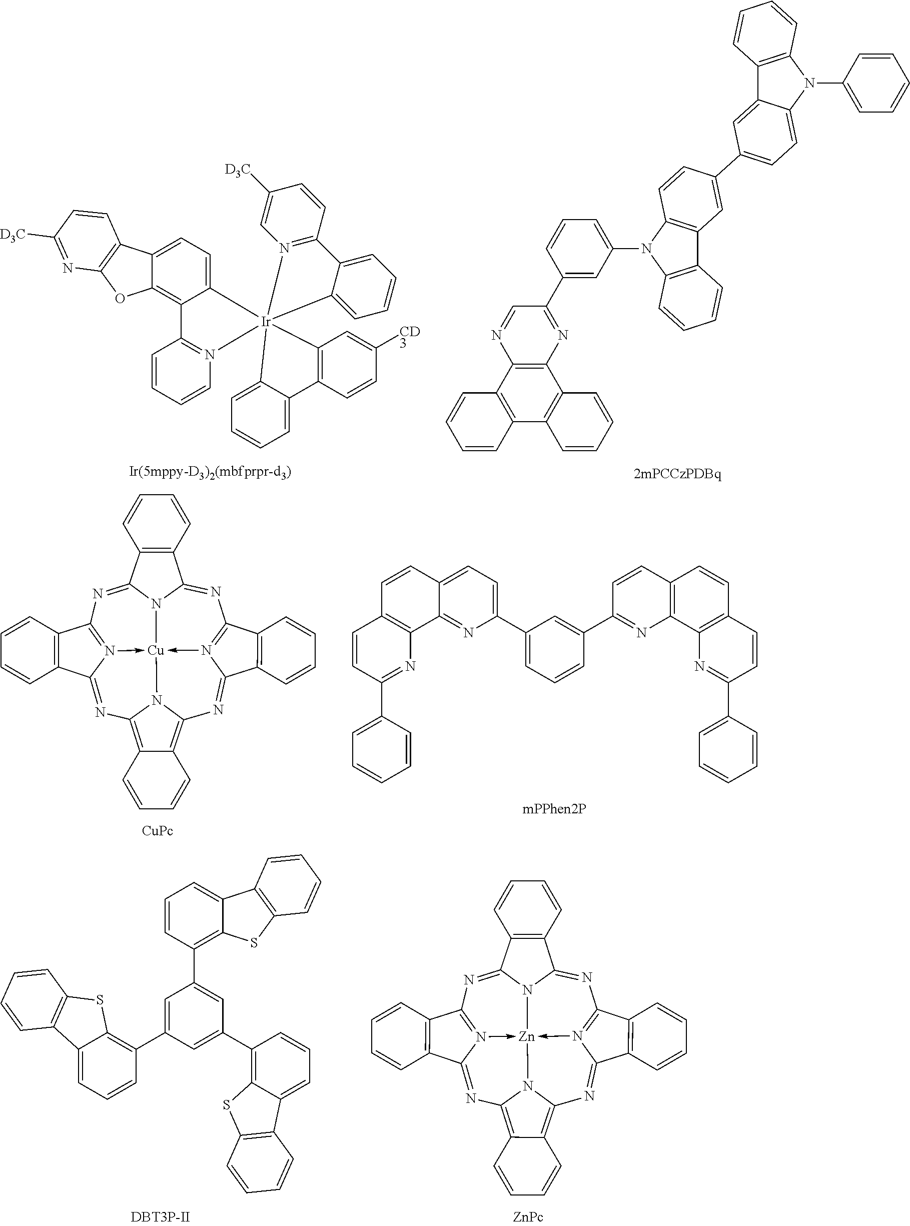

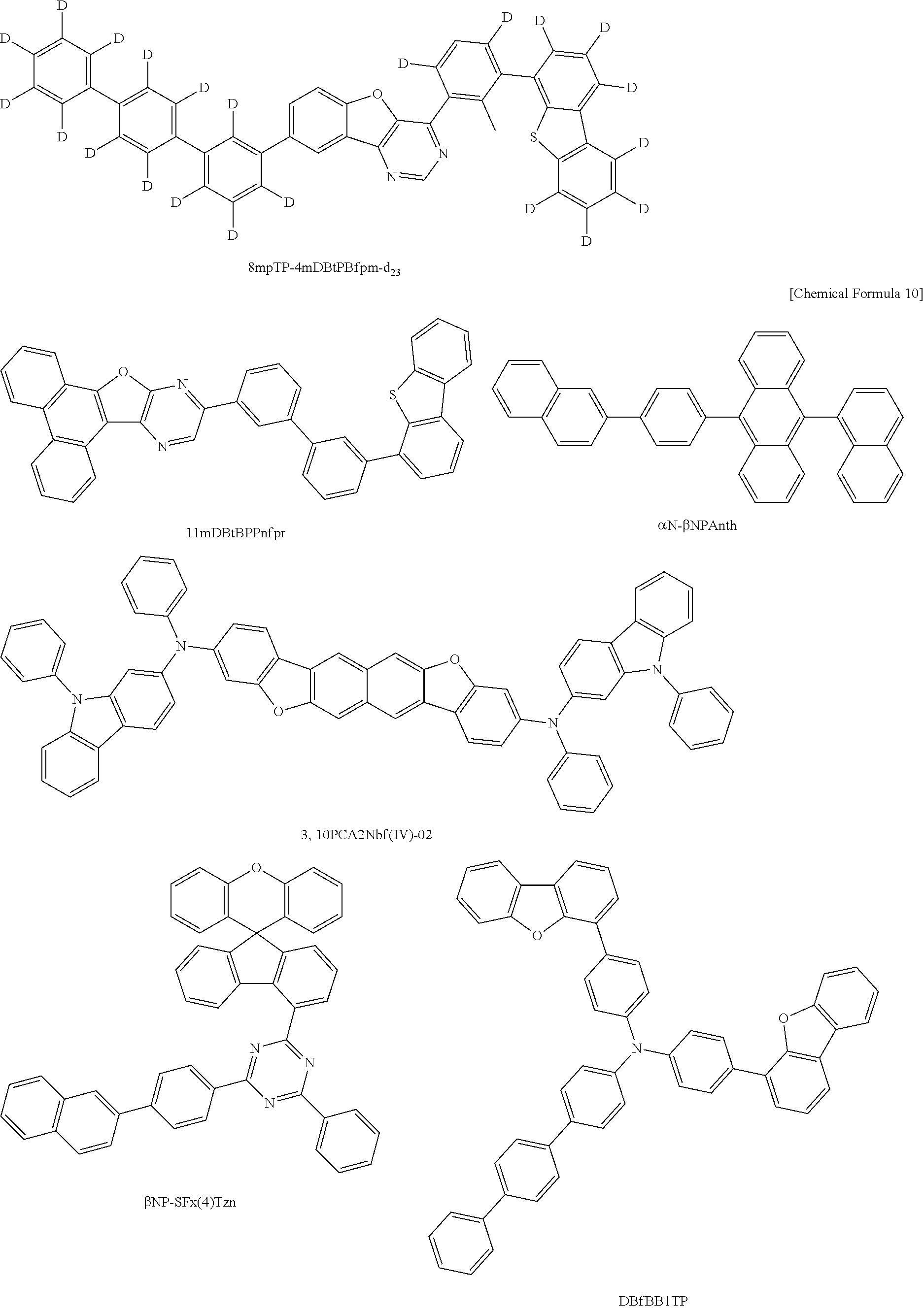

### (Method for Fabricating Light-Emitting Device 9G)

The light-emitting device 9G includes an intermediate layer having the same structure as the intermediate layer of the light-emitting device 1. Note that the light-emitting device 9G is different from the light-emitting device 1 in the method for forming the organic compound layer through processing by a photolithography method and the method for the heat treatment.

First, as a reflective electrode, an alloy containing silver (Ag), palladium (Pd), and copper (Cu) (abbreviation: APC) was deposited over a glass substrate to a thickness of 100 nm by a sputtering method, and then, as a transparent electrode, indium tin oxide containing silicon oxide (ITSO) was deposited to a thickness of 50 nm by a sputtering method, so that the first electrode was formed. Note that the transparent electrode functions as the anode, and the transparent electrode and the reflective electrode can be collectively regarded as the first electrode.

Note that the first electrodes were formed to achieve matrix arrangement of 40×40=1600 pixels in an area of 2 mm×2 mm. This shape and arrangement correspond to a resolution of 508 ppi, and each pixel was formed to include three subpixels.

Next, in pretreatment for forming the light-emitting devices over the substrate, the surface of the substrate was washed with water, and baking was performed at 200° C. for 1 hour.

After that, the substrate was transferred into a vacuum evaporation apparatus where the pressure had been reduced to approximately 1′10⁻⁴ Pa, and was subjected to heat treatment at 170° C. for 30 minutes in a heating chamber of the vacuum evaporation apparatus, and then the substrate was cooled down for approximately 30 minutes.

Then, the substrate was fixed to a substrate holder provided in the vacuum evaporation apparatus such that the surface on which the first electrodes were formed faced downward. Over the first electrodes, PCBBiF and OCHD-003 were deposited by co-evaporation to a thickness of 10 nm such that the weight ratio of PCBBiF to OCHD-003 was 1:0.03, whereby the hole-injection layer was formed.

Over the hole-injection layer, PCBBiF was deposited by evaporation to a thickness of 120 nm, so that the first hole-transport layer was formed.

Then, over the first hole-transport layer, 8mpTP-4mDBtPBfpm, βNCCP, and Ir(5mppy-d₃)₂(mbfpypy-d₃) were deposited by co-evaporation to a thickness of 40 nm such that the weight ratio of 8mpTP-4mDBtPBfpm to βNCCP to Ir(5mppy-d₃)₂(mbfpypy-d₃) was 0.5:0.5:0.1, whereby the first light-emitting layer was formed.

After that, 2mPCCzPDBq was deposited by evaporation to a thickness of 10 nm, so that the first electron-transport layer was formed.

After the formation of the first electron-transport layer, mPPhen2P, Pyrrd-Phen (Structural Formula (100)), and indium (In) were deposited by co-evaporation to a thickness of 5 nm such that the volume ratio of mPPhen2P to Pyrrd-Phen to In was 0.5:0.5:0.02, whereby the first layer of the intermediate layer was formed.

Then, a film of copper phthalocyanine (abbreviation: CuPc) was formed to have a thickness of 2 nm, so that the third layer of the intermediate layer was formed.

Furthermore, PCBBiF and OCHD-003 were deposited by co-evaporation to a thickness of 10 nm such that the weight ratio of PCBBiF to OCHD-003 was 1:0.15, whereby the second layer of the intermediate layer was formed.

Next, over the intermediate layer, PCBBiF was deposited by evaporation to a thickness of 50 nm, so that the second hole-transport layer was formed.

Over the second hole-transport layer, 8mpTP-4mDBtPBfpm, βNCCP, and Ir(5mppy-d₃)₂(mbfpypy-d₃) were deposited by co-evaporation to a thickness of 40 nm such that the weight ratio of 8mpTP-4mDBtPBfpm to βNCCP to Ir(5mppy-d₃)₂(mbfpypy-d₃) was 0.5:0.5:0.1, whereby the second light-emitting layer was formed.

After that, 2mPCCzPDBq was deposited by evaporation to a thickness of 20 nm and mPPhen2P was further deposited by evaporation to a thickness of 20 nm, so that the second electron-transport layer was formed.

After the formation of the second electron-transport layer, processing by a photolithography method and heat treatment were performed.

### <<Processing by Photolithography Method and Heat Treatment 2>>

After the second electron-transport layer was formed, tris(8-quinolinolato)aluminum(III) (abbreviation: Alq₃) was deposited by evaporation to a thickness of 10 nm, the substrate was taken out from the vacuum evaporation apparatus and exposed to the air, and then aluminum oxide was deposited to a thickness of 30 nm by an ALD method using trimethylaluminum (abbreviation: TMA) as a precursor and water vapor as an oxidizer to form the first sacrificial layer.

Next, over the first sacrificial layer, molybdenum was deposited to a thickness of 50 nm by a sputtering method to form the second sacrificial layer.

Then, resists were formed using a photoresist over the second sacrificial layer, and processing was performed such that an end portion of the organic compound layer was located outward from an end surface of the first electrode. Thus, the light-emitting devices enabling a resolution of 508 ppi can be formed.

Specifically, the second sacrificial layer was processed using an etching gas containing sulfur hexafluoride (SF₆) and oxygen (O₂) at a flow rate ratio of SF₆:O₂ 10:4 and an etching gas containing oxygen (O₂) with the use of the resists as masks and then, the first sacrificial layer was processed using an etching gas containing fluoroform (CHF₃) and helium (He) at a flow rate ratio of CHF₃:He=1:49 with the use of the second sacrificial layer as a hard mask. Then, the second electron-transport layer, the second light-emitting layer, the second hole-transport layer, the intermediate layer, the first electron-transport layer, the first light-emitting layer, the first hole-transport layer, and the hole-injection layer were processed using an etching gas containing oxygen (O₂).

After the organic compound layer was formed by the processing, the second sacrificial layer was removed using an etching gas containing sulfur hexafluoride (SF₆) and oxygen (O₂) at SF₆:O₂=10:4 (flow rate ratio) and an etching gas containing oxygen (O₂), whereas the first sacrificial layer was left. Then, aluminum oxide was deposited to a thickness of 15 nm by an ALD method, so that a protective film was formed.

Next, layers of a photosensitive high molecular material were formed over the protective film to overlap with the first electrodes by a photolithography method. After heating was performed at 100° C. in an air atmosphere for 10 minutes, unnecessary portions of the Alq₃ layer, the first sacrificial layer, and the protective film were removed using a mixed acid aqueous solution containing hydrofluoric acid (HF), so that the second electron-transport layers were exposed. At this time, the layers of the photosensitive high molecular material function as resists.

Then, the substrate was transferred into a vacuum evaporation apparatus where the pressure had been reduced to approximately 1′10⁻⁴ Pa, and heat treatment was performed at 100° C. for 1 hour in a heating chamber of the vacuum evaporation apparatus.

The above is the description of the processing by a photolithography method and the heat treatment. As described above, in the processing by a photolithography method and the heat treatment, treatment using water or a chemical solution containing water as a solvent is performed.

After the processing by a photolithography method and the heat treatment, over the exposed second electron-transport layers, lithium fluoride (LiF) and ytterbium (Yb) were deposited by co-evaporation to a thickness of 1.5 nm such that the volume ratio of LiF to Yb was 1:0.5 to form the electron-injection layer, and lastly silver (Ag) and magnesium (Mg) were deposited by co-evaporation to a thickness of 15 nm such that the volume ratio of Ag to Mg was 1:0.1 to form the second electrode, whereby the light-emitting devices 9G were fabricated.

The second electrode is a semi-transmissive and semi-reflective electrode having a function of reflecting light and a function of transmitting light; thus, the light-emitting device of this example is a top-emission tandem device in which light is extracted through the second electrode. Over the second electrode, 4,4′,4″-(benzene-1,3,5-triyl)tri(dibenzothiophene) (abbreviation: DBT3P-II) was deposited by evaporation to a thickness of 70 nm as a cap layer to improve light extraction efficiency.

The method for forming the organic compound layer through processing by a photolithography method and the method for the heat treatment for the light-emitting device 9G are as described above.

### (Method for Fabricating Comparative Light-Emitting Device 10G)

The comparative light-emitting device 10G is different from the light-emitting device 9G in that to form the first layer of the intermediate layer, mPPhen2P and Li₂O were deposited by co-evaporation to a thickness of 5 nm such that the volume ratio of mPPhen2P to Li₂O was 1:0.02. The other components were formed in the same manner as those in the light-emitting device 9G.

The table below lists the structures of the light-emitting device 9G and the comparative light-emitting device 10G.

TABLE 9

| | | | | Comparative |
|---|---|---|---|---|
| | | | Light-emitting | light-emitting |
| | | Thickness | device 9G | device 10G |
| Cap layer | | 70 nm | DBT3P-II | |
| Second electrode | | 15 nm | Ag:Mg (1:0.1) | |
| Electron-injection | | 1.5 nm | LiF:Yb (1:0.5) | |
| layer | | | | |
| — | | | Processing was performed by | |
| | | | photolithography method. | |
| Second | 2 | 20 nm | mPPhen2P | |
| electron- | 1 | 20 nm | 2mPCCzPDBq | |
| transport | | | | |
| layer | | | | |
| Second light- | | 40 nm | 8mpTP-4mDBtPBfpm:βNCCP: | |
| emitting layer | | | Ir(5mppy-d₃)₂(mbfpypy-d₃) | |
| | | | (0.5:0.5:0.1) | |
| Second hole- | | 50 nm | PCBBiF | |
| transport layer | | | | |
| Intermediate | Second | 10 nm | PCBBiF:OCHD-003 (1:0.15) | |
| layer | layer | | | |
| | Third | 2 nm | CuPc | |
| | layer | | | |
| | First | 5 nm | mPPhen2P: | mPPhen2P: |
| | layer | | Pyrrd-Phen:In | Li₂O |
| | | | (0.5:0.5:0.02) | (1:0.02) |

| First electron- | | 10 nm | 2mPCCzPDBq |
|---|---|---|---|
| transport layer | | | |
| First light-emitting | | 40 nm | 8mpTP-4mDBtPBfpm:βNCCP: |
| layer | | | Ir(5mppy-d₃)₂(mbfpypy-d₃) |
| | | | (0.5:0.5:0.1) |
| First hole-transport | | 120 nm | PCBBiF |
| layer | | | |
| Hole-injection layer | | 10 nm | PCBBiF:OCHD-003 (1:0.03) |
| First | 2 | 50 nm | ITSO |
| electrode | 1 | 100 nm | APC |

### (Method for Fabricating Light-Emitting Device 9R)

The light-emitting device 9R is different from the light-emitting device 9G in the structures of the first and second light-emitting layers and the thicknesses of the first hole-transport layer, the second hole-transport layer, and the second electron-transport layer; the other components were formed in the same manner as those in the light-emitting device 9G. Specifically, to form each of the first and second light-emitting layers of the light-emitting device 9R, 11-[3′-(dibenzothiophen-4-yl)biphenyl-3-yl]phenanthro[9′,10′:4,5]furo[2,3-b]pyrazine (abbreviation: 11mDBtBPPnfpr), PCBBiF, and OCPG-006 as a material emitting red phosphorescent light were deposited by co-evaporation to a thickness of 50 nm such that the weight ratio of 11mDBtBPPnfpr to PCBBiF to OCPG-006 was 0.7:0.3:0.05. In the light-emitting device 9R, the thickness of the first hole-transport layer was 15 nm, the thickness of the second hole-transport layer was 65 nm, the thickness of the 2mPCCzPDBq layer of the second electron-transport layer was 10 nm, and as in the light-emitting device 9G, the thickness of the mPPhen2P layer of the second electron-transport layer was 20 nm.

### (Method for Fabricating Comparative Light-Emitting Device 10R)

The comparative light-emitting device 10R is different from the light-emitting device 9R in that to form the first layer of the intermediate layer, mPPhen2P and Li₂O were deposited by co-evaporation to a thickness of 5 nm such that the volume ratio of mPPhen2P to L₂O was 1:0.02. The other components were formed in the same manner as those in the light-emitting device 9R.

The table below lists the structures of the light-emitting device 9R and the comparative light-emitting device 10R.

TABLE 10

| | | | Light- | Comparative |
|---|---|---|---|---|
| | | | emitting | light-emitting |
| | | Thickness | device 9R | device 10R |
| Cap layer | | 70 nm | DBT3P-II | |
| Second electrode | | 15 nm | Ag:Mg (1:0.1) | |
| Electron-injection | | 1.5 nm | LiF:Yb (1:0.5) | |
| layer | | | | |
| — | | | Processing was performed by | |
| | | | photolithography method. | |
| Second | 2 | 20 nm | mPPhen2P | |
| electron- | 1 | 10 nm | 2mPCCzPDBq | |
| transport | | | | |
| layer | | | | |
| Second light- | | 50 nm | 11mDBtBPPnfpr:PCBBiF: | |
| emitting layer | | | OCPG-006 (0.7:0.3:0.05) | |
| Second hole- | | 65 nm | PCBBiF | |
| transport layer | | | | |
| Intermediate | Second | 10 nm | PCBBiF:OCHD-003 (1:0.15) | |
| layer | layer | | | |
| | Third | 2 nm | CuPc | |
| | layer | | | |
| | First | 5 nm | mPPhen2P: | mPPhen2P: |
| | layer | | Pyrrd-Phen:In | Li₂O |
| | | | (0.5:0.5:0.02) | (1:0.02) |

| First electron- | | 10 nm | 2mPCCzPDBq |
|---|---|---|---|
| transport layer | | | |
| First light-emitting | | 50 nm | 11mDBtBPPnfpr:PCBBiF: |
| layer | | | OCPG-006 (0.7:0.3:0.05) |
| First hole-transport | | 15 nm | PCBBiF |
| layer | | | |
| Hole-injection layer | | 10 nm | PCBBiF:OCHD-003 (1:0.03) |
| First | 2 | 50 nm | ITSO |
| electrode | 1 | 100 nm | APC |

### (Method for Fabricating Light-Emitting Device 9B)

The light-emitting device 9B is different from the light-emitting device 9G in the structures of the first hole-transport layer, the first light-emitting layer, the first electron-transport layer, the second hole-transport layer, the second light-emitting layer, and the second electron-transport layer; the other components were formed in the same manner as those in the light-emitting device 9G. Specifically, to form the first hole-transport layer of the light-emitting device 9B, PCBBiF was deposited by evaporation to a thickness of 70 nm and then, N,N-bis[4-(dibenzofuran-4-yl)phenyl]-4-amino-p-terphenyl (abbreviation: DBfBB1TP) was deposited by evaporation to a thickness of 10 nm. To form each of the first and second light-emitting layers of the light-emitting device 9B, 9-(1-naphthyl)−10-[4-(2-naphthyl)phenyl]anthracene (abbreviation: αN-βNPAnth) and 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02) were deposited by co-evaporation to a thickness of 25 nm such that the weight ratio of αN-βNPAnth to 3,10PCA2Nbf(IV)-02 was 1:0.015. To form the first electron-transport layer of the light-emitting device 9B, 2-[4-(2-naphthalenyl)phenyl]−4-phenyl-6-spiro[9H-fluorene-9,9′-[9H]xanthen]-4-yl-1,3,5-triazine (abbreviation: βNP-SFx(4)Tzn) was deposited by evaporation to a thickness of 10 nm. To form the second hole-transport layer of the light-emitting device 9B, PCBBiF was deposited by evaporation to a thickness of 35 nm and then, DBfBB1TP was deposited by evaporation to a thickness of 10 nm. To form the second electron-transport layer of the light-emitting device 9B, βNP-SFx(4)Tzn was deposited by evaporation to a thickness of 15 nm and then, mPPhen2P was deposited by evaporation to a thickness of 20 nm.

### (Method for Fabricating Comparative Light-Emitting Device 10B)

The comparative light-emitting device 10B is different from the light-emitting device 9B in the structures of the first electron-transport layer, the second electron-transport layer, and the first layer of the intermediate layer; the other components were formed in the same manner as those in the light-emitting device 9B. Specifically, to form the first electron-transport layer of the comparative light-emitting device 10B, 2mPCCzPDBq was deposited by evaporation to a thickness of 10 nm; to form the second electron-transport layer of the comparative light-emitting device 10B, 2mPCCzPDBq was deposited by evaporation to a thickness of 15 nm and then, mPPhen2P was deposited by evaporation to a thickness of 20 nm. To form the first layer of the intermediate layer of the comparative light-emitting device 10B, mPPhen2P and Li₂O were deposited by co-evaporation to a thickness of 5 nm such that the volume ratio of mPPhen2P to Li₂O was 1:0.02.

The table below lists the structures of the light-emitting device 9B and the comparative light-emitting device 10B.

TABLE 11

| | | | | Comparative |
|---|---|---|---|---|
| | | | Light-emitting | light-emitting |
| | | Thickness | device 9B | device 10B |
| Cap layer | | 70 nm | DBT3P-II | |
| Second electrode | | 15 nm | Ag:Mg (1:0.1) | |
| Electron-injection | | 1.5 nm | LiF:Yb (1:0.5) | |
| layer | | | | |
| | | | Processing was performed by | |
| | | | photolithography method. | |
| Second | 2 | 20 nm | mPPhen2P | |
| electron- | 1 | 15 nm | βNP-SFx(4)Tzn | 2mPCCzPDBq |
| transport | | | | |
| layer | | | | |
| Second light- | | 25 nm | αN-βNPAnth: | |
| emitting layer | | | 3,10PCA2Nbf(IV)-02 | |
| | | | (1:0.015) | |
| Second | 2 | 10 nm | DBfBB1TP | |
| hole- | 1 | 35 nm | PCBBiF | |
| transport | | | | |
| layer | | | | |
| Intermediate | Second | 10 nm | PCBBiF:OCHD-003 (1:0.15) | |
| layer | layer | | | |
| | Third | 2 nm | CuPc | |
| | layer | | | |
| | First | 5 nm | mPPhen2P: | mPPhen2P: |
| | layer | | Pyrrd-Phen:In | Li₂O |
| | | | (0.5:0.5:0.02) | (1:0.02) |

| | | | |
|---|---|---|---|
| First electron- | 10 nm | βNP-SFx(4)Tzn | 2mPCCzPDBq |
| transport layer | | | |

| First light- | | 25 nm | αN-βNPAnth: |
|---|---|---|---|
| emitting layer | | | 3,10PCA2Nbf(IV)-02 |
| | | | (1:0.015) |
| First | 2 | 10 nm | DBfBB1TP |
| hole- | 1 | 70 nm | PCBBiF |
| transport | | | |
| layer | | | |
| Hole-injection layer | | 10 nm | PCBBiF:OCHD-003 (1:0.03) |
| First | 2 | 50 nm | ITSO |
| electrode | 1 | 100 nm | APC |

### (Method for Fabricating Comparative Light-Emitting Device 11G)

The comparative light-emitting device 11G is different from the comparative light-emitting device 10G in the structures of the first electrode, the first and second hole-transport layers, the first and second light-emitting layers, the first and third layers of the intermediate layer, the second electron-transport layer, and the cap layer. Note that the comparative light-emitting device 11G is different from the comparative light-emitting device 10G in the method for forming the organic compound layer through processing by a photolithography method and the method for the heat treatment.

Specifically, over a silicon substrate provided with a wiring, a 50-nm-thick titanium (Ti) layer, a 70-nm-thick aluminum (Al) layer, and a 6-nm-thick Ti layer were stacked in this order from the substrate side and then, baking was performed at 300° C. in the air for 1 hour. After that, a 10-nm-thick layer of indium tin oxide containing silicon oxide (ITSO) was stacked by a sputtering method. Then, processing by a lithography method was performed such that a resolution of 3207 ppi would be achieved; thus, the first electrodes were formed. Then, a film of SiON was formed, and a sidewall was formed using SiON to cover an end portion of the first electrode. Note that ITSO functions as an anode, and is regarded as the first electrode together with the above stacked-layer structure of Ti and Al.

Note that the first electrodes were formed to achieve matrix arrangement of 251×251=63001 pixels in an area of 2 mm×2 mm. This shape and arrangement correspond to a resolution of 3207 ppi.

Next, in pretreatment for forming the light-emitting devices over the substrate, the substrate was subjected to heat treatment at 120° C. for 120 seconds, 1,1,1,3,3,3-hexamethyldisilazane (abbreviation: HMDS) was then vaporized, and a spray thereof was given, for 120 seconds, to the substrate heated to 60° C. This can make it difficult for the stacked-layer film formed over the first electrodes to be separated from the first electrodes in the fabrication process.

After that, the substrate was transferred into a vacuum evaporation apparatus where the pressure had been reduced to approximately 1′10⁻⁴ Pa, and was subjected to vacuum baking at 170° C. for 60 minutes in a heating chamber of the vacuum evaporation apparatus, and then the substrate was cooled down for approximately 60 minutes.

Then, the substrate was fixed to a substrate holder provided in the vacuum evaporation apparatus such that the surface on which the first electrodes were formed faced downward. Over the first electrodes, PCBBiF and OCHD-003 were deposited by co-evaporation to a thickness of 10 nm such that the weight ratio of PCBBiF to OCHD-003 was 1:0.03, whereby the hole-injection layer was formed.

Over the hole-injection layer, PCBBiF was deposited by evaporation to a thickness of 35 nm, so that the first hole-transport layer was formed.

Then, over the first hole-transport layer, 8-(1,1′: 4′,1″-terphenyl-3-yl-2,4,5,6,2′,3′,5′,6′,2″,3″,4″,5″,6″-d₃)-4-[3-(dibenzothiophen-4-yl-1,2,3,6,7,8,9-d₇)phenyl-2,4,6-d₃]-[1]benzofuro[3,2-d]pyrimidine (abbreviation: 8mpTP-4mDBtPBfpm-d₂₃), βNCCP, and tris{2-[5-(methyl-d₃)-4-phenyl-2-pyridinyl-κN]phenyl-κC}iridium(III) (abbreviation: Ir(5m4dppy-d₃)₃) were deposited by co-evaporation to a thickness of 40 nm such that the weight ratio of 8mpTP-4mDBtPBfpm-d₂₃ to βNCCP to Ir(5m4dppy-d₃)₃ was 0.5:0.5:0.1, whereby the first light-emitting layer was formed.

After that, 2mPCCzPDBq was deposited by evaporation to a thickness of 10 nm, so that the first electron-transport layer was formed.

After the formation of the first electron-transport layer, mPPhen2P and Li₂O were deposited by co-evaporation to a thickness of 5 nm such that the volume ratio of mPPhen2P to Li₂O was 1:0.01, whereby the first layer of the intermediate layer was formed.

Then, a film of zinc phthalocyanine (abbreviation: ZnPc) was formed to have a thickness of 2 nm, so that the third layer of the intermediate layer was formed.

Furthermore, PCBBiF and OCHD-003 were deposited by co-evaporation to a thickness of 10 nm such that the weight ratio of PCBBiF to OCHD-003 was 1:0.15, whereby the second layer of the intermediate layer was formed.

Next, over the intermediate layer, PCBBiF was deposited by evaporation to a thickness of 55 nm, so that the second hole-transport layer was formed.

Over the second hole-transport layer, 8mpTP-4mDBtPBfpm-d₂₃, βNCCP, and Ir(5m4dppy-d₃)₃ were deposited by co-evaporation to a thickness of 40 nm such that the weight ratio of 8mpTP-4mDBtPBfpm-d₂₃ to βNCCP to Ir(5m4dppy-d₃)₃ was 0.5:0.5:0.1, whereby the second light-emitting layer was formed.

After that, 2mPCCzPDBq was deposited by evaporation to a thickness of 10 nm and mPPhen2P was further deposited by evaporation to a thickness of 15 nm, so that the second electron-transport layer was formed.

After the formation of the second electron-transport layer, processing by a photolithography method and heat treatment were performed.

### <<Processing by Photolithography Method and Heat Treatment 3>>

The substrate over which the second electron-transport layer and the components thereunder had been formed was taken out from the vacuum evaporation apparatus and exposed to the air, and then aluminum oxide was deposited to a thickness of 30 nm by an ALD method using trimethylaluminum (abbreviation: TMA) as a precursor and water vapor as an oxidizer to form the first sacrificial layer.

Next, over the first sacrificial layer, tungsten (W) was deposited to a thickness of 54 nm by a sputtering method to form the second sacrificial layer.

A photoresist was applied onto the second sacrificial layer, light exposure and development were performed, and processing was performed such that an end portion of the second sacrificial layer was located inward from the end surface of the first electrode. This makes it possible that the organic compound layer of the comparative light-emitting device 11G is formed by processing to have a shape such that an end portion of the organic compound layer is located inward from the end surface of the first electrode.

The second sacrificial layer was processed using an etching gas containing SF₆ with the use of the photoresist as a mask and then, the first sacrificial layer was processed using an etching gas containing fluoroform (CHF₃), helium (He), and methane (CH₄) at a flow rate ratio of CHF₃:He:CH₄=16.5:118.5:15 with the use of the second sacrificial layer as a hard mask. Then, the hole-injection layer, the first hole-transport layer, the first light-emitting layer, the first electron-transport layer, the intermediate layer, the second hole-transport layer, the second light-emitting layer, and the second electron-transport layer were processed using an etching gas containing oxygen (O₂).

After the organic compound layer was formed by the processing, the second sacrificial layer was removed using an etching gas containing SF₆, whereas the first sacrificial layer was left. Then, aluminum oxide was deposited to a thickness of 15 nm by an ALD method, so that a protective film was formed.

Next, layers of a photosensitive high molecular material were formed over the protective film to overlap with the first electrodes by a photolithography method. After heating was performed at 100° C. in an air atmosphere for 1 hour, unnecessary portions of the first sacrificial layer and the protective film were removed using a mixed acid aqueous solution containing hydrofluoric acid (HF), so that the second electron-transport layers were exposed. At this time, the layers of the photosensitive high molecular material function as resists.

The substrate, over which the second electron-transport layers were exposed, was transferred into a vacuum evaporation apparatus where the pressure had been reduced to approximately 1′10⁻⁴ Pa, and was subjected to vacuum baking at 100° C. for 90 minutes in a heating chamber of the vacuum evaporation apparatus.

Subsequently, lithium fluoride (LiF) and ytterbium (Yb) were deposited by co-evaporation to a thickness of 1.5 nm such that the volume ratio of LiF to Yb was 1:0.5 to form the electron-injection layer, and then, silver (Ag) and magnesium (Mg) were deposited by co-evaporation to a thickness of 15 nm such that the volume ratio of Ag to Mg was 1:0.1 to form the second electrode. As the cap layer, ITO (indium oxide-tin oxide) was deposited over the second electrode to a thickness of 70 nm by a sputtering method.

### (Method for Fabricating Comparative Light-Emitting Device 11R)

The comparative light-emitting device 11R is different from the comparative light-emitting device 11G in the structures of the first and second light-emitting layers and the cap layer and the thicknesses of the first hole-transport layer, the second hole-transport layer, and the second electron-transport layer; the other components were formed in the same manner as those in the comparative light-emitting device 11G. Specifically, to form each of the first and second light-emitting layers of the comparative light-emitting device 11R, 11mDBtBPPnfpr, PCBBiF, and OCPG-006 as a material emitting red phosphorescent light were deposited by co-evaporation to a thickness of 40 nm such that the weight ratio of 11mDBtBPPnfpr to PCBBiF to OCPG-006 was 0.7:0.3:0.05. To form the cap layer of the comparative light-emitting device 11R, PCBBiF was deposited by evaporation to a thickness of 80 nm. In the comparative light-emitting device 11R, the thickness of the first hole-transport layer was 60 nm, the thickness of the second hole-transport layer was 65 nm, the thickness of the 2mPCCzPDBq layer of the second electron-transport layer was 20 nm, and the thickness of the mPPhen2P layer of the second electron-transport layer was 25 nm.

### (Method for Fabricating Comparative Light-Emitting Device 11B)

The comparative light-emitting device 11B is different from the comparative light-emitting device 11G in the structures of the first hole-transport layer, the first light-emitting layer, the third layer of the intermediate layer, the second hole-transport layer, and the second light-emitting layer; the other components were formed in the same manner as those in the comparative light-emitting device 11G. Specifically, to form the first hole-transport layer of the comparative light-emitting device 11B, PCBBiF was deposited by evaporation to a thickness of 10 nm and then, DBfBB1TP was deposited by evaporation to a thickness of 10 nm. To form each of the first and second light-emitting layers of the comparative light-emitting device 11B, αN-βNPAnth and 3,10PCA2Nbf(IV)-02 were deposited by co-evaporation to a thickness of 25 nm such that the weight ratio of αN-βNPAnth to 3,10PCA2Nbf(IV)-02 was 1:0.015. As the third layer of the intermediate layer of the comparative light-emitting device 11B, a film of CuPc was formed to have a thickness of 2 nm. To form the second hole-transport layer of the comparative light-emitting device 11B, PCBBiF was deposited by evaporation to a thickness of 30 nm and then, DBfBB1TP was deposited by evaporation to a thickness of 10 nm.

The table below lists the structures of the comparative light-emitting devices 11G, 11R, and 11B.

TABLE 12

| | | | Comparative | Comparative | Comparative |
|---|---|---|---|---|---|
| | | Thickness | light-emitting | light-emitting | light-emitting |
| | | (nm) | device 11G | device 11R | device 11B |
| Cap layer | | — | ITO (70 nm) | PCBBiF (80 nm) | ITO (70 nm) |
| Second electrode | | 15 | Ag:Mg (1:0.1) | | |
| Electron-injection | | 1.5 | LiF:Yb (1:0.5) | | |
| layer | | | | | |
| | | | Processing was performed by photolithography method. | | |
| Second electron- | 2 | — | mPPhen2P (15 nm) | mPPhen2P (25 nm) | mPPhen2P (15 nm) |
| transport layer | 1 | — | 2mPCCzPDBq (10 nm) | 2mPCCzPDBq (20 nm) | 2mPCCzPDBq (10 nm) |
| Second light-emitting | | — | 8mpTP-4mDBtPBfpm-d₂₃: | 11mDBtBPPnfpr: | αN-βNPAnth: |
| layer | | | βNCCP:Ir(5m4dppy-d₃)₃ | PCBBiF:OCPG-006 | 3,10PCA2Nbf(IV)-02 |
| | | | (40 nm) (0.5:0.5:0.1) | (0.7:0.3:0.05) (40 nm) | (1:0.015) (25 nm) |
| Second hole- | 2 | — | PCBBiF (55 nm) | PCBBiF (65 nm) | DBfBB1TP (10 nm) |
| transport layer | 1 | — | | | PCBBiF (30 nm) |
| Intermediate | 2 | 10 | PCBBiF:OCHD-003 (1:0.15) | | |
| layer | 3 | 2 | ZnPc | | CuPc |
| | 1 | 5 | mPPhen2P:Li₂O (1:0.01) | | |
| First electron- | | 10 | 2mPCCzPDBq | | |
| transport layer | | | | | |
| First light-emitting | | 1 | 8mpTP-4mDBtPBfpm-d₂₃: | 11mDBtBPPnfpr: | αN-βNPAnth: |
| layer | | | βNCCP:Ir(5m4dppy-d₃)₃ | PCBBiF:OCPG-006 | 3,10PCA2Nbf(IV)-02 |
| | | | (0.5:0.5:0.1) (40 nm) | (0.7:0.3:0.05) (40 nm) | (1:0.015) (25 nm) |
| First hole- | 2 | — | PCBBiF (35 nm) | PCBBiF (60 nm) | DBfBB1TP (10 nm) |
| transport layer | 1 | — | | | PCBBiF (10 nm) |

| Hole-injection layer | | 10 | PCBBiF:OCHD-003 (1:0.03) |
|---|---|---|---|
| First electrode | 4 | 10 | ITSO |
| | 3 | 6 | Ti |
| | 2 | 70 | Al |
| | 1 | 50 | Ti |

The light-emitting devices fabricated were sealed using a glass substrate in a glove box containing a nitrogen atmosphere so as not to be exposed to the air. Specifically, a UV curable sealing material was applied to surround the devices, only the sealing material was irradiated with UV while the light-emitting devices were not irradiated with the UV, and heat treatment was performed at 80° C. under an atmospheric pressure for 1 hour. Then, the initial characteristics of the light-emitting devices were measured.

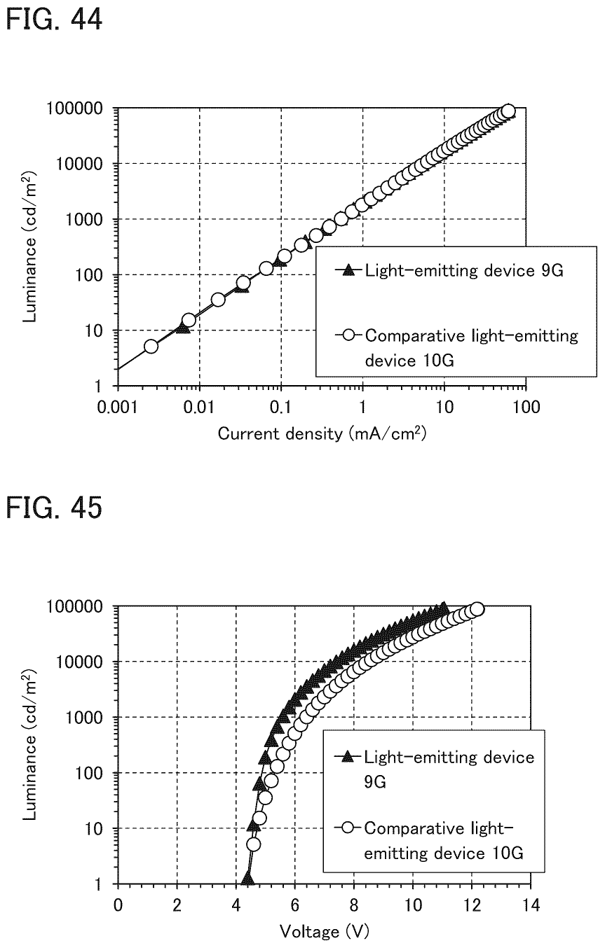

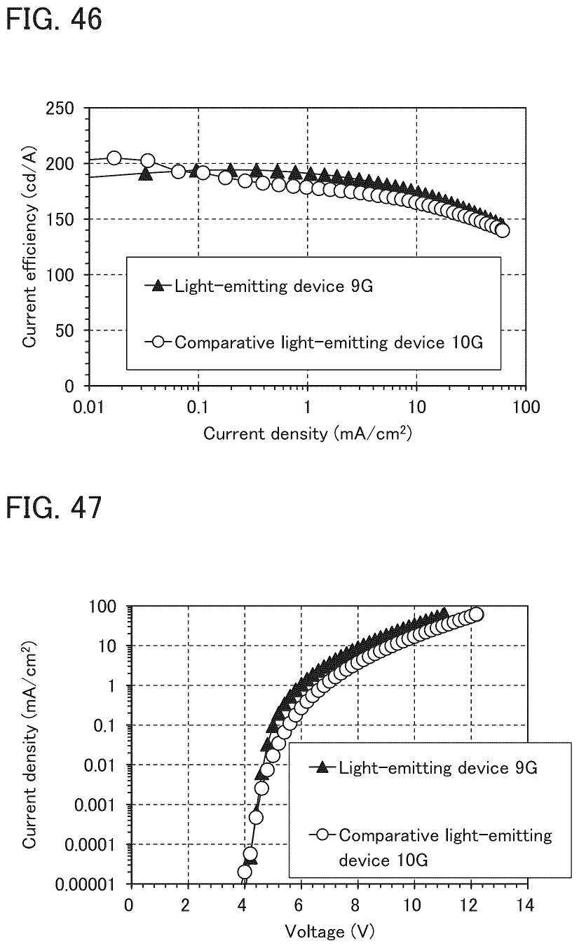

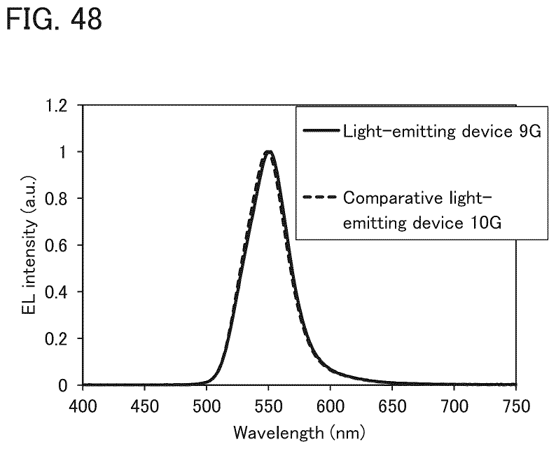

FIG. 44 shows the luminance-current density characteristics of the light-emitting device 9G and the comparative light-emitting device 10G, FIG. 45 shows the luminance-voltage characteristics thereof, FIG. 46 shows the current efficiency-current density characteristics thereof, FIG. 47 shows the current density-voltage characteristics thereof, and FIG. 48 shows the electroluminescence spectra thereof.

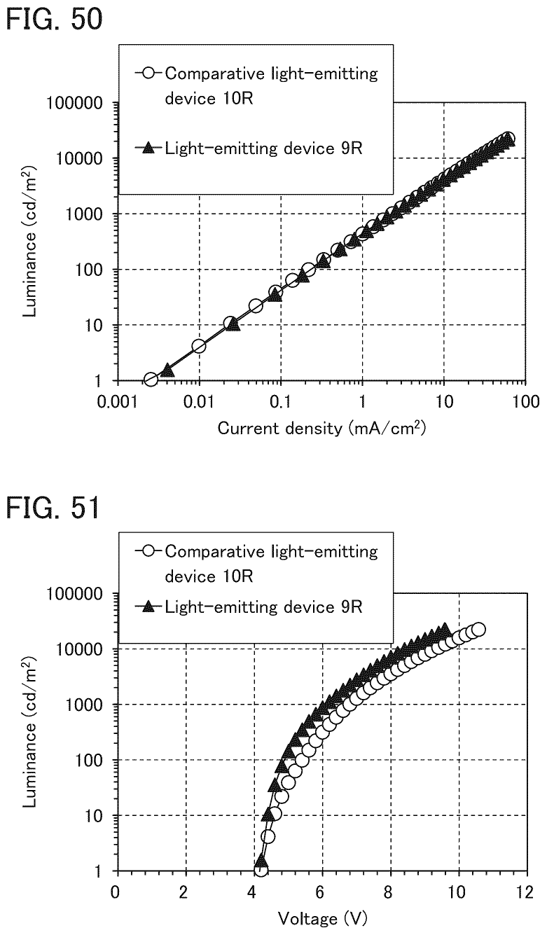

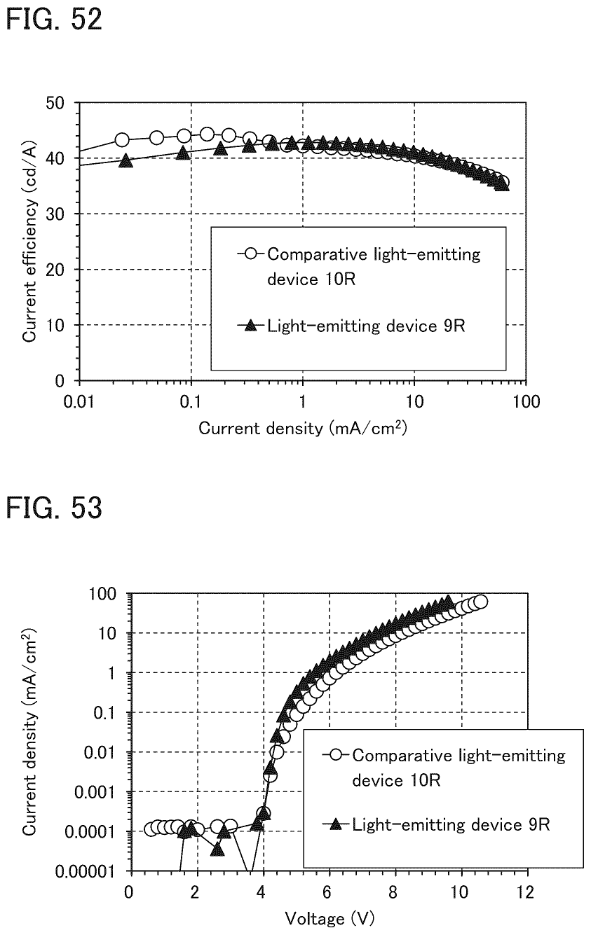

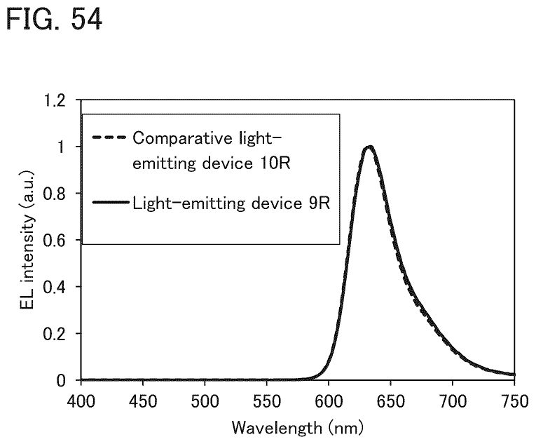

FIG. 50 shows the luminance-current density characteristics of the light-emitting device 9R and the comparative light-emitting device 10R, FIG. 51 shows the luminance-voltage characteristics thereof, FIG. 52 shows the current efficiency-current density characteristics thereof, FIG. 53 shows the current density-voltage characteristics thereof, and FIG. 54 shows the electroluminescence spectra thereof.

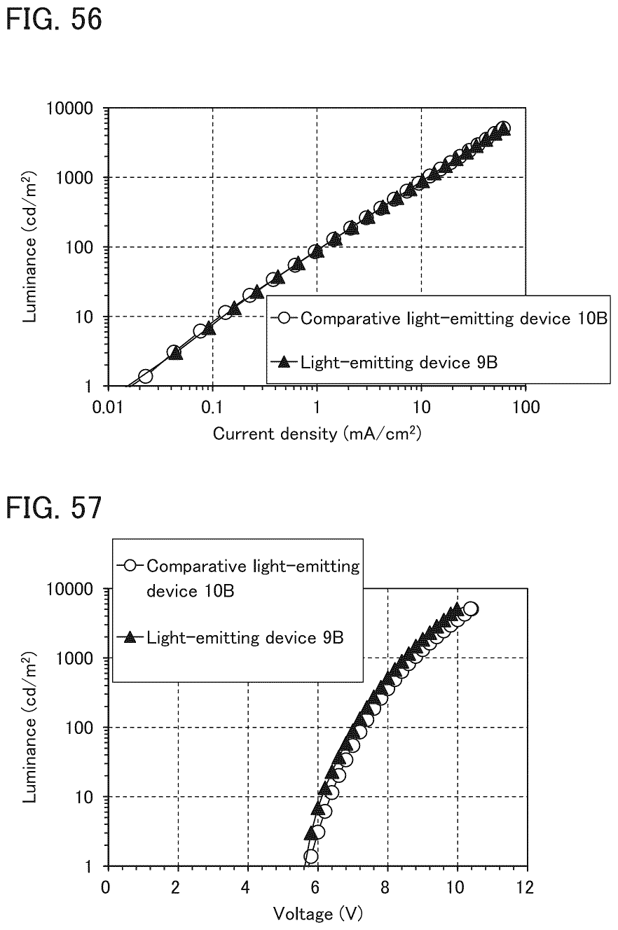

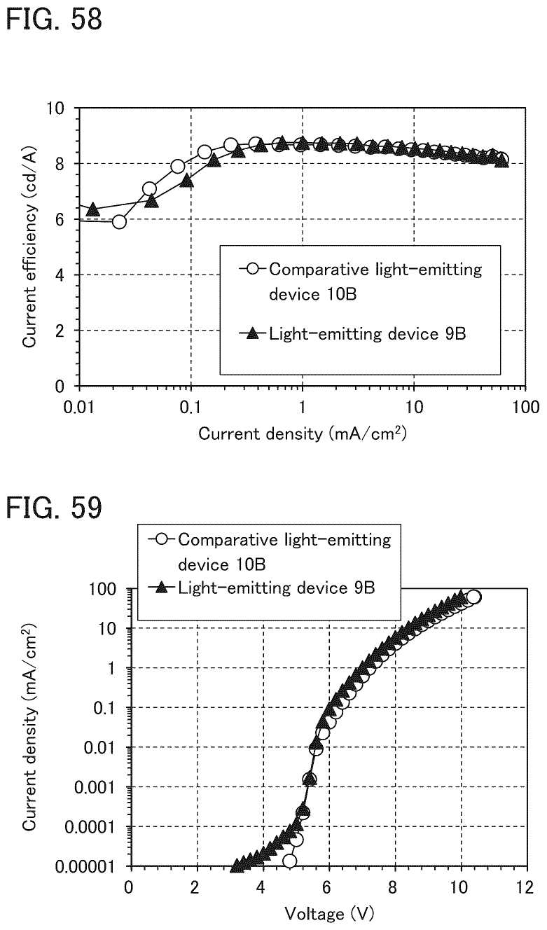

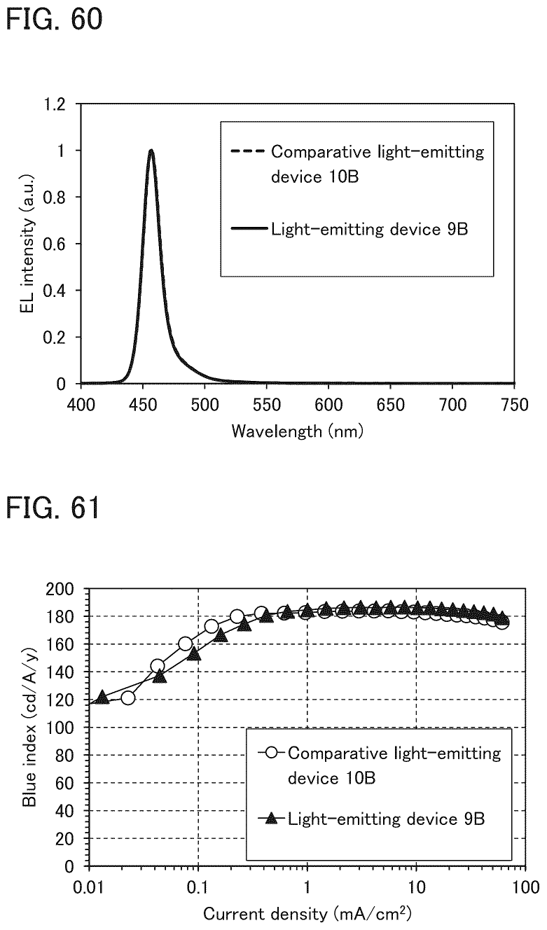

FIG. 56 shows the luminance-current density characteristics of the light-emitting device 9B and the comparative light-emitting device 10B, FIG. 57 shows the luminance-voltage characteristics thereof, FIG. 58 shows the current efficiency-current density characteristics thereof, FIG. 59 shows the current density-voltage characteristics thereof, FIG. 60 shows the electroluminescence spectra thereof, and FIG. 61 shows the blue index-current density characteristics thereof.

Note that the blue index (BI) is a value obtained by dividing current efficiency (cd/A) by the y value of CIE chromaticity (x, y), and is one of the indicators of characteristics of blue light emission. As the y chromaticity value of blue light emission becomes smaller, the color purity thereof tends to be higher. Blue light emission having a small y chromaticity value and high color purity enables expression of blue colors with a wide range of chromaticity in a display. Using blue light emission with high color purity reduces the luminance of light emission necessary for a display to express white, leading to lower power consumption of the display. Thus, BI, which is current efficiency based on a y chromaticity value as one of the indicators of color purity of blue, is suitably used as a means for showing efficiency of blue light emission. The light-emitting device with higher BI can be regarded as a blue-light-emitting device having higher efficiency for a display.

The table below shows the main characteristics of the light-emitting devices 9G, 9R, and 9B and the comparative light-emitting devices 10G, 10R, and 10B at a luminance of approximately 1000 cd/m². The luminance, CIE chromaticity, and electroluminescence spectra were measured at normal temperature with a spectroradiometer (SR-UL1R manufactured by TOPCON TECHNOHOUSE CORPORATION).

TABLE 13

| | | | Current | | | | Current | |
|---|---|---|---|---|---|---|---|---|
| | Voltage | Current | density | Chromaticity | Chromaticity | Luminance | efficiency | BI value |
| | (V) | (mA) | (mA/cm²) | x | y | (cd/m²) | (cd/A) | (cd/A/y) |
| Light-emitting device 9G | 5.6 | 0.0087 | 0.53 | 0.34 | 0.65 | 1045 | 193 | — |
| Comparative light-emitting device 10G | 6.4 | 0.0089 | 0.55 | 0.33 | 0.65 | 1006 | 181 | — |
| Light-emitting device 9R | 6.0 | 0.033 | 2.0 | 0.70 | 0.30 | 870 | 43 | — |
| Comparative light-emitting device 10R | 6.8 | 0.038 | 2.3 | 0.70 | 0.30 | 997 | 42 | — |
| Light-emitting device 9B | 8.4 | 0.17 | 10 | 0.15 | 0.046 | 894 | 8.5 | 186 |
| Comparative light-emitting device 10B | 8.8 | 0.20 | 12 | 0.15 | 0.046 | 1045 | 8.5 | 182 |

FIGS. 44 to 48 and the above table reveal that the light-emitting device 9G exhibits green light emission derived from Ir(5mppy-d₃)₂(mbfpypy-d₃) and has favorable emission characteristics. It is also found that the light-emitting device 9G has a lower driving voltage and higher current efficiency than the comparative light-emitting device 10G.

FIGS. 50 to 54 and the above table reveal that the light-emitting device 9R exhibits red light emission derived from OCPG-006 and has favorable emission characteristics. It is also found that the light-emitting device 9R has a lower driving voltage than the comparative light-emitting device 10R.

FIGS. 56 to 61 and the above table reveal that the light-emitting device 9B exhibits blue light emission derived from 3,10PCA2Nbf(IV)-02 and has favorable emission characteristics. It is also found that the light-emitting device 9B has a lower driving voltage than the comparative light-emitting device 10B.

The light-emitting devices 9G, 9R, and 9B of embodiments of the present invention respectively had more favorable characteristics than the comparative light-emitting devices 10G, 10R, and 10B as described above because the light-emitting devices 9G, 9R, and 9B suffered from little variation in characteristics regardless of having undergone the process of forming the organic compound layer through processing by a photolithography method, whereas the comparative light-emitting devices 10G, 10R, and 10B, in each of which the first layer of the intermediate layer included lithium, suffered from a variation in characteristics by having undergone the process of forming the organic compound layer through processing by a photolithography method.

On the assumption that pixels of a display apparatus with a resolution of 508 ppi are fabricated using the light-emitting devices 9G, 9R, and 9B, the characteristics of the display apparatus were calculated. The diagonal size of the display apparatus is 1.5 inches, and G, R and B pixels have aperture ratios of 34.7%, 12.4%, and 21.7%, respectively. The power consumption of the display apparatus is 231 mW/cm² when the display apparatus performs D65 white display at a luminance of 15000 cd/m² on the entire screen. At this time, the current density is 20 mA/cm², 50 mA/cm², and 50 mA/cm² in the G pixel, the R pixel, and the B pixel, respectively. The power consumption of a similar display apparatus whose pixels include the comparative light-emitting devices 10G, 10R, and 10B is 260 mW/cm² when the display apparatus performs D65 white display at a luminance of 15000 cd/m² on the entire screen. That is, a display apparatus can have low power consumption by including the light-emitting devices of embodiments of the present invention.

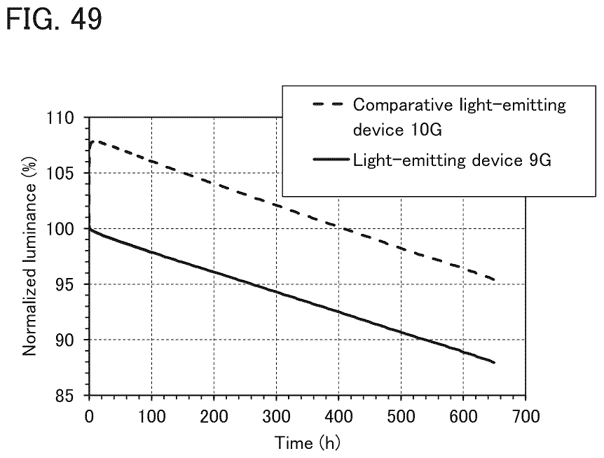

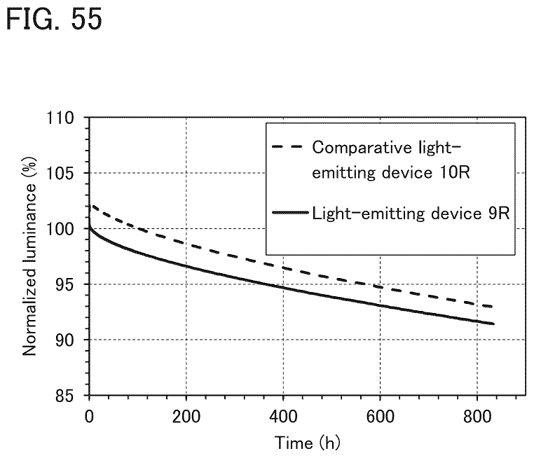

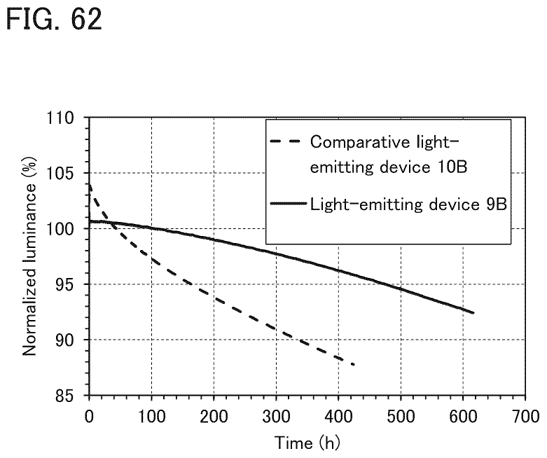

Reliability tests were performed under the above-described driving conditions of the display apparatuses. FIG. 49 is a graph showing driving time-dependent changes in luminance of the light-emitting device 9G and the comparative light-emitting device 10G driven by a constant current at 20 mA/cm²; FIG. 55 is a graph showing driving time-dependent changes in luminance of the light-emitting device 9R and the comparative light-emitting device 10R driven by a constant current at 50 mA/cm²; and FIG. 62 is a graph showing driving time-dependent changes in luminance of the light-emitting device 9B and the comparative light-emitting device 10B driven by a constant current at 50 mA/cm².

FIG. 49, FIG. 55, and FIG. 62 show that the 5% luminance decay times of the light-emitting devices 9G, 9R, and 9B are longer than or equal to 200 hours, which means excellent reliability of these light-emitting devices. It was also found that the comparative light-emitting devices 10G, 10R, and 10B exhibited a phenomenon in which the luminance abruptly increased at the beginning of the driving and then decreased, i.e., unstable behavior, whereas the light-emitting devices 9G, 9R, and 9B exhibited a behavior in which the luminance gradually decreased from the beginning of the driving, which means that the light-emitting devices 9G, 9R, and 9B were stably driven. FIG. 62 shows that the light-emitting device 9B suffers from a smaller change in luminance and has a longer lifetime than the comparative light-emitting device 10B.

The above results show that the light-emitting devices of embodiments of the present invention have favorable characteristics and particularly, a low driving voltage and high emission efficiency.

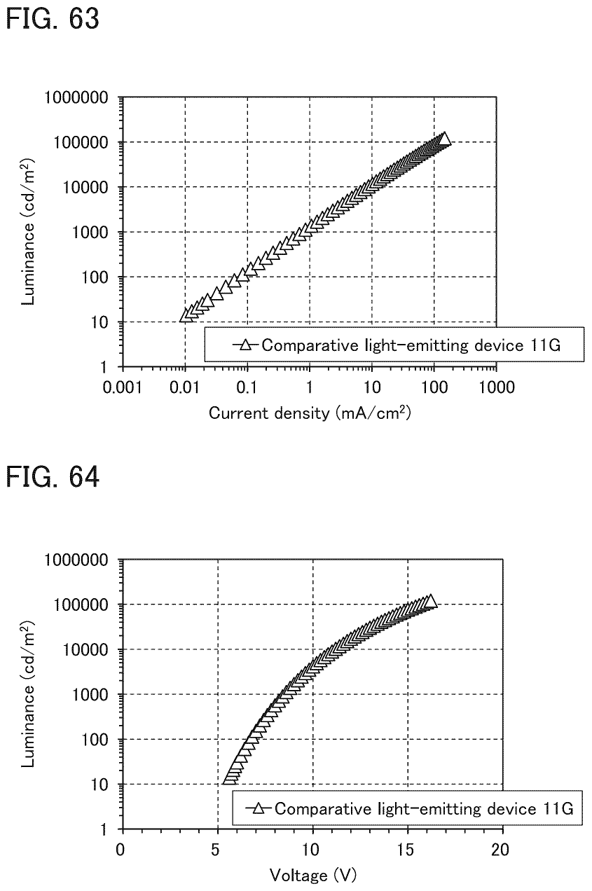

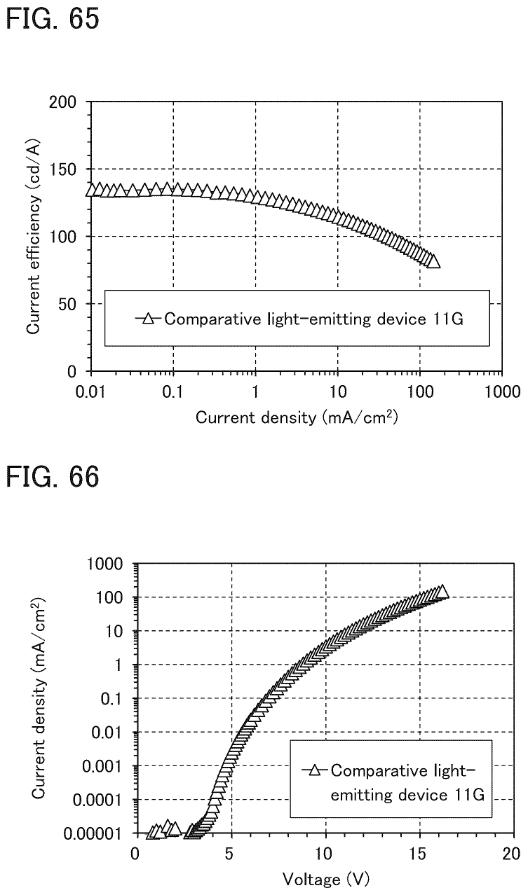

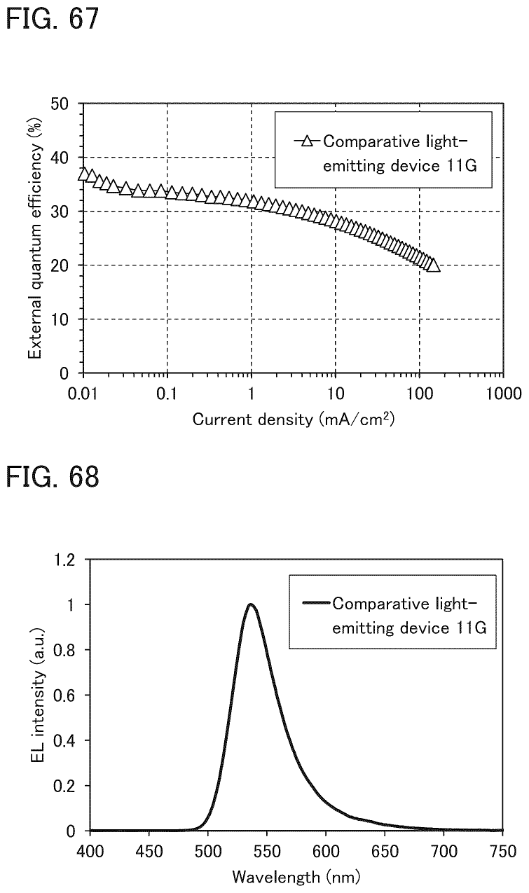

Next, FIG. 63 shows the luminance-current density characteristics of the comparative light-emitting device 11G, FIG. 64 shows the luminance-voltage characteristics thereof, FIG. 65 shows the current efficiency-current density characteristics thereof, FIG. 66 shows the current density-voltage characteristics thereof, FIG. 67 shows the external quantum efficiency-current density characteristics thereof, and FIG. 68 shows the electroluminescence spectrum thereof.

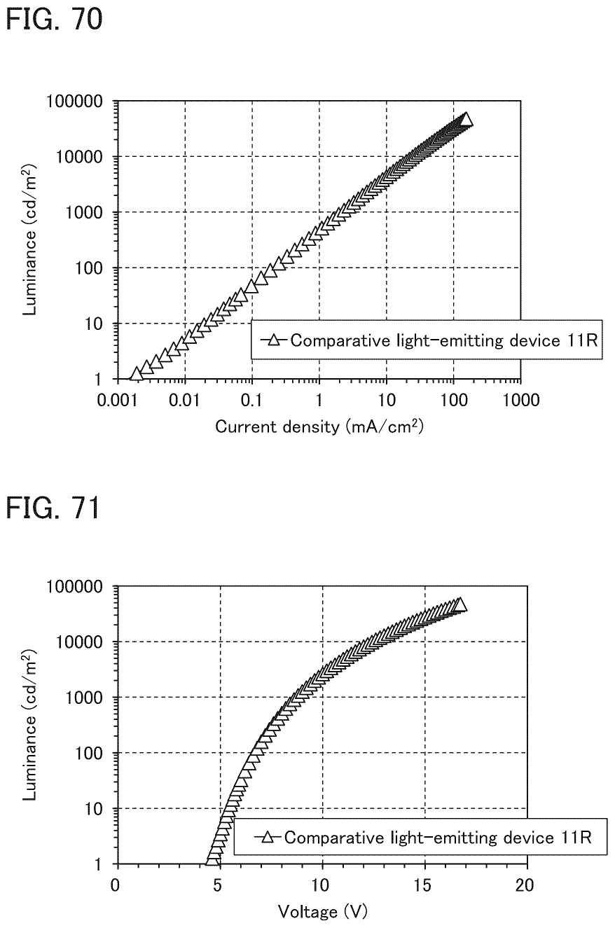

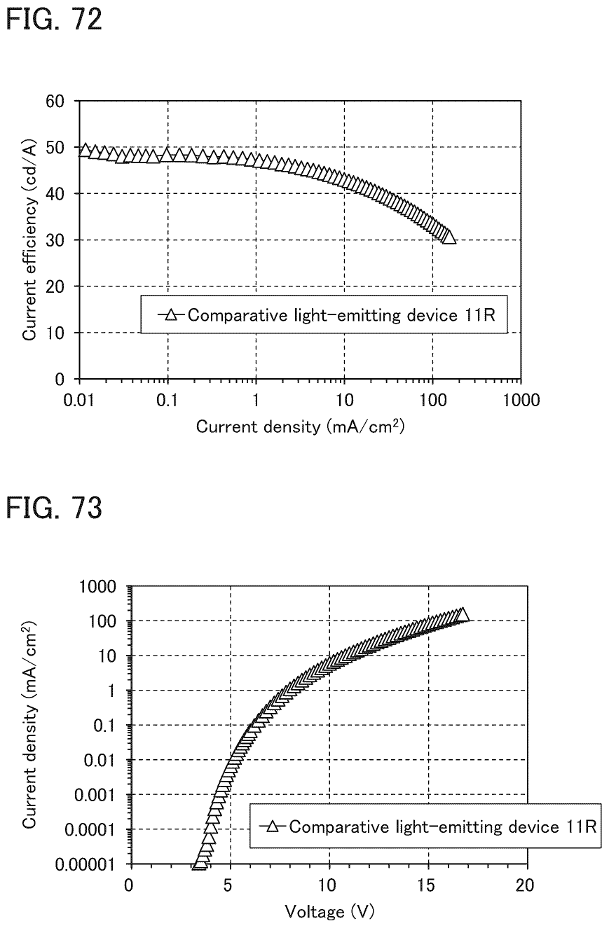

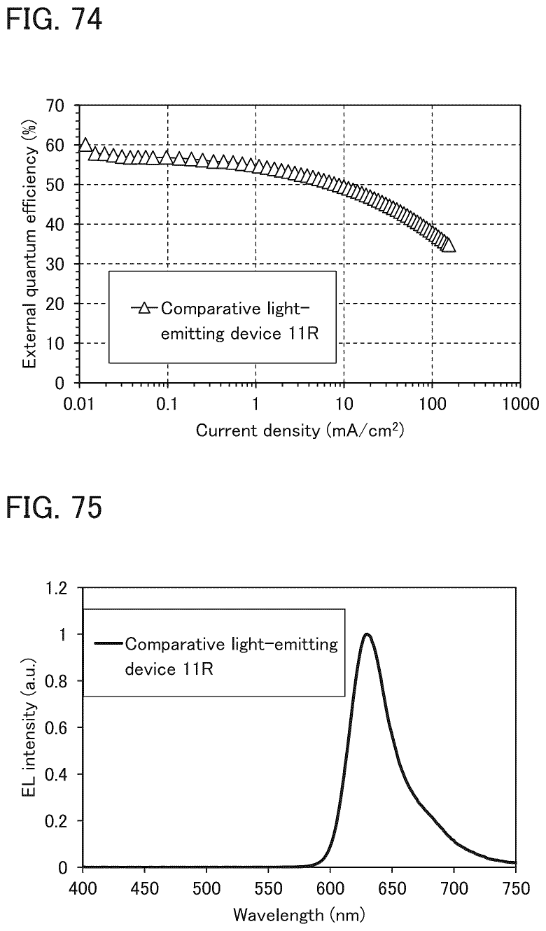

FIG. 70 shows the luminance-current density characteristics of the comparative light-emitting device 11R, FIG. 71 shows the luminance-voltage characteristics thereof, FIG. 72 shows the current efficiency-current density characteristics thereof, FIG. 73 shows the current density-voltage characteristics thereof, FIG. 74 shows the external quantum efficiency-current density characteristics thereof, and FIG. 75 shows the electroluminescence spectrum thereof.

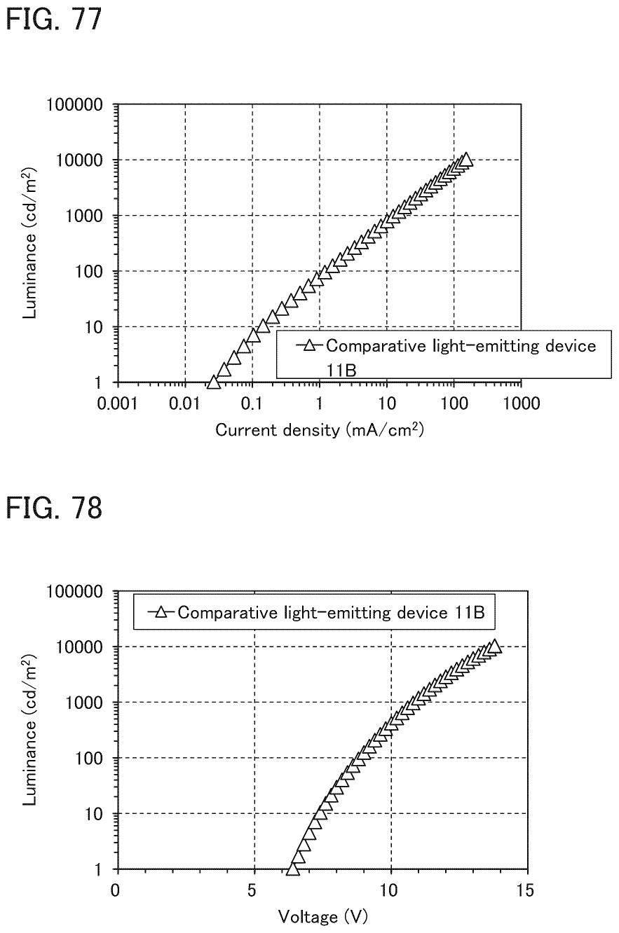

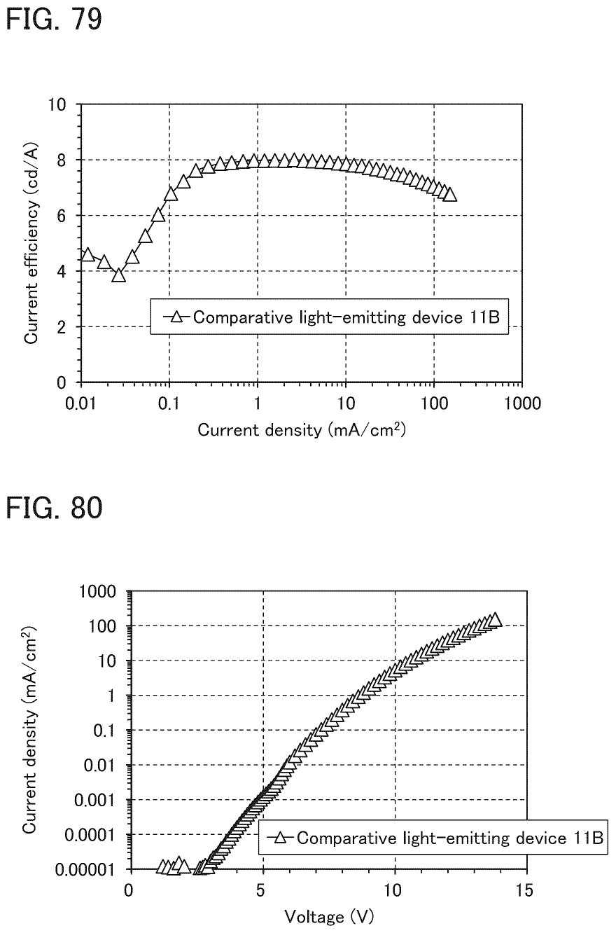

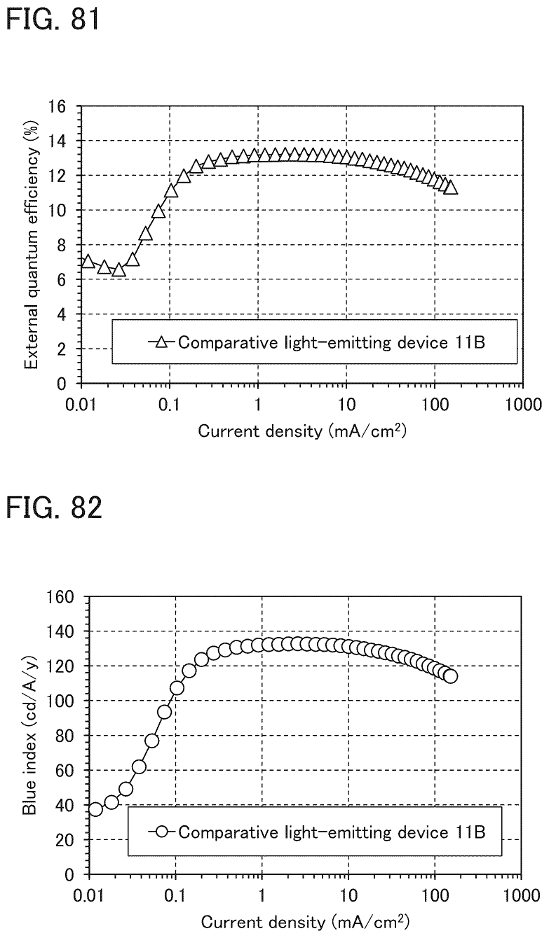

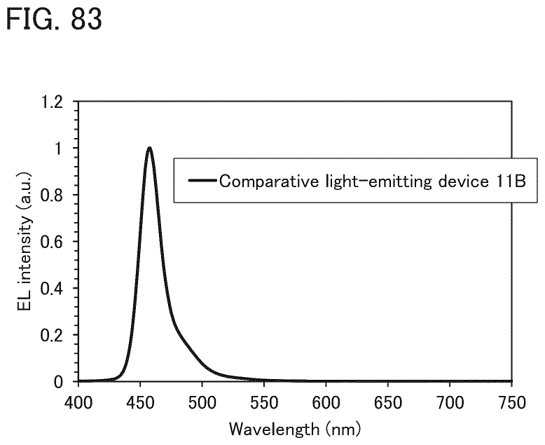

FIG. 77 shows the luminance-current density characteristics of the comparative light-emitting device 11B, FIG. 78 shows the luminance-voltage characteristics thereof, FIG. 79 shows the current efficiency-current density characteristics thereof, FIG. 80 shows the current density-voltage characteristics thereof, FIG. 81 shows the external quantum efficiency-current density characteristics thereof, FIG. 82 shows the blue index-current density characteristics thereof, and FIG. 83 shows the electroluminescence spectrum thereof.

The table below shows the main characteristics of the comparative light-emitting devices 11G, 11R, and 11B at a luminance of approximately 1000 cd/m². The luminance, CIE chromaticity, and electroluminescence spectra were measured at normal temperature with a spectroradiometer (SR-UL1R manufactured by TOPCON TECHNOHOUSE CORPORATION). The external quantum efficiency was calculated from the luminance and the electroluminescence spectra measured with the spectroradiometer, on the assumption that the devices had Lambertian light-distribution characteristics.

TABLE 14

| | | | Current | | | | Current | |
|---|---|---|---|---|---|---|---|---|
| | Voltage | Current | density | Chromaticity | Chromaticity | Luminance | efficiency | BI value |
| | (V) | (mA) | (mA/cm²) | x | y | (cd/m²) | (cd/A) | (cd/A/y) |
| Comparative light-emitting device 11G | 8.6 | 0.0029 | 0.86 | 0.32 | 0.65 | 1114 | 130 | — |
| Comparative light-emitting device 11R | 8.8 | 0.0076 | 2.3 | 0.70 | 0.30 | 1075 | 46 | — |
| Comparative light-emitting device 11B | 10.8 | 0.041 | 12 | 0.14 | 0.060 | 969 | 7.8 | 131 |

On the assumption that pixels of a display apparatus with a resolution of 3207 ppi are fabricated using the comparative light-emitting devices 11G, 11R, and 11B, the characteristics of the display apparatus were calculated. The diagonal size of the display apparatus is 1.5 inches, and G, R and B pixels have aperture ratios of 22.9%, 10.7%, and 31.4%, respectively. When the display apparatus performs D65 white display at a luminance of 15000 cd/m² on the entire screen, the current density is 50 mA/cm², 70 mA/cm², and 50 mA/cm² in the G pixel, the R pixel, and the B pixel, respectively.

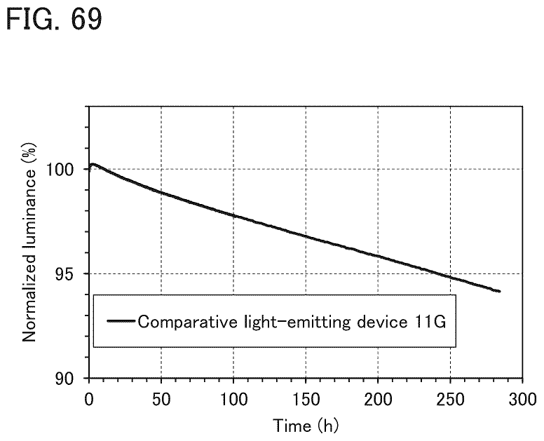

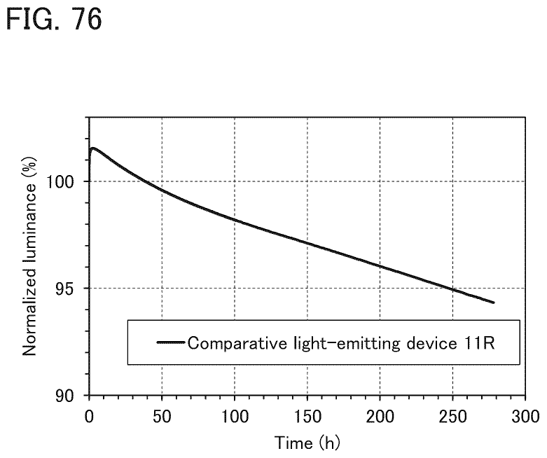

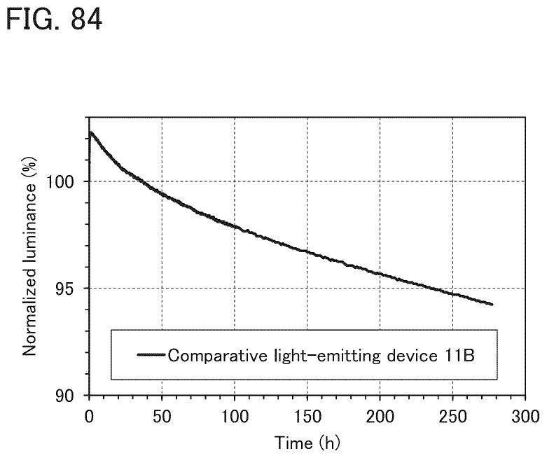

Reliability tests were performed under the above-described driving conditions of the display apparatus. FIG. 69 is a graph showing a driving time-dependent change in luminance of the comparative light-emitting device 11G driven by a constant current at 50 mA/cm²; FIG. 76 is a graph showing a driving time-dependent change in luminance of the comparative light-emitting device 11R driven by a constant current at 70 mA/cm²; and FIG. 84 is a graph showing a driving time-dependent change in luminance of the comparative light-emitting device 11B driven by a constant current at 50 mA/cm².

FIG. 69, FIG. 76, and FIG. 84 show that the comparative light-emitting devices 11G, 11R, and 11B exhibited a phenomenon in which the luminance abruptly increased at the beginning of the driving and then decreased, i.e., unstable behavior.

### Example 5

In this example, a light-emitting device 12 of one embodiment of the present invention and comparative light-emitting devices 13 and 14 are described. Note that in fabrication of the light-emitting device 12 and the comparative light-emitting devices 13 and 14, the processing by a photolithography method for forming the organic compound layer was replaced with air exposure. The structural formulae of the organic compounds used in the light-emitting device 12 and the comparative light-emitting devices 13 and 14 are shown below.

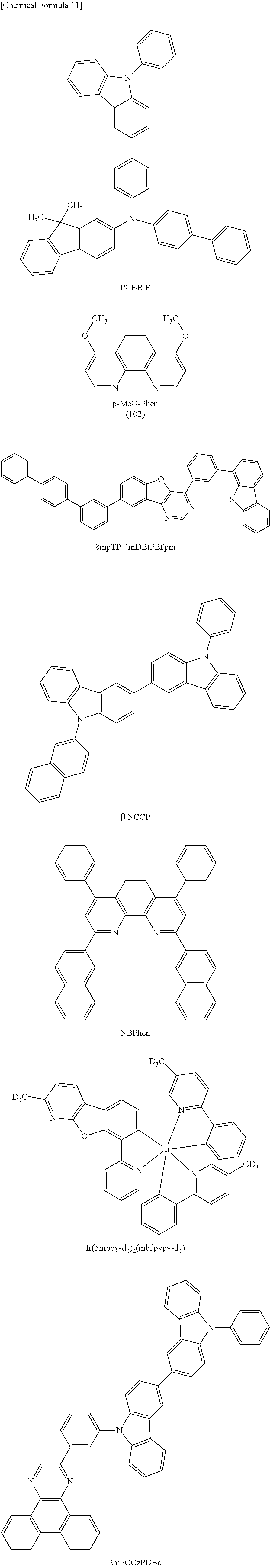

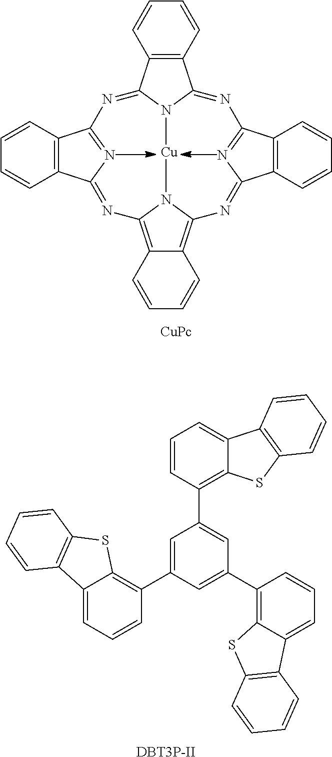

### (Method for Fabricating Light-Emitting Device 12)

The light-emitting device 12 is different from the light-emitting device 1 in the methods for forming the first electrode, the first hole-transport layer, the first layer of the intermediate layer, and the second hole-transport layer, and the step of the processing for forming the organic compound layer. Specifically, the first electrode of the light-emitting device 12 was formed in the following manner: as a reflective electrode, silver (Ag) was deposited over a glass substrate to a thickness of 100 nm by a sputtering method, and then, as a transparent electrode, indium tin oxide containing silicon oxide (JTSO) was deposited to a thickness of 85 nm by a sputtering method. To form the first hole-transport layer of the light-emitting device 12, PCBBiF was deposited by evaporation to a thickness of 85 nm over the hole-injection layer. To form the first layer of the intermediate layer of the light-emitting device 12, 2,9-di(naphthalen-2-yl)-4,7-diphenyl-1,10-phenanthroline (abbreviation: NBPhen), 4,7-dimethoxy-1,10-phenanthroline (abbreviation: p-MeO-Phen) (Structural Formula (102)) as an organic compound containing a phenanthroline ring with an electron-donating group, and indium (In) were deposited by co-evaporation to a thickness of 5 nm such that the volume ratio of NBPhen to p-MeO-Phen to In was 0.5:0.5:0.05, after the formation of the first electron-transport layer. To form the second hole-transport layer of the light-emitting device 12, PCBBiF was deposited by evaporation to a thickness of 50 nm over the second layer of the intermediate layer.

The light-emitting device 12 underwent the air exposure instead of the processing by a photolithography method for forming the organic compound layer. Specifically, after the formation of the second electron-transport layer, the substrate was taken out of the vacuum evaporation apparatus to be exposed to the air, and the substrate was held for 1 hour in a state of being exposed to the air. After that, the substrate was transferred into the vacuum evaporation apparatus, heating was performed at 80° C. in a vacuum atmosphere for 1 hour and then, the electron-injection layer was formed as in the light-emitting device 1.

The other components of the light-emitting device 12 were formed in the same manner as those in the light-emitting device 1.

### (Method for Fabricating Comparative Light-Emitting Device 13)

The comparative light-emitting device 13 is different from the light-emitting device 12 in that to form the first layer of the intermediate layer, p-MeO-Phen (Structural Formula (102)) and indium (In) were deposited by co-evaporation to a thickness of 5 nm such that the volume ratio of p-MeO-Phen to In was 1.0:0.05. The other components were formed in the same manner as those in the light-emitting device 12.

### (Method for Fabricating Comparative Light-Emitting Device 14)

The comparative light-emitting device 14 is different from the light-emitting device 12 in that to form the first layer of the intermediate layer, p-MeO-Phen (Structural Formula (102)) and lithium oxide (Li₂O) were deposited by co-evaporation to a thickness of 5 nm such that the volume ratio of p-MeO-Phen to Li₂O was 1.0:0.02. The other components were formed in the same manner as those in the light-emitting device 12.

The table below lists the structures of the light-emitting device 12 and the comparative light-emitting devices 13 and 14.

TABLE 15

| | | | |
|---|---|---|---|
| | Light- | Comparative | Comparative |
| | emitting | light-emitting | light-emitting |
| Thickness | device 12 | device 13 | device 14 |

| | | |
|---|---|---|
| Cap layer | 70 nm | DBT3P-II |
| Second electrode | 15 nm | Ag:Mg (1:0.1) |
| Electron-injection layer | 1.5 nm | LiF:Yb (1:0.5) |

Air exposure was performed.

| Second electron- | 2 | 20 nm | mPPhen2P | | |
|---|---|---|---|---|---|
| transport layer | 1 | 20 nm | 2mPCCzPDBq | | |
| Second light-emitting layer | | 40 nm | 8mpTP-4mDBtPBfpm:βNCCP: | | |
| | | | Ir(5mppy-d₃)₂(mbfpypy-d₃) | | |
| | | | (0.5:0.5:0.1) | | |
| Second hole-transport layer | | 50 nm | PCBBiF | | |
| Intermediate | Second layer | 10 nm | PCBBiF:OCHD-003 (1:0.15) | | |
| layer | Third layer | 2 nm | CuPc | | |
| | First layer | 5 nm | NBPhen: | p-MeO-Phen: | p-MeO-Phen: |
| | | | p-MeO-Phen:In | In | Li₂O |
| | | | (0.5:0.5:0.05) | (1.0:0.05) | (1.0:0.02) |

| First electron-transport layer | | 10 nm | 2mPCCzPDBq |
|---|---|---|---|
| First light-emitting layer | | 40 nm | 8mpTP-4mDBtPBfpm:βNCCP: |
| | | | Ir(5mppy-d₃)₂(mbfpypy-d₃) |
| | | | (0.5:0.5:0.1) |
| First hole-transport layer | | 85 nm | PCBBiF |
| Hole-injection layer | | 10 nm | PCBBiF:OCHD-003 (1:0.03) |
| First electrode | 2 | 85 nm | ITSO |
| | 1 | 100 nm | Ag |

The light-emitting devices fabricated were each sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for 1 hour. Then, the initial characteristics of the light-emitting devices were measured.

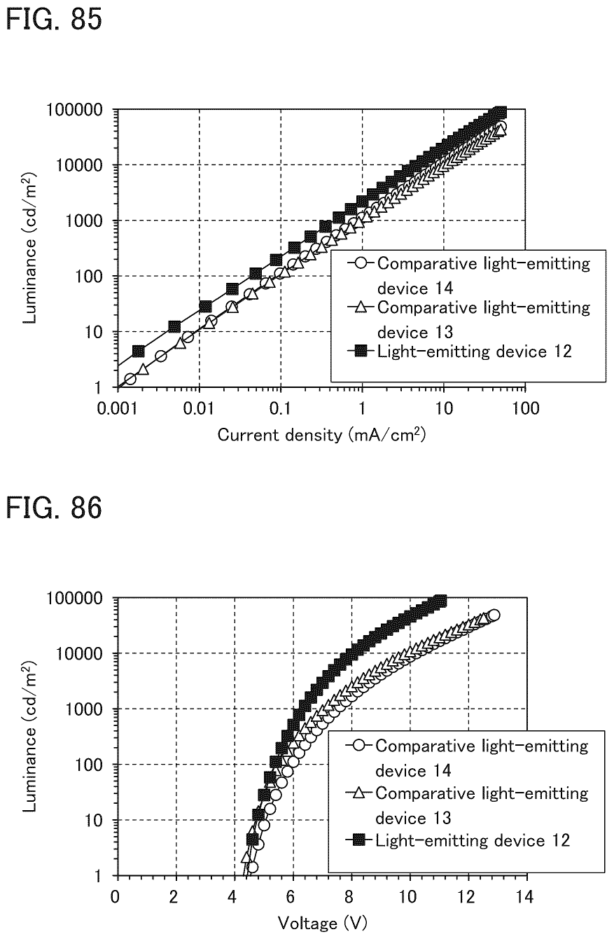

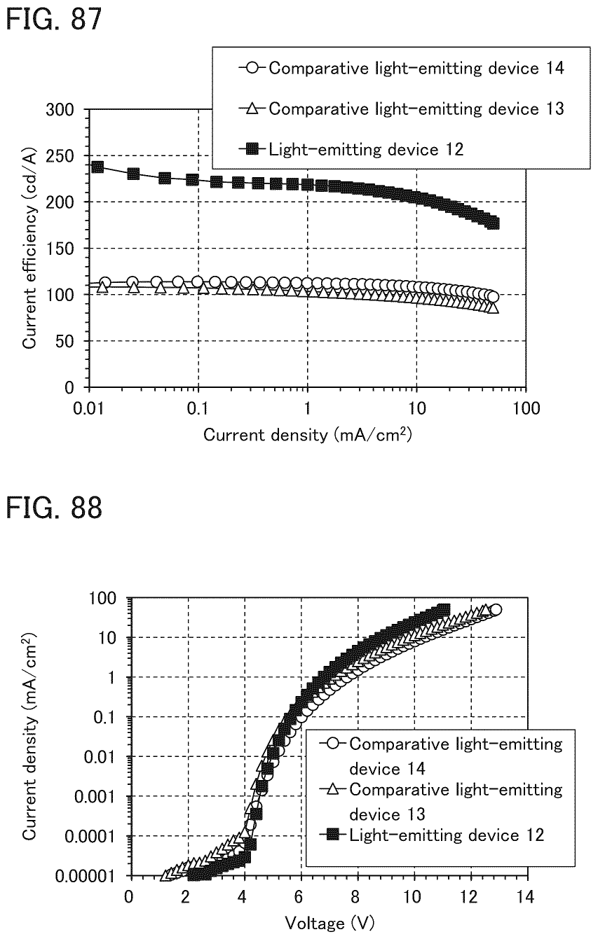

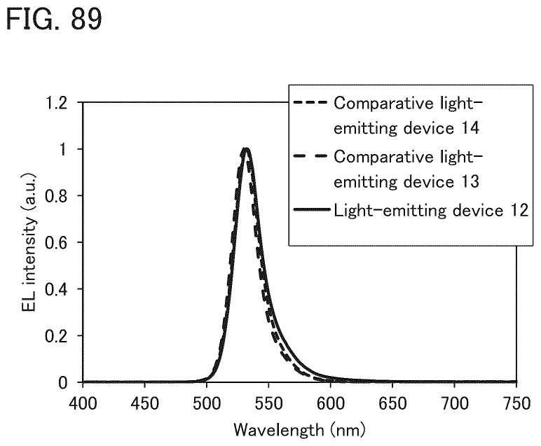

FIG. 85 shows the luminance-current density characteristics of the light-emitting device 12 and the comparative light-emitting devices 13 and 14, FIG. 86 shows the luminance-voltage characteristics thereof, FIG. 87 shows the current efficiency-current density characteristics thereof, FIG. 88 shows the current density-voltage characteristics thereof, and FIG. 89 shows the electroluminescence spectra thereof.

The table below shows the main characteristics of the light-emitting device 12 and the comparative light-emitting devices 13 and 14 at a luminance of approximately 1000 cd/m². The luminance, CIE chromaticity, and electroluminescence spectra were measured at normal temperature with a spectroradiometer (SR-UL1R manufactured by TOPCON TECHNOHOUSE CORPORATION).

TABLE 16

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Light-emitting device 12 | 6.4 | 0.021 | 0.51 | 0.25 | 0.72 | 1128 | 220 |
| Comparative light-emitting device 13 | 7.0 | 0.036 | 0.91 | 0.21 | 0.75 | 940 | 104 |
| Comparative light-emitting device 14 | 7.6 | 0.040 | 0.99 | 0.22 | 0.74 | 1110 | 112 |

FIGS. 85 to 89 and the above table reveal that the light-emitting device 12 exhibits green light emission derived from Ir(5mppy-d₃)₂(mbfpypy-d₃) and has favorable emission characteristics. It is also found that the light-emitting device 12 has higher current efficiency than the comparative light-emitting devices 13 and 14 and that the light-emitting device 12 is driven as a tandem light-emitting device, whereas the comparative light-emitting device 13 is not driven as a tandem light-emitting device. It is also found that the light-emitting device 12 has a lower driving voltage and lower power consumption than the comparative light-emitting devices 13 and 14.

It can be said that the above results were brought about because the light-emitting device 12 of one embodiment of the present invention suffered from little variation in characteristics regardless of having undergone the air exposure and was driven as a tandem light-emitting device, whereas the comparative light-emitting devices 13 and 14 suffered from a variation in characteristics by having undergone the air exposure and was not driven as a tandem light-emitting device. The light-emitting device 12 of one embodiment of the present invention suffered from little variation in characteristics regardless of having undergone the air exposure and was driven as a tandem light-emitting device because the light-emitting device of one embodiment of the present invention is resistant to air exposure.

The above results show that the light-emitting device of one embodiment of the present invention has a low driving voltage and high efficiency.

This application is based on Japanese Patent Application Serial No. 2023-083173 filed with Japan Patent Office on May 19, 2023 and Japanese Patent Application Serial No. 2023−143442 filed with Japan Patent Office on Sep. 5, 2023, the entire contents of which are hereby incorporated by reference.

What is claimed is:

1. A light-emitting device comprising:
a first electrode;
a second electrode; and
an organic compound layer,
wherein the organic compound layer is between the first electrode and the second electrode,
wherein the organic compound layer comprises a first light-emitting layer, a second light-emitting layer, and an intermediate layer,
wherein the intermediate layer is between the first light-emitting layer and the second light-emitting layer,
wherein the intermediate layer comprises a metal, a first organic compound, and a second organic compound,
wherein the first organic compound comprises a phenanthroline ring comprising an electron-donating group,
wherein the second organic compound comprises a π-electron deficient heteroaromatic ring, and
wherein the first organic compound and the metal form a donor level by interacting with each other as an electron donor with respect to the second organic compound.

2. A light-emitting device comprising:
a first electrode;
a second electrode; and
an organic compound layer,
wherein the organic compound layer is between the first electrode and the second electrode,
wherein the organic compound layer comprises a first light-emitting layer, a second light-emitting layer, and an intermediate layer,
wherein the intermediate layer is between the first light-emitting layer and the second light-emitting layer,
wherein the intermediate layer comprises a metal, a first organic compound, and a second organic compound,
wherein the first organic compound comprises a phenanthroline ring comprising an electron-donating group,
wherein the second organic compound comprises a π-electron deficient heteroaromatic ring, and
wherein a LUMO level of the second organic compound is lower than a LUMO level of the first organic compound.

3. A light-emitting apparatus comprising:
a first light-emitting device over an insulating surface; and
a second light-emitting device over the insulating surface,
wherein the first light-emitting device comprises:
a first electrode;
a second electrode; and
a first organic compound layer between the first electrode and the second electrode,
wherein the second light-emitting device comprises:
a third electrode;
the second electrode; and
a second organic compound layer between the third electrode and the second electrode,
wherein the first organic compound layer comprises:
a first light-emitting layer;
a second light-emitting layer; and
a first intermediate layer between the first light-emitting layer and the second light-emitting layer,
wherein the second organic compound layer comprises:
a third light-emitting layer;
a fourth light-emitting layer; and
a second intermediate layer between the third light-emitting layer and the fourth light-emitting layer,
wherein contours of the first light-emitting layer, the first intermediate layer, and the second light-emitting layer are aligned or substantially aligned with each other,
wherein contours of the third light-emitting layer, the second intermediate layer, and the fourth light-emitting layer are aligned or substantially aligned with each other,
wherein the first intermediate layer and the second intermediate layer each comprise a first layer,
wherein the first layer is a mixed layer comprising a metal, a first organic compound, and a second organic compound,
wherein the first organic compound comprises a phenanthroline ring comprising an electron-donating group, and
wherein the second organic compound comprises a π-electron deficient heteroaromatic ring.

4. The light-emitting device according to claim 1,
wherein the electron-donating group is at least one of an alkyl group, an alkoxy group, an aryloxy group, an alkylamino group, an arylamino group, and a heterocyclic amino group.

5. The light-emitting device according to claim 1,
wherein the phenanthroline ring is a 1,10-phenanthroline ring, and
wherein the electron-donating group is at at least one of a 4-position and a 7-position of the 1,10-phenanthroline ring.

6. The light-emitting device according to claim 1,
wherein an acid dissociation constant pKₐ of the first organic compound is higher than or equal to 8.

7. The light-emitting apparatus according to claim 3,
wherein a minimum value of an electrostatic potential of the first organic compound is smaller than or equal to −0.085 Eₕ when a threshold value of electron density distribution is 0.0004 e/a₀³.

8. The light-emitting apparatus according to claim 3,
wherein spin density of the first layer measured by an electron spin resonance method is higher than or equal to 5×10¹⁶ spins/cm³.

9. The light-emitting apparatus according to claim 8,
wherein spin density of a mixed film comprising the metal and the first organic compound is lower than or equal to 2×10¹⁶ spins/cm³, the spin density being measured by the electron spin resonance method, and
wherein spin density of a mixed film comprising the metal and the second organic compound is lower than or equal to 2×10¹⁶ spins/cm³, the spin density being measured by the electron spin resonance method.

10. The light-emitting device according to claim 1,
wherein the second organic compound comprises a phenanthroline ring.

11. The light-emitting device according to claim 1,
wherein a glass transition temperature T_{g} of the second organic compound is higher than or equal to 100° C.

12. The light-emitting apparatus according to claim 3,
wherein a LUMO level of the second organic compound is lower than a LUMO level of the first organic compound.

13. The light-emitting device according to claim 1,
wherein the metal belongs to Group 1, 3, 11, or 13 in a periodic table.

14. The light-emitting device according to claim 1,
wherein the intermediate layer further comprises a second layer,
wherein the second layer comprises a third organic compound and a fourth organic compound,
wherein the third organic compound comprises a π-electron rich heteroaromatic ring or an aromatic amine,
wherein the fourth organic compound comprises one or more halogen groups, one or more cyano groups, or both one or more halogen groups and one or more cyano groups, and
wherein a total number of the one or more halogen groups, the one or more cyano groups, or both the one or more halogen groups and the one or more cyano groups is four or more.

15. The light-emitting device according to claim 14,
wherein spin density of the second layer measured by an electron spin resonance method is higher than or equal to 1×10¹⁷ spins/cm³.

16. The light-emitting device according to claim 2,
wherein the electron-donating group is at least one of an alkyl group, an alkoxy group, an aryloxy group, an alkylamino group, an arylamino group, and a heterocyclic amino group.

17. The light-emitting device according to claim 2,
wherein the phenanthroline ring is a 1,10-phenanthroline ring, and
wherein the electron-donating group is at at least one of a 4-position and a 7-position of the 1,10-phenanthroline ring.

18. The light-emitting device according to claim 2,
wherein an acid dissociation constant pKₐ of the first organic compound is higher than or equal to 8.

19. The light-emitting device according to claim 2,
wherein the metal belongs to Group 1, 3, 11, or 13 in a periodic table.

20. The light-emitting apparatus according to claim 3,
wherein the metal belongs to Group 1, 3, 11, or 13 in a periodic table.
